(19) United States
(12) Patent Application Publication
(10) Pub. No.: US 2023/0092325 A1
(43) Pub. Date: Mar. 23, 2023

(54) DIGITAL PIXEL SENSOR

(71) Applicant: Meta Platforms Technologies, LLC, Menlo Park, CA (US)

(72) Inventors: Tsung-Hsun Tsai, Redmond, WA (US); Song Chen, Redmond, WA (US); Lyle David Bainbridge, Redwood City, CA (US); Xinqiao Liu, Medina, WA (US)

(21) Appl. No.: 17/931,001

(22) Filed: Sep. 9, 2022

Related U.S. Application Data
(60) Provisional application No. 63/247,596, filed on Sep. 23, 2021.

(51) Int. Cl. H01L 27/146; H04N 5/378; H04N 5/355; H04N 5/3745; G02B 27/01

(52) U.S. Cl. CPC H01L 27/14643; H04N 5/378; H04N 5/3559; H04N 5/37452; H04N 5/35536; G02B 27/0172; G02B 2027/0178; G02B 2027/014

(57) ABSTRACT

In one example, an apparatus comprises a first photodiode, a second photodiode, a first floating diffusion, a second floating diffusion, a quantizer, and a controller. The controller can enable the first photodiode and the second photodiode to generate and accumulate photo charge within an exposure period, and use the quantizer to quantize reset voltages at the first floating diffusion and at the second floating diffusion to generate a first digital reset value and a second digital reset value. After the exposure period ends, the controller can transfer the photo charge from the first photodiode and the second photodiode to, respectively, the first floating diffusion and the second floating diffusion to generate a first signal voltage and a second signal voltage, and quantize the signal voltages into digital signal values using the quantizer. Digital representations can be generated based on the digital reset values and the digital signal values.

### CROSS-REFERENCE TO RELATED APPLICATIONS

This application claims priority to U.S. Provisional Patent Application 63/247,596, filed Sep. 23, 2021, titled “Digital Pixel Sensor,” the entirety of which is hereby incorporated by reference.

### BACKGROUND

A typical pixel in an image sensor includes a photodiode to sense incident light by converting photons into charge (e.g., electrons or holes). The incident light can include components of different wavelength ranges for different applications, such as two dimensional—(2D) and three dimensional—(3D) sensing. Moreover, to reduce image distortion, a global shutter operation can be performed in which each photodiode of the array of photodiodes senses the incident light simultaneously in a global exposure period to generate the charge. The charge can be converted by a charge sensing unit (e.g., a floating diffusion) to convert to a voltage. The array of pixel cells can measure different components of the incident light based on the voltages converted by the charge sensing unit and provide the measurement results for generation of 2D and 3D images of a scene.

### SUMMARY

The present disclosure relates to image sensors. More specifically, and without limitation, this disclosure relates to a pixel cell. This disclosure also relates to operating the circuitries of pixel cells to generate a digital representation of the intensity of incident light.

One example apparatus includes a first photodiode; a second photodiode; a first floating diffusion; a second floating diffusion; a quantizer; and a controller configured to, within an exposure period, enable the first photodiode and the second photodiode to generate and accumulate, respectively, a first photo charge and a second photo charge in response to light; reset the first floating diffusion and the second floating diffusion to, respectively, generate a first reset voltage and a second reset voltage; quantize, using the quantizer, the first reset voltage to a first digital reset value; and quantize, using the quantizer, the second reset voltage to a second digital reset value; and after the exposure period ends, transfer the first photo charge from the first photodiode to the first floating diffusion to generate a first signal voltage; transfer the second photo charge from the second photodiode to the second floating diffusion to generate a second signal voltage; quantize, using the quantizer, the first signal voltage to a first digital signal value; quantize, using the quantizer, the second signal voltage to a second digital signal value; output a first digital representation of an intensity of the light received by the first photodiode based on a difference between the first digital signal value and the first digital reset value; and output a second digital representation of an intensity of the light received by the second photodiode based on a difference between the second digital signal value and the second digital reset value.

One example method includes, within an exposure period, enabling a first photodiode and a second photodiode to generate and accumulate, respectively, a first photo charge and a second photo charge in response to light; resetting a first floating diffusion and a second floating diffusion to, respectively, generate a first reset voltage and a second reset voltage; quantizing, using a quantizer, the first reset voltage to a first digital reset value; and quantizing, using the quantizer, the second reset voltage to a second digital reset value; and after the exposure period ends, transferring the first photo charge from the first photodiode to the first floating diffusion to generate a first signal voltage; transferring the second photo charge from the second photodiode to the second floating diffusion to generate a second signal voltage; quantizing, using the quantizer, the first signal voltage to a first digital signal value; quantizing, using the quantizer, the second signal voltage to a second digital signal value; outputting a first digital representation of an intensity of the light received by the first photodiode based on a difference between the first digital signal value and the first digital reset value; and outputting a second digital representation of an intensity of the light received by the second photodiode based on a difference between the second digital signal value and the second digital reset value.

### BRIEF DESCRIPTION OF THE DRAWINGS

Illustrative examples are described with reference to the following figures.

FIGS. 1A and 1B are diagrams of an example of a near-eye display.

FIG. 2 is an example of a cross section of the near-eye display.

FIG. 3 illustrates an isometric view of an example of a waveguide display with a single source assembly.

FIG. 4 illustrates a cross section of an example of the waveguide display.

FIG. 5 is a block diagram of an example of a system including the near-eye display.

FIG. 6 illustrates block diagrams of examples of an image sensor.

FIGS. 7A, 7B, and 7C illustrate operations for determining light intensities of different ranges by examples of FIG. 6.

FIGS. 8A, 8B, 8C, 8D, and 8E illustrate examples of components of the image sensor of FIG. 6.

FIGS. 9A, 9B, 9C, and 9D illustrate examples of an image sensor.

FIGS. 10A and 10B illustrate examples of an image sensor and their physical arrangement.

FIGS. 11A and 11B illustrate examples of an image sensor and their operations.

FIGS. 12A, 12B, and 12C illustrate examples of an image sensor and their operations.

FIGS. 13A and 13B illustrate examples of an image sensor and their operations.

FIGS. 14A and 14B illustrate examples of operations of an image sensor in generating an image frame based on detecting light in multiple exposure sub-periods.

FIGS. 15A and 15B illustrate examples of an image sensor and their operations in generating an image frame based on detecting light in multiple exposure sub-periods.

FIGS. 16A and 16B illustrate examples of an image sensor and their operations in generating an image frame based on detecting light in multiple exposure sub-periods.

FIGS. 17A and 17B illustrate a flowchart of an example process for performing an imaging operation.

The figures depict examples of the present disclosure for purposes of illustration only. One skilled in the art will readily recognize from the following description that alternative examples of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

In the following description, for the purposes of explanation, specific details are set forth in order to provide a thorough understanding of certain inventive examples. However, it will be apparent that various examples may be practiced without these specific details. The figures and description are not intended to be restrictive.

A typical image sensor includes an array of pixel cells. Each pixel cell includes one or more photodiodes. As part of a light measurement operation, the photodiode can measure the intensity incident light by converting photons into charge (e.g., electrons or holes). The charge generated by the photodiode can be converted to a voltage by a charge sensing unit, which can include a floating diffusion node. The voltage can be quantized by an analog-to-digital converter (ADC) into a digital output. The digital output can provide a digital representation of an intensity of light received by the pixel cell and can form a pixel, which can correspond to light received from a spot of a scene. An image comprising an array of pixels can be derived from the digital outputs of the array of pixel cells.

An image sensor can be used to perform different modes of imaging, such as 2D and 3D sensing. The 2D and 3D sensing can be performed based on light of different wavelength ranges. For example, visible light can be used for 2D sensing, whereas invisible light (e.g., infrared light) can be used for 3D sensing. An image sensor may include an optical filter array to allow visible light of different optical wavelength ranges and colors (e.g., red, green, blue, monochrome) to a first set of pixel cells assigned for 2D sensing, and invisible light to a second set of pixel cells assigned for 3D sensing.

To perform 2D sensing, a photodiode at a pixel cell can generate charge at a rate that is proportional to an intensity of a visible light component (e.g., red, green, blue, monochrome) incident upon the pixel cell, and the quantity of charge accumulated in an exposure period can be used to represent the intensity of visible light (or a certain color component of the visible light). The charge can be stored temporarily at the photodiode and then transferred to a capacitor (e.g., a floating diffusion) to develop a voltage. The voltage can be sampled and quantized by an ADC to generate an output corresponding to the intensity of visible light. An image pixel value can be generated based on the outputs from multiple pixel cells configured to sense different color components of the visible light (e.g., red, green, and blue colors).

Moreover, to perform 3D sensing, light of a different wavelength range (e.g., infrared light) can be projected onto an object, and the reflected light can be detected by the pixel cells. The light can include structured light, light pulses, etc. The pixel cells' outputs can be used to perform depth sensing operations based on, for example, detecting patterns of the reflected structured light, measuring a time-of-flight of the light pulse, etc. To detect patterns of the reflected structured light, a distribution of quantities of charge generated by the pixel cells during the exposure time can be determined, and pixel values can be generated based on the voltages corresponding to the quantities of charge. For time-of-flight measurement, the timing of generation of the charge at the photodiodes of the pixel cells can be determined to represent the times when the reflected light pulses are received at the pixel cells. Time differences between when the light pulses are projected to the object and when the reflected light pulses are received at the pixel cells can be used to provide the time-of-flight measurement.

A pixel cell array can be used to generate information of a scene. In some examples, each pixel cell (or at least some of the pixel cells) of the pixel cell array can be used to perform collocated 2D and 3D sensing at the same time. For example, a pixel cell may include multiple photodiodes, each configured to convert a different spectral component of light to charge. For 2D sensing, a photodiode can be configured to convert visible light (e.g., monochrome, or for a color of a particular frequency range) to charge, whereas another photodiode can be configured to convert infrared light to charge for 3D sensing. Having the same set of pixel cells to perform sensing of different spectral components of light can facilitate the correspondence between 2D and 3D images of different spectral components of light generated by the pixel cells. Moreover, given that every pixel cell of a pixel cell array can be used to generate the image, the full spatial resolution of the pixel cell array can be utilized for the imaging.

The 2D- and 3D-imaging data can be fused for various applications that provide virtual-reality (VR), augmented-reality (AR) and/or mixed reality (MR) experiences. For example, a wearable VR/AR/MR system may perform a scene reconstruction of an environment in which the user of the system is located. Based on the reconstructed scene, the VR/AR/MR can generate display effects to provide an interactive experience. To reconstruct a scene, the 3D-image data can be used to determine the distances between physical objects in the scene and the user. Moreover, 2D-image data can capture visual attributes including textures, colors, and reflectivity of these physical objects. The 2D- and 3D-image data of the scene can then be merged to create, for example, a 3D model of the scene including the visual attributes of the objects. As another example, a wearable VR/AR/MR system can also perform a head tracking operation based on a fusion of 2D and 3D image data. For example, based on the 2D-image data, the VR/AR/AR system can extract certain image features to identify an object. Based on the 3D-image data, the VR/AR/AR system can track a location of the identified object relative to the wearable device worn by the user. The VR/AR/AR system can track the head movement based on, for example, tracking the change in the location of the identified object relative to the wearable device as the user's head moves.

There are various performance metrics for an image sensor. The performance metric can include, for example, a resolution of the image sensor, which can affect a quality of the image captured by the image sensor and can be determined by the total number of pixel cells that can be included in a pixel cell array. The total number of pixel cells in a pixel cell array can be determined by the size and the power consumption of each pixel cell, especially for a wearable VR/AR/MR system where available space and power are at a premium. Specifically, in addition to the photodiodes, a pixel cell may include processing circuits to support measurement of the charge generated by each photodiode and to support the generation of a pixel value based on the measurements. The processing circuits, such as a quantizer (which typically includes a comparator), voltage buffer, etc., typically are built using analog processes and typically have much bigger footprints than the photodiode. The processing circuits also typically consume huge amounts of power. Including a dedicated comparator in each pixel cell can substantially increase both the footprint and the power consumption of the pixel cell. This may render the pixel cells unsuitable for a wearable device.

Another performance metric of an image sensor is a range of measurable light intensity, which determines the range of light intensity in which the digital output generated by a pixel cell is correlated to the intensity of light received by that pixel cell. The range of measurable light intensity can be characterized by the dynamic range of the image sensor, which can be defined by a ratio between an upper limit of the measurable light intensity and a lower limit of the measurable light intensity. A wide dynamic range is desirable as the image sensor may operate in environments with a very wide range of light intensities.

The degree of correlation between the digital output generated by a pixel cell and the intensity of light received by that pixel cell can vary. The degree of correlation can be affected by various factors. For example, when operating in a strong ambient light environment, the floating diffusion can become saturated by the charge generated by the photodiode and cannot take in additional charge. As a result, the quantity of the charge stored at the floating diffusion may be lower than the quantity of charge actually generated by the photodiode. The intensity of light that causes the floating diffusion to saturate can define an upper limit of the measurable light intensity of the image sensor. In addition, when operating in a low ambient light environment, the charge stored at the floating diffusion can include electronic noise charge (e.g., thermal noise, flicker noise, etc.) not related to the intensity of incident light, as well as dark charge contributed by dark current.

In addition, measurement errors can also be introduced. For example, leakage of charge may occur at the floating diffusion prior to the quantization operation, such that the charge being measured no longer represents the total charge generated by the photodiode during the exposure period and a measurement error is introduced. In addition, the comparator offset of the quantizer, voltage buffer threshold mismatches, etc., can also add to an error component in the digital output. The error components can appear as fixed pattern noises (FPN) in the digital outputs of the pixel cell array, where different pixel cells may have different comparator offsets, voltage buffer thresholds, and/or charge leakage rates. If the light intensity is sufficiently low, the quantity of charge actually generated by the photodiode and stored in the floating diffusion can also become so low that the charge is indistinguishable from the error component caused by the noises and the measurement errors. The error component can define a lower limit of the measurable light intensity of the image sensor.

This disclosure relates to an image sensor having a reduced footprint and power consumption, while providing an extended dynamic range. An image sensor can include a first photodiode, a second photodiode, a first floating diffusion, a second floating diffusion, a first transfer switch coupled between the first photodiode and the first floating diffusion, a second transfer switch coupled between the second photodiode and the second floating diffusion, a first reset switch coupled with the first floating diffusion, a second reset switch coupled with the second floating diffusion, a first source follower coupled with the first floating diffusion, a second source follower coupled with the second floating diffusion, a quantizer, a multiplexor circuit to selectively couple the output of one of the first source follower or the second source follower to the input of the quantizer, a first memory, a second memory, and a controller. The quantizer may include a comparator, whereas the first memory and the second memory can include banks of static random-access memory (SRAM) devices.

The controller can control the first and second transfer switches and reset switches to put both the first and second photodiodes, as well as the first and second floating diffusions, in a reset state prior to the start of an exposure period. The controller can then start the exposure period by disabling the first and second transfer switches, to enable the first and second photodiodes to generate and accumulate, respectively, a first photo charge and a second photo charge in response to light. Within the exposure period, while the first and second floating diffusions remain in the reset state, the controller can control the multiplexor circuit to couple the output of the first source follower to the quantizer. The quantizer can then quantize the first reset voltage to generate a first digital reset value. The controller can store the first digital reset value at the first memory. After the first digital reset value is generated, the controller can control the multiplexor circuit to couple the output of the second source follower to the quantizer. The quantizer can then quantize the second reset voltage to generate a second digital reset value. The controller can then store the second digital reset value at the second memory.

Prior to the end of the exposure period, the controller can disable the first and second reset switches simultaneously, and then enable the first and second transfer switches simultaneously, to transfer the first photo charge from the first photodiode to the first floating diffusion and to transfer the second photo charge from the second photodiode to the second floating diffusion. The controller can then disable the first and second transfer switches to end the transfer and the exposure period. At the end of the exposure period, the first floating diffusion can have a first signal voltage corresponding to a quantity of the first photo charge, whereas the second floating diffusion can have a second signal voltage corresponding to a quantity of the second photo charge. With such arrangements, both the first photodiode and the second photodiode can have the same exposure period (same duration and same start and end times), which can improve the global shutter operation.

After the exposure period ends, the controller can control the multiplexor circuit to couple the output of the first source follower to the quantizer. The quantizer can then quantize the first signal voltage to generate a first digital signal value, which can be stored at the first memory by the controller. After the first digital signal value is stored at the first memory, the controller can control the multiplexor circuit to couple the output of the second source follower to the quantizer. The quantizer can then quantize the second signal voltage to generate a second digital signal value, which can be stored at the second memory by the controller.

The controller can fetch the digital signal values and digital reset values from the first memory and the second memory to enable another device (e.g., an image processor) to generate digital outputs representing the intensity of light received by the photodiodes. The digital signal values and digital reset values can be fetched at the end of a frame period or can be fetched while additional digital signal values and digital reset values are being generated for other photodiodes that share the quantizer. The other device can then generate a digital output for a photodiode based on the digital signal value and the digital reset value generated for that photodiode. For example, the other device can generate a first digital output representing the intensity of light received by the first photodiode based on the first digital signal value and the first digital reset value, and a second digital output representing the intensity of light received by the second photodiode based on the second digital signal value and the second digital reset value.

In some examples, the first digital reset value and the second digital reset value can be used to support a digital correlated double sampling (CDS) operation for the first photodiode and the second photodiode. Specifically, the aforementioned error component introduced by electronic noise, as well as measurement errors such as comparator offset and voltage buffer threshold mismatch, is present in both the digital reset value and the digital signal value. A digital CDS operation can be performed to generate a digital output for a photodiode based on subtracting the digital reset value from the digital signal value to remove or reduce the error component. For example, the first digital output for the first photodiode can be based on a difference between the first digital signal value and the first digital reset value, and the second digital output for the second photodiode can be based on a difference between the second digital signal value and the second digital reset value. With such arrangements, the lower limit of the measurable light intensity can be further reduced to extend the dynamic range of the image sensor.

In addition to digital CDS operation, other post-processing operations can also be performed, such as leakage compensation, on both the digital reset value and the digital signal value. Specifically, as the quantization operation is performed for the first photodiode followed by the second photodiode, the charge stored in the first floating diffusion can experience less leakage than in the second floating diffusion when the quantization operation starts. To compensate for the mismatches in leakage, both the second digital reset value and the second digital signal value for the second photodiode can be increased by an offset based on a delay between the quantization operations for the first photodiode and the second photodiode, and a charge leakage rate of the second floating diffusion.

The first photodiode and the second photodiode can be of the same pixel cell or can be of different pixel cells within a block of pixel cells that share the quantizer. In some examples, more than two (e.g., four, eight, etc.) pixel cells/photodiodes can share a single quantizer. Compared with an arrangement where each photodiode has a dedicated quantizer to perform quantization, such arrangements can substantially reduce the total power and the footprint of the image sensor. The footprint of the image sensor can be further reduced by having the photodiodes, the quantizer, and the memory implemented in different semiconductor layers forming a stack. For example, the photodiodes can be formed on a first semiconductor layer, the quantizers shared by the photodiodes can be implemented in a second semiconductor layer, whereas the first and second memory for each photodiode can be implemented in a third semiconductor layer. The first, second, and third semiconductor layers can form a vertical stack and be electrically coupled using vertical interconnects, such as copper-to-copper bonding, through silicon vias (TSVs), etc., to reduce the power and delay incurred in the transmission of signals between the semiconductor layers.

In some examples, the apparatus can further include one or more sample-and-hold (S/H) circuits, each including a sampling switch and a sampling capacitor, to sample and hold/store the reset voltages and signal voltages at the floating diffusions. For example, the apparatus may include a first S/H circuit that is coupled between the first source follower output and the quantizer, and a second S/H circuit that is coupled between the second source follower output and the quantizer. The sampling switch can be implemented in the first semiconductor layer that also includes the photodiodes, whereas the sampling capacitor can be implemented as, for example, a metal capacitor stacked between the first semiconductor layer and the second semiconductor layer that includes the quantizer. The quantizer can quantize the sampled reset voltages and the sampled signal voltages to generate the digital reset values and the digital signal values. Such arrangements can reduce the effect of charge leakage and dark current on the charge stored in the floating diffusion while waiting to be quantized by the quantizer. The effect of charge leakage can be further reduced based on increasing the capacitance of the sampling capacitor. Meanwhile, the second digital reset value and the second digital signal value generated from the sampled reset and signal voltages can be increased by an offset based on a delay between the quantization operations for the first photodiode and the second photodiode, and a charge leakage rate of the second sampling capacitor.

Various examples of the multiplexor circuit are also proposed. In the examples where the quantizer is coupled with the outputs of the first and second source followers (e.g., no S/H circuit), the multiplexor circuit can be coupled between the outputs of the first and second source followers and the input of the quantizer, to selectively couple the output of one of the first or second source followers to the quantizer.

Moreover, in the examples where the apparatus includes the first S/H circuit of which an input is coupled with the first source follower and the second S/H circuit of which an input is coupled with the second source follower, the apparatus can further include a third source follower coupled with the output of the first S/H circuit and a fourth source follower coupled with the output of the second S/H circuit. In such examples, the multiplexor circuit can be coupled with the outputs of the third and fourth source followers to selectively couple one of the outputs of the third and fourth source followers with the quantizer. The third and fourth source followers can improve the driving strength and bandwidth. Moreover, by isolating the sampling capacitors from the quantizer, the third and fourth source followers can reduce the effect of leakage on the input voltage to ensure that the input voltage closely follows the sampled signal/reset voltages.

In some examples, the multiplexor can also be coupled directly with the outputs of the first S/H circuit and the second S/H circuit. Such arrangements can remove the power consumption and footprint that would otherwise be contributed by the third and fourth source followers, thereby reducing the power and footprint of the image sensor. In such examples, the apparatus may include a pre-charge circuit to reset the input of the quantizer prior to the multiplexor coupling the output of a S/H circuit to the quantizer, to reduce the effect of leakage (via the sampling capacitors) on the input voltage of the quantizer.

In some examples, to further increase the dynamic range of the image sensor, the controller can enable the first photodiode and the second photodiode to generate charge in multiple exposure sub-periods of different durations within a global exposure period, and the charge can be quantized to generate an image frame. The different durations can be configured based on different target intensity ranges. For example, the controller can enable a photodiode to sense light of a high light intensity range in a short duration exposure period to avoid saturating the photodiode. Moreover, the controller can enable the photodiode to sense light of a low light intensity range in a long duration exposure period to ensure that the charge generated and accumulated by the photodiode exceeds the noise charge.

In some examples, the controller can control the quantizer to quantize the first and second signal voltages for the first and second photodiodes for each exposure period to generate an image frame, and multiple image frames can be generated for the multiple exposure periods. For example, in a case where a first image frame is generated from a short exposure sub-period and a second image frame is generated from a long exposure sub-period, a combined image frame can be generated based on combining the first image frame and the second image frame. As part of the combination process, each pixel of the combined image frame can be generated from a pixel of one of the first image frame or the second image frame if the pixel value, scaled based on the exposure period, is within a pixel value range representing an intensity range of light to be measured. With such arrangements, pixel cells that are saturated in the second image frame due to the long exposure sub-period can have their digital outputs discarded, while pixel cells that receive low light within the long exposure sub-period can generate sufficient amount of charge to generate digital outputs that correlate with the intensities of the low light. Moreover, pixel cells that do not generate a sufficient amount of charge within the short exposure sub-period can have their digital outputs discarded, while pixel cells that receive strong light within the short exposure sub-period can avoid being saturated and can generate digital outputs that correlate with the intensities of the strong light.

In some examples, each of the first memory and the second memory may have sufficient capacity to store one set of digital values (e.g., first reset and signal digital values for the first photodiode, second reset and signal digital values for the second photodiode, etc.) generated within an exposure period. To accommodate the generation of multiple image frames for multiple exposure periods, the controller can perform read-out operations of the first set of digital values, which are generated from quantizing the reset noise charge and photo charge generated in a first exposure period, prior to the end of a second exposure period that follows the first exposure period. Such arrangements can ensure that the first set of digital values can be accessed by other devices (e.g., stored in an external frame buffer, accessed by an image processor, etc.) prior to being overwritten with the second set of digital values obtained from the quantization of the reset noise charge and photo charge generated in the second exposure period. In such examples, the duration and/or the start time of the second exposure period can be set to provide sufficient time for the read-out operation to complete.

In some examples, the controller may store only one set of digital values generated in one of the multiple exposure periods for each photodiode within a frame period, and discard other sets of digital values generated in other exposure periods within the frame period. For example, the controller may store a digital signal value obtained from one of the exposure periods in the memory if the digital signal value is within a pixel value range representing an intensity range of light to be measured. After the digital signal value is stored in the memory, the controller may lock the memory to prevent the memory from being overwritten for the rest of the frame period. The controller can also store the digital reset value obtained during the one of the exposure periods, so that the digital reset value and the digital signal value can be fetched from the memory to support a digital CDS operation.

In some examples, the controller can perform quantization of the reset voltage in the floating diffusion in one of the multiple exposure periods, such as in the short exposure sub-period within the frame period. The floating diffusions are reset only in the beginning of the short exposure sub-period, which allows the floating diffusions to accumulate charges from the photodiodes obtained in multiple exposure periods. As such, the multiple exposure periods can start at the same time. Compared with the aforementioned arrangements where the floating diffusions are reset in each of multiple integration periods, such arrangements can reduce the number of quantization operations, which can reduce power as well as the total time incurred by the quantization operations. The frame period can be reduced as a result. In addition, by having the multiple exposure periods starting at the same time, it becomes more likely that the same scenes are captured in the multiple exposure periods, which can reduce the motion artifacts in the image in a case where the scene contains fast moving objects.

With examples of the present disclosure, an image sensor can have a reduced footprint and power consumption by having multiple photodiodes taking turns in accessing a quantizer to perform quantization operations, while the photodiodes can have the same exposure period to support a global shutter operation. In addition, examples of the present disclosure can implement various techniques to extend the dynamic range of the image sensor. For example, quantization operations can also be performed to quantize the reset voltages and the signal voltages to support digital CDS operations. Moreover, S/H circuits can also be provided to sample and hold the reset and signal voltages at the floating diffusions to reduce the effect of leakage mismatch among the multiple photodiodes, as well as dark charge, caused by the sequential quantization operations. Further, each photodiode can have multiple exposure periods, each having a different duration, to increase the likelihood that the photodiode can generate an accurate intensity measurement within a wide light intensity range. All these can improve the performance of the image sensor.

The disclosed examples may include or be implemented in conjunction with an artificial reality system. Artificial reality is a form of reality that has been adjusted in some manner before presentation to a user, which may include, e.g., VR, AR, MR, a hybrid reality, or some combination and/or derivatives thereof. Artificial reality content may include completely generated content or generated content combined with captured (e.g., real-world) content. The artificial reality content may include video, audio, haptic feedback, or some combination thereof, any of which may be presented in a single channel or in multiple channels (such as stereo video that produces a three-dimensional effect to the viewer). Additionally, in some examples, artificial reality may also be associated with applications, products, accessories, services, or some combination thereof, that are used to, e.g., create content in an artificial reality and/or are otherwise used in (e.g., perform activities in) an artificial reality. The artificial reality system that provides the artificial reality content may be implemented on various platforms, including a head-mounted display (HMD) connected to a host computer system, a standalone HMD, a mobile device or computing system, or any other hardware platform capable of providing artificial reality content to one or more viewers.

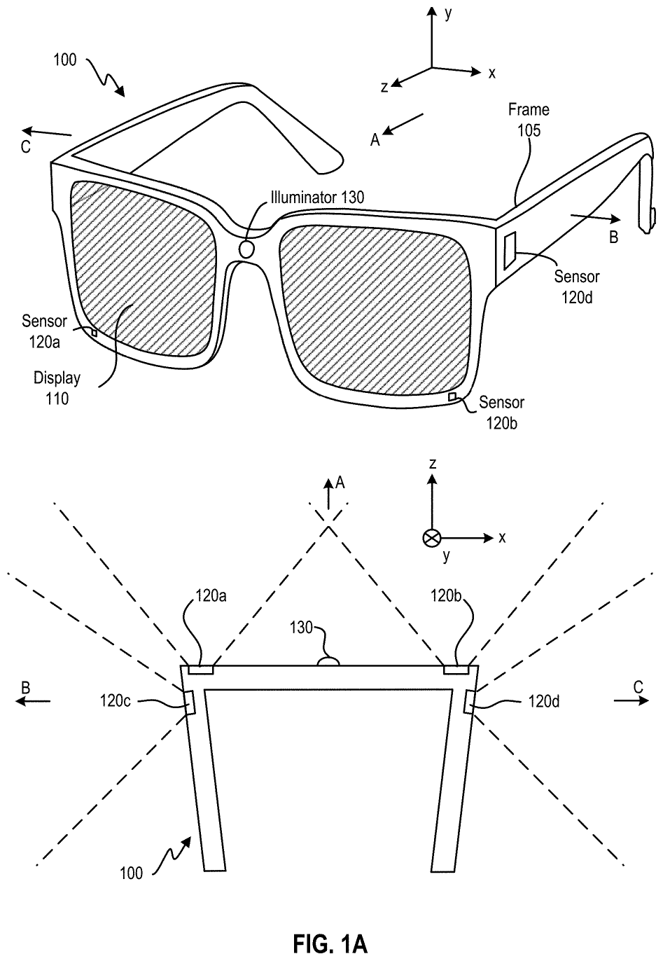

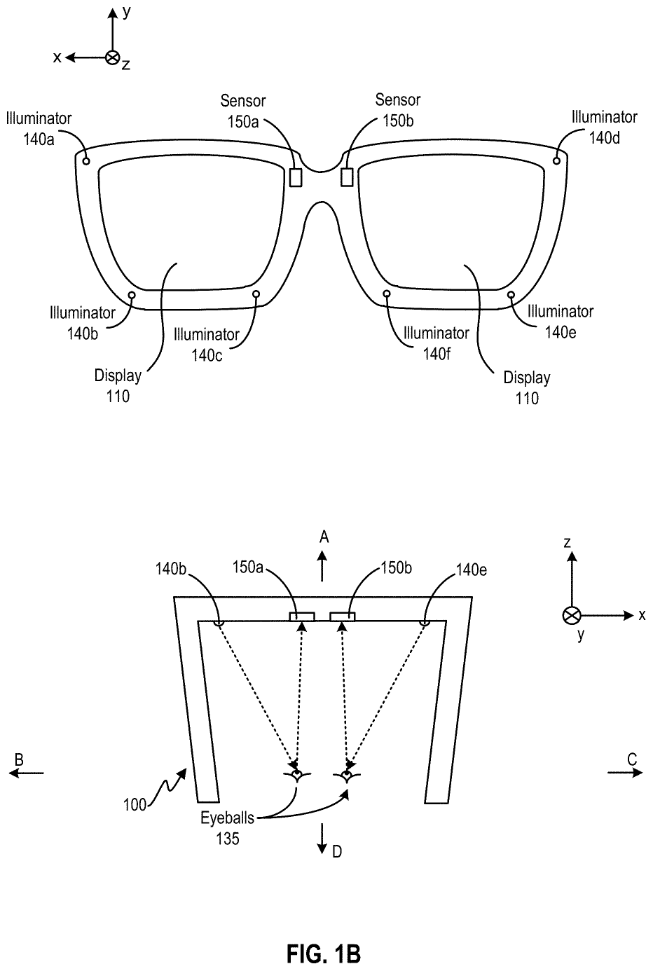

FIG. 1A is a diagram of an example of a near-eye display 100. Near-eye display 100 presents media to a user. Examples of media presented by near-eye display 100 include one or more images, video, and/or audio. In some examples, audio is presented via an external device (e.g., speakers and/or headphones) that receives audio information from the near-eye display 100, a console, or both, and presents audio data based on the audio information. Near-eye display 100 is generally configured to operate as a VR display. In some examples, near-eye display 100 is modified to operate as an AR display and/or a MR display.

Near-eye display 100 includes a frame 105 and a display 110. Frame 105 is coupled to one or more optical elements. Display 110 is configured for the user to see content presented by near-eye display 100. In some examples, display 110 comprises a wave guide display assembly for directing light from one or more images to an eye of the user.

Near-eye display 100 further includes image sensors 120a, 120b, 120c, and 120d. Each of image sensors 120a, 120b, 120c, and 120d may include a pixel array configured to generate image data representing different fields of views along different directions. For example, image sensors 120a and 120b may be configured to provide image data representing two fields of view towards a direction A along the Z axis, whereas sensor 120c may be configured to provide image data representing a field of view towards a direction B along the X axis, and sensor 120d may be configured to provide image data representing a field of view towards a direction C along the X axis.

In some examples, image sensors 120a 120d can be configured as input devices to control or influence the display content of the near-eye display 100, to provide an interactive VR/AR/MR experience to a user who wears near-eye display 100. For example, image sensors 120a 120d can generate physical image data of a physical environment in which the user is located. The physical image data can be provided to a location tracking system to track a location and/or a path of movement of the user in the physical environment. A system can then update the image data provided to display 110 based on, for example, the location and orientation of the user, to provide the interactive experience. In some examples, the location tracking system may operate a simultaneous localization and mapping (SLAM) algorithm to track a set of objects in the physical environment and within a view of field of the user as the user moves within the physical environment. The location tracking system can construct and update a map of the physical environment based on the set of objects, and track the location of the user within the map. By providing image data corresponding to multiple fields of views, image sensors 120a 120d can provide the location tracking system a more holistic view of the physical environment, which can lead to more objects to be included in the construction and updating of the map. With such an arrangement, the accuracy and robustness of tracking a location of the user within the physical environment can be improved.

In some examples, near-eye display 100 may further include one or more active illuminators 130 to project light into the physical environment. The light projected can be associated with different frequency spectrums (e.g., visible light, infrared light, ultra-violet light, etc.), and can serve various purposes. For example, illuminator 130 may project light in a dark environment (or in an environment with low intensity of infrared light, ultra-violet light, etc.) to assist image sensors 120a 120d in capturing images of different objects within the dark environment to, for example, enable location tracking of the user. Illuminator 130 may project certain markers onto the objects within the environment, to assist the location tracking system in identifying the objects for map construction/updating.

In some examples, illuminator 130 may also enable stereoscopic imaging. For example, one or more of image sensors 120a or 120b can include both a first pixel array for visible light sensing and a second pixel array for infrared (IR) light sensing. The first pixel array can be overlaid with a color filter (e.g., a Bayer filter), with each pixel of the first pixel array being configured to measure intensity of light associated with a particular color (e.g., one of red, green or blue colors). The second pixel array (for IR light sensing) can also be overlaid with a filter that allows only IR light through, with each pixel of the second pixel array being configured to measure intensity of IR lights. The pixel arrays can generate an RGB image and an IR image of an object, with each pixel of the IR image being mapped to each pixel of the RGB image. Illuminator 130 may project a set of IR markers on the object, the images of which can be captured by the IR pixel array. Based on a distribution of the IR markers of the object as shown in the image, the system can estimate a distance of different parts of the object from the IR pixel array, and generate a stereoscopic image of the object based on the distances. Based on the stereoscopic image of the object, the system can determine, for example, a relative position of the object with respect to the user, and can update the image data provided to display 100 based on the relative position information to provide the interactive experience.

As discussed above, near-eye display 100 may be operated in environments associated with a very wide range of light intensities. For example, near-eye display 100 may be operated in an indoor environment or in an outdoor environment, and/or at different times of the day. Near-eye display 100 may also operate with or without active illuminator 130 being turned on. As a result, image sensors 120a 120d may need to have a wide dynamic range to be able to operate properly (e.g., to generate an output that correlates with the intensity of incident light) across a very wide range of light intensities associated with different operating environments for near-eye display 100.

FIG. 1B is a diagram of another example of near-eye display 100. FIG. 1B illustrates a side of near-eye display 100 that faces the eyeball(s) 135 of the user who wears near-eye display 100. As shown in FIG. 1B, near-eye display 100 may further include a plurality of illuminators 140a, 140b, 140c, 140d, 140e, and 140f. Near-eye display 100 further includes a plurality of image sensors 150a and 150b. Illuminators 140a, 140b, and 140c may emit lights of certain frequency range (e.g., NIR) towards direction D (which is opposite to direction A of FIG. 1A). The emitted light may be associated with a certain pattern, and can be reflected by the left eyeball of the user. Image sensor 150a may include a pixel array to receive the reflected light and generate an image of the reflected pattern. Similarly, illuminators 140d, 140e, and 140f may emit NIR lights carrying the pattern. The NIR lights can be reflected by the right eyeball of the user, and may be received by image sensor 150b. Image sensor 150b may also include a pixel array to generate an image of the reflected pattern. Based on the images of the reflected pattern from image sensors 150a and 150b, the system can determine a gaze point of the user, and update the image data provided to display 100 based on the determined gaze point to provide an interactive experience to the user.

As discussed above, to avoid damaging the eyeballs of the user, illuminators 140a, 140b, 140c, 140d, 140e, and 140f are typically configured to output lights of very low intensities. In a case where image sensors 150a and 150b comprise the same sensor devices as image sensors 120a 120d of FIG. 1A, the image sensors 120a 120d may need to be able to generate an output that correlates with the intensity of incident light when the intensity of the incident light is very low, which may further increase the dynamic range requirement of the image sensors.

Moreover, the image sensors 120a 120d may need to be able to generate an output at a high speed to track the movements of the eyeballs. For example, a user's eyeball can perform a very rapid movement (e.g., a saccade movement) in which there can be a quick jump from one eyeball position to another. To track the rapid movement of the user's eyeball, image sensors 120a 120d need to generate images of the eyeball at high speed. For example, the rate at which the image sensors generate an image frame (the frame rate) needs to at least match the speed of movement of the eyeball. The high frame rate requires short total exposure time for all of the pixel cells involved in generating the image frame, as well as high speed for converting the sensor outputs into digital values for image generation. Moreover, as discussed above, the image sensors also need to be able to operate at an environment with low light intensity.

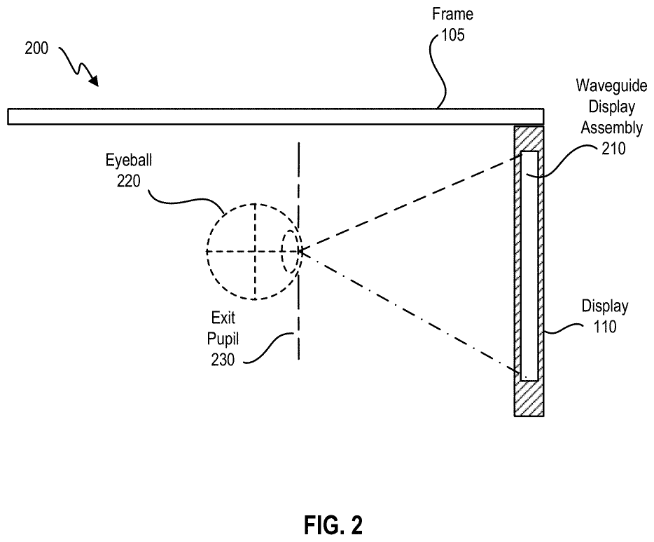

FIG. 2 is an example of a cross section 200 of near-eye display 100 illustrated in FIG. 1. Display 110 includes at least one waveguide display assembly 210. An exit pupil 230 is a location where a single eyeball 220 of the user is positioned in an eyebox region when the user wears the near-eye display 100. For purposes of illustration, FIG. 2 shows the cross section 200 associated eyeball 220 and a single waveguide display assembly 210, but a second waveguide display is used for a second eye of a user.

Waveguide display assembly 210 is configured to direct image light to an eyebox located at exit pupil 230 and to eyeball 220. Waveguide display assembly 210 may be composed of one or more materials (e.g., plastic, glass) with one or more refractive indices. In some examples, near-eye display 100 includes one or more optical elements between waveguide display assembly 210 and eyeball 220.

In some examples, waveguide display assembly 210 includes a stack of one or more waveguide displays including, but not restricted to, a stacked waveguide display, a varifocal waveguide display, etc. The stacked waveguide display is a polychromatic display (e.g., RGB display) created by stacking waveguide displays whose respective monochromatic sources are of different colors. The stacked waveguide display is also a polychromatic display that can be projected on multiple planes (e.g., multi-planar colored display). In some configurations, the stacked waveguide display is a monochromatic display that can be projected on multiple planes (e.g., multi-planar monochromatic display). The varifocal waveguide display is a display that can adjust a focal position of image light emitted from the waveguide display. In alternate examples, waveguide display assembly 210 may include the stacked waveguide display and the varifocal waveguide display.

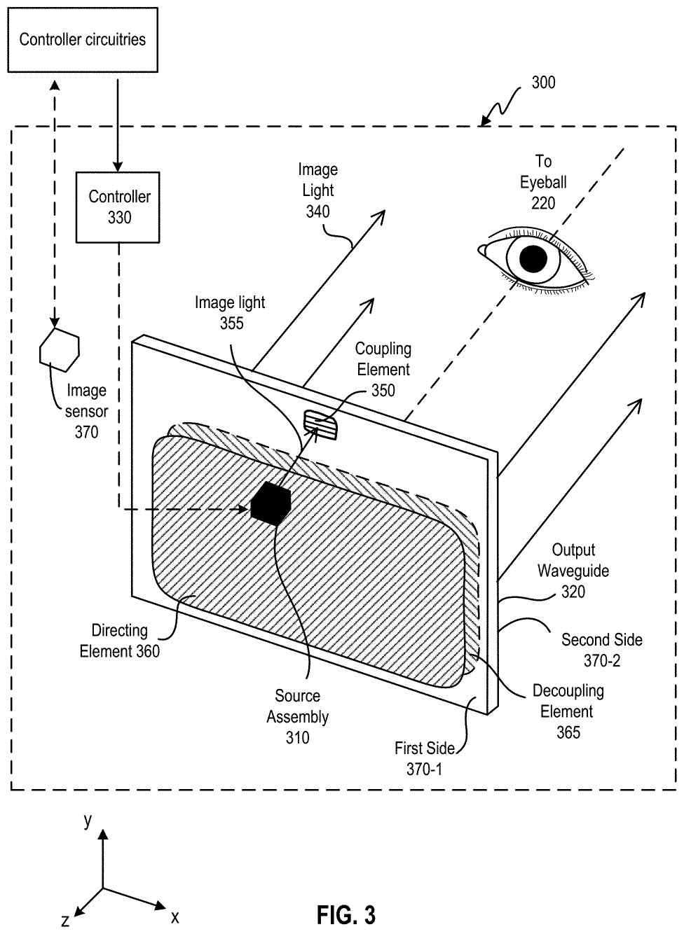

FIG. 3 illustrates an isometric view of an example of a waveguide display 300. In some examples, waveguide display 300 is a component (e.g., waveguide display assembly 210) of near-eye display 100. In some examples, waveguide display 300 is part of some other near-eye display or other system that directs image light to a particular location.

Waveguide display 300 includes a source assembly 310, an output waveguide 320, and a controller 330. For purposes of illustration, FIG. 3 shows the waveguide display 300 associated with a single eyeball 220, but in some examples, another waveguide display that is separate, or partially separate, from the waveguide display 300 provides image light to another eye of the user.

Source assembly 310 generates image light 355. Source assembly 310 generates and outputs image light 355 to a coupling element 350 located on a first side 370-1 of output waveguide 320. Output waveguide 320 is an optical waveguide that outputs expanded image light 340 to an eyeball 220 of a user. Output waveguide 320 receives image light 355 at one or more coupling elements 350 located on the first side 370-1 and guides received input image light 355 to a directing element 360. In some examples, coupling element 350 couples the image light 355 from source assembly 310 into output waveguide 320. Coupling element 350 may be, e.g., a diffraction grating, a holographic grating, one or more cascaded reflectors, one or more prismatic surface elements, and/or an array of holographic reflectors.

Directing element 360 redirects the received input image light 355 to decoupling element 365 such that the received input image light 355 is decoupled out of output waveguide 320 via decoupling element 365. Directing element 360 is part of, or affixed to, first side 370-1 of output waveguide 320. Decoupling element 365 is part of, or affixed to, second side 370-2 of output waveguide 320, such that directing element 360 is opposed to the decoupling element 365. Directing element 360 and/or decoupling element 365 may be, e.g., a diffraction grating, a holographic grating, one or more cascaded reflectors, one or more prismatic surface elements, and/or an array of holographic reflectors.

Second side 370-2 represents a plane along an x-dimension and a y-dimension. Output waveguide 320 may be composed of one or more materials that facilitate total internal reflection of image light 355. Output waveguide 320 may be composed of e.g., silicon, plastic, glass, and/or polymers. Output waveguide 320 has a relatively small form factor. For example, output waveguide 320 may be approximately 50 mm wide along an x-dimension, 30 mm long along a y-dimension and 0.5-1 mm thick along a z-dimension.

Controller 330 controls scanning operations of source assembly 310. The controller 330 determines scanning instructions for the source assembly 310. In some examples, the output waveguide 320 outputs expanded image light 340 to the user's eyeball 220 with a large field of view (FOV). For example, the expanded image light 340 is provided to the user's eyeball 220 with a diagonal FOV (in x and y) of 60 degrees and/or greater and/or 150 degrees and/or less. The output waveguide 320 is configured to provide an eyebox with a length of 20 mm or greater and/or equal to or less than 50 mm; and/or a width of 10 mm or greater and/or equal to or less than 50 mm.

Moreover, controller 330 also controls image light 355 generated by source assembly 310, based on image data provided by image sensor 370. Image sensor 370 may be located on first side 370-1 and may include, for example, image sensors 120a 120d of FIG. 1A to generate image data of a physical environment in front of the user (e.g., for location determination). Image sensor 370 may also be located on second side 370-2 and may include image sensors 150a and 150b of FIG. 1B to generate image data of eyeball 220 (e.g., for gaze point determination) of the user. Image sensor 370 may interface with a remote console that is not located within waveguide display 300. Image sensor 370 may provide image data to the remote console, which may determine, for example, a location of the user, a gaze point of the user, etc., and determine the content of the images to be displayed to the user. The remote console can transmit instructions to controller 330 related to the determined content. Based on the instructions, controller 330 can control the generation and outputting of image light 355 by source assembly 310.

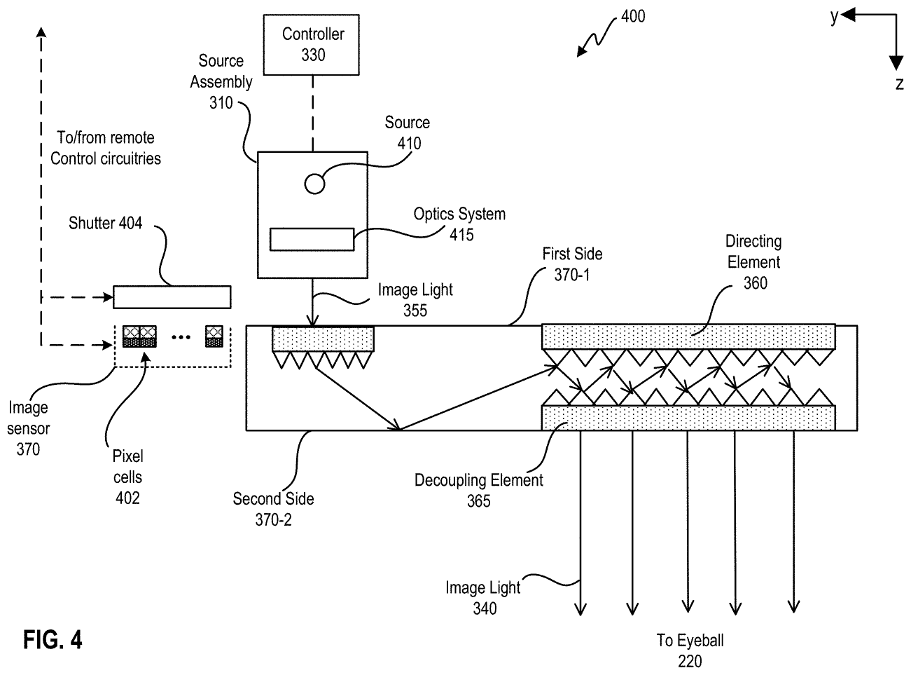

FIG. 4 illustrates an example of a cross section 400 of the waveguide display 300. The cross section 400 includes source assembly 310, output waveguide 320, and image sensor 370. In the example of FIG. 4, image sensor 370 may include a set of pixel cells 402 located on first side 370-1 to generate an image of the physical environment in front of the user. In some examples, there can be a mechanical shutter 404 interposed between the set of pixel cells 402 and the physical environment to control the exposure of the set of pixel cells 402. In some examples, the mechanical shutter 404 can be replaced by an electronic shutter gate, as to be discussed below. Each of pixel cells 402 may correspond to one pixel of the image. Although not shown in FIG. 4, it is understood that each of pixel cells 402 may also be overlaid with a filter to control the frequency range of the light to be sensed by the pixel cells.

After receiving instructions from the remote console, mechanical shutter 404 can open and expose the set of pixel cells 402 in an exposure period. During the exposure period, image sensor 370 can obtain samples of lights incident on the set of pixel cells 402, and generate image data based on an intensity distribution of the incident light samples detected by the set of pixel cells 402. Image sensor 370 can then provide the image data to the remote console, which determines the display content, and provide the display content information to controller 330. Controller 330 can then determine image light 355 based on the display content information.

Source assembly 310 generates image light 355 in accordance with instructions from the controller 330. Source assembly 310 includes a source 410 and an optics system 415. Source 410 is a light source that generates coherent or partially coherent light. Source 410 may be, e.g., a laser diode, a vertical cavity surface emitting laser, and/or a light emitting diode.

Optics system 415 includes one or more optical components that condition the light from source 410. Conditioning light from source 410 may include, e.g., expanding, collimating, and/or adjusting orientation in accordance with instructions from controller 330. The one or more optical components may include one or more lenses, liquid lenses, mirrors, apertures, and/or gratings. In some examples, optics system 415 includes a liquid lens with a plurality of electrodes that allows scanning of a beam of light with a threshold value of scanning angle to shift the beam of light to a region outside the liquid lens. Light emitted from the optics system 415 (and also source assembly 310) is referred to as image light 355.

Output waveguide 320 receives image light 355. Coupling element 350 couples image light 355 from source assembly 310 into output waveguide 320. In examples where coupling element 350 is a diffraction grating, a pitch of the diffraction grating is chosen such that total internal reflection occurs in output waveguide 320, and image light 355 propagates internally in output waveguide 320 (e.g., by total internal reflection), toward decoupling element 365.

Directing element 360 redirects image light 355 toward decoupling element 365 for decoupling from output waveguide 320. In examples where directing element 360 is a diffraction grating, the pitch of the diffraction grating is chosen to cause incident image light 355 to exit output waveguide 320 at angle(s) of inclination relative to a surface of decoupling element 365.

In some examples, directing element 360 and/or decoupling element 365 are structurally similar. Expanded image light 340 exiting output waveguide 320 is expanded along one or more dimensions (e.g., may be elongated along x-dimension). In some examples, waveguide display 300 includes a plurality of source assemblies 310 and a plurality of output waveguides 320. Each of source assemblies 310 emits a monochromatic image light of a specific band of wavelength corresponding to a primary color (e.g., red, green, or blue). Each of output waveguides 320 may be stacked together with a distance of separation to output an expanded image light 340 that is multi-colored.

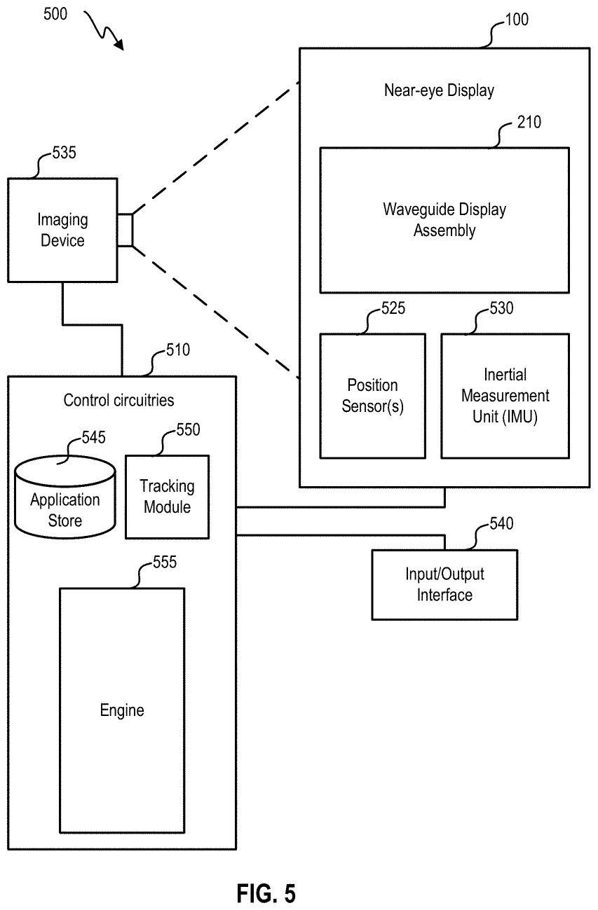

FIG. 5 is a block diagram of an example of a system 500 including the near-eye display 100. The system 500 comprises near-eye display 100, an imaging device 535, an input/output interface 540, and image sensors 120a 120d and 150a 150b that are each coupled to control circuitries 510. System 500 can be configured as a head-mounted device, a wearable device, etc.

Near-eye display 100 is a display that presents media to a user. Examples of media presented by the near-eye display 100 include one or more images, video, and/or audio. In some examples, audio is presented via an external device (e.g., speakers and/or headphones) that receives audio information from near-eye display 100 and/or control circuitries 510 and presents audio data based on the audio information to a user. In some examples, near-eye display 100 may also act as an AR eyewear glass. In some examples, near-eye display 100 augments views of a physical, real-world environment, with computer-generated elements (e.g., images, video, sound).

Near-eye display 100 includes waveguide display assembly 210, one or more position sensors 525, and/or an inertial measurement unit (IMU) 530. Waveguide display assembly 210 includes source assembly 310, output waveguide 320, and controller 330.

IMU 530 is an electronic device that generates fast calibration data indicating an estimated position of near-eye display 100 relative to an initial position of near-eye display 100 based on measurement signals received from one or more of position sensors 525.

Imaging device 535 may generate image data for various applications. For example, imaging device 535 may generate image data to provide slow calibration data in accordance with calibration parameters received from control circuitries 510. Imaging device 535 may include, for example, image sensors 120a 120d of FIG. 1A for generating image data of a physical environment in which the user is located, for performing location tracking of the user. Imaging device 535 may further include, for example, image sensors 150a 150b of FIG. 1B for generating image data for determining a gaze point of the user, to identify an object of interest of the user.

The input/output interface 540 is a device that allows a user to send action requests to the control circuitries 510. An action request is a request to perform a particular action. For example, an action request may be to start or end an application or to perform a particular action within the application.

Control circuitries 510 provide media to near-eye display 100 for presentation to the user in accordance with information received from one or more of: imaging device 535, near-eye display 100, and input/output interface 540. In some examples, control circuitries 510 can be housed within system 500 configured as a head-mounted device. In some examples, control circuitries 510 can be a standalone console device communicatively coupled with other components of system 500. In the example shown in FIG. 5, control circuitries 510 include an application store 545, a tracking module 550, and an engine 555.

The application store 545 stores one or more applications for execution by the control circuitries 510. An application is a group of instructions, that, when executed by a processor, generates content for presentation to the user. Examples of applications include gaming applications, conferencing applications, video playback applications, or other suitable applications.

Tracking module 550 calibrates system 500 using one or more calibration parameters and may adjust one or more calibration parameters to reduce error in determination of the position of the near-eye display 100.

Tracking module 550 tracks movements of near-eye display 100 using slow calibration information from the imaging device 535. Tracking module 550 also determines positions of a reference point of near-eye display 100 using position information from the fast calibration information.

Engine 555 executes applications within system 500 and receives position information, acceleration information, velocity information, and/or predicted future positions of near-eye display 100 from tracking module 550. In some examples, information received by engine 555 may be used for producing a signal (e.g., display instructions) to waveguide display assembly 210 that determines a type of content presented to the user. For example, to provide an interactive experience, engine 555 may determine the content to be presented to the user based on a location of the user (e.g., provided by tracking module 550), or a gaze point of the user (e.g., based on image data provided by imaging device 535), a distance between an object and user (e.g., based on image data provided by imaging device 535).

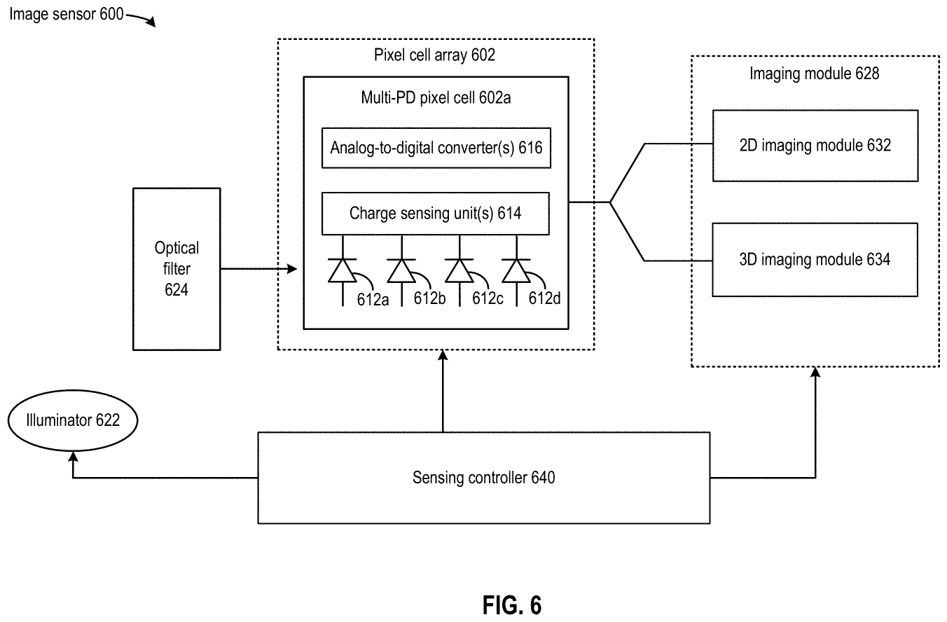

FIG. 6 illustrates an example of an image sensor 600. Image sensor 600 can be part of near-eye display 100, and can provide 2D and 3D image data to control circuitries 510 of FIG. 5 to control the display content of near-eye display 100. As shown in FIG. 6, image sensor 600 may include an array of pixel cells 602 including pixel cell 602a. Although FIG. 6 illustrates only a single pixel cell 602, it is understood that an actual pixel cell array 602 can include many pixel cells.

Pixel cell 602a can include a plurality of photodiodes 612 including, for example, photodiodes 612a, 612b, 612c, and 612d, one or more charge sensing units 614, and one or more analog-to-digital converters (ADCs) 616. The plurality of photodiodes 612 can convert different components of incident light to charge. For example, photodiode 612a 612c can correspond to different visible light channels, in which photodiode 612a can convert a visible blue component (e.g., a wavelength range of 450 490 nanometers (nm)) to charge. Photodiode 612b can convert a visible green component (e.g., a wavelength range of 520 560 nm) to charge. Photodiode 612c can convert a visible red component (e.g., a wavelength range of 635 700 nm) to charge. Moreover, photodiode 612d can convert an infrared component (e.g., 700 1000 nm) to charge. Each of the one or more charge sensing units 614 can include a charge storage device and a buffer to convert the charge generated by photodiodes 612a 612d to voltages, which can be quantized by one or more ADCs 616 into digital values. In some examples, the ADCs can be external to pixel cell 602a and can be shared among multiple pixel cells. The digital values generated from photodiodes 612a 612c can represent the different visible light components of a pixel, and each can be used for 2D sensing in a particular visible light channel. Moreover, the digital value generated from photodiode 612d can represent the infrared light component of the same pixel and can be used for 3D sensing. Although FIG. 6 shows that pixel cell 602a includes four photodiodes, it is understood that the pixel cell can include a different number of photodiodes (e.g., two, three).

In some examples, image sensor 600 may also include an illuminator 622, an optical filter 624, an imaging module 628, and a sensing controller 630. Illuminator 622 may be an infrared illuminator, such as a laser, a light emitting diode (LED), etc., that can project infrared light for 3D sensing. The projected light may include, for example, structured light, light pulses, etc. Optical filter 624 may include an array of filter elements overlaid on the plurality of photodiodes 612a 612d of each pixel cell including pixel cell 606a. Each filter element can set a wavelength range of incident light received by each photodiode of pixel cell 606a. For example, a filter element over photodiode 612a may transmit the visible blue light component while blocking other components, a filter element over photodiode 612b may transmit the visible green light component, a filter element over photodiode 612c may transmit the visible red light component, whereas a filter element over photodiode 612d may transmit the infrared light component.

Image sensor 600 further includes an imaging module 628. Imaging module 628 may further include a 2D-imaging module 632 to perform 2D-imaging operations and a 3D-imaging module 634 to perform 3D-imaging operations. The operations can be based on digital values provided by ADCs 616. For example, based on the digital values from each of photodiodes 612a 612c, 2D-imaging module 632 can generate an array of pixel values representing an intensity of an incident light component for each visible color channel, and generate an image frame for each visible color channel. Moreover, 3D-imaging module 634 can generate a 3D image based on the digital values from photodiode 612d. In some examples, based on the digital values, 3D-imaging module 634 can detect a pattern of structured light reflected by a surface of an object, and compare the detected pattern with the pattern of structured light projected by illuminator 622 to determine the depths of different points of the surface with respect to the pixel cells array. For detection of the pattern of reflected light, 3D-imaging module 634 can generate pixel values based on intensities of infrared light received at the pixel cells. As another example, 3D-imaging module 634 can generate pixel values based on time-of-flight of the infrared light transmitted by illuminator 622 and reflected by the object.

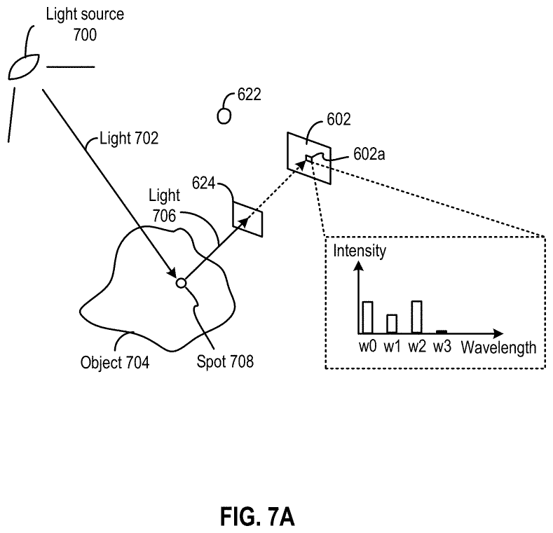

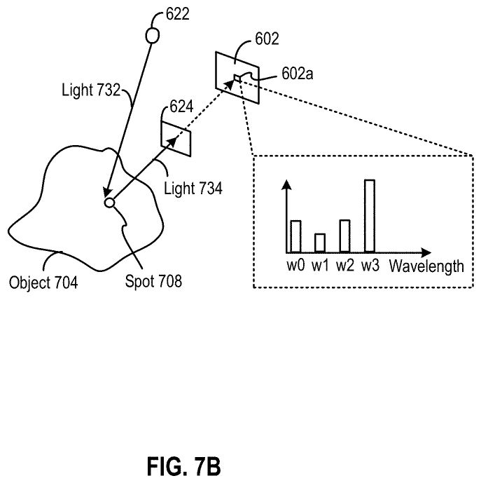

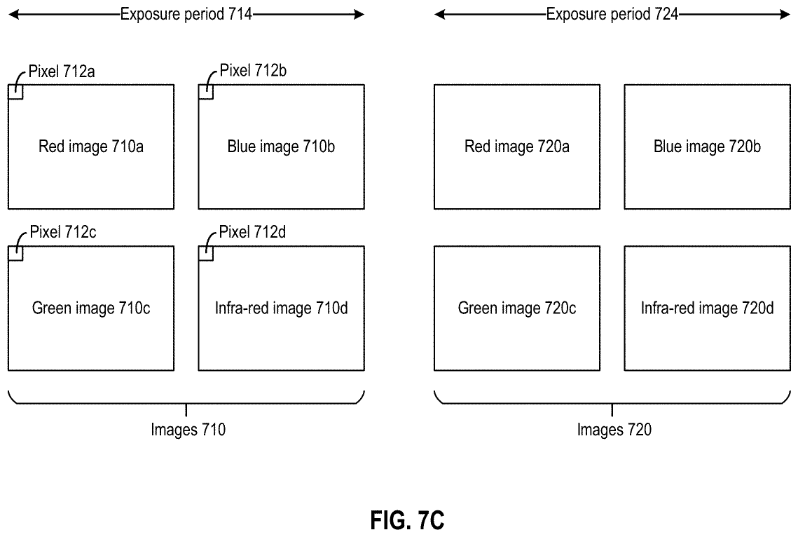

Image sensor 600 further includes a sensing controller 640 to control different components of image sensor 600 to perform 2D and 3D imaging of an object. Reference is now made to FIG. 7A FIG. 7C, which illustrate examples of operations of image sensor 600 for 2D and 3D imaging. FIG. 7A illustrates an example of operations for 2D imaging. For 2D imaging, pixel cell array 602 can detect visible light in the environment including visible light reflected off an object. For example, referring to FIG. 7A, visible light source 700 (e.g., a light bulb, the sun, or other sources of ambient visible light) can project visible light 702 onto an object 704. Visible light 706 can be reflected off a spot 708 of object 704. Visible light 706 can also include the ambient infrared light component. Visible light 706 can be filtered by optical filter array 624 to pass different components of visible light 706 of wavelength ranges w0, w1, w2, and w3 to, respectively, photodiodes 612a, 612b, 612c, and 612d of pixel cell 602a. Wavelength ranges w0, w1, w2, and w3 and correspond to, respectively, blue, green, red, and infrared. As shown in FIG. 7A, as the infrared illuminator 622 is not turned on, the intensity of infrared component (w3) is contributed by the ambient infrared light and can be very low. Moreover, different visible components of visible light 706 can also have different intensities. Charge sensing units 614 can convert the charge generated by the photodiodes to voltages, which can be quantized by ADCs 616 into digital values representing the red, blue, and green components of a pixel representing spot 708. Referring to FIG. 7C, after the digital values are generated, sensing controller 640 can control 2D-imaging module 632 to generate, based on the digital values, sets of images including a set of images 710, which includes a red image frame 710a, a blue image frame 710b, and a green image frame 710c each representing one of a red, blue, or green color image of a scene captured with the same exposure period 714. Each pixel from the red image (e.g., pixel 712a), from the blue image (e.g., pixel 712b), and from the green image (e.g., pixel 712c) can represent visible components of light from the same spot (e.g., spot 708) of a scene. A different set of images 720 can be generated by 2D-imaging module 632 in a subsequent exposure period 724. Each of red image 710a, blue image 710b, and green image 710c can represent the scene in a specific color channel and can be provided to an application to, for example, extract image features from the specific color channel. As each image represents the same scene and each corresponding pixel of the images represents light from the same spot of the scene, the correspondence of images between different color channels can be improved.

Furthermore, image sensor 600 can also perform 3D imaging of object 704. Referring to FIG. 7B, sensing controller 610 can control illuminator 622 to project infrared light 732, which can include a light pulse, structured light, etc., onto object 704. Infrared light 732 can have a wavelength range of 700 nanometers (nm) to 1 millimeter (mm). Infrared light 734 can reflect off spot 708 of object 704 and can propagate towards pixel cell array 602 and pass through optical filter 624, which can provide the infrared component (of wavelength range w3) to photodiode 612d to convert to charge. Charge sensing units 614 can convert the charge to a voltage, which can be quantized by ADCs 616 into digital values. Referring to FIG. 7C, after the digital values are generated, sensing controller 640 can control 3D-imaging module 634 to generate, based on the digital values, an infrared image 710d of the scene as part of images 710 captured within exposure period 714. As infrared image 710d can represent the same scene in the infrared channel and a pixel of infrared image 710d (e.g., pixel 712d) represents light from the same spot of the scene as other corresponding pixels (pixels 712a 712c) in other images within images 710, the correspondence between 2D and 3D imaging can be improved as well.

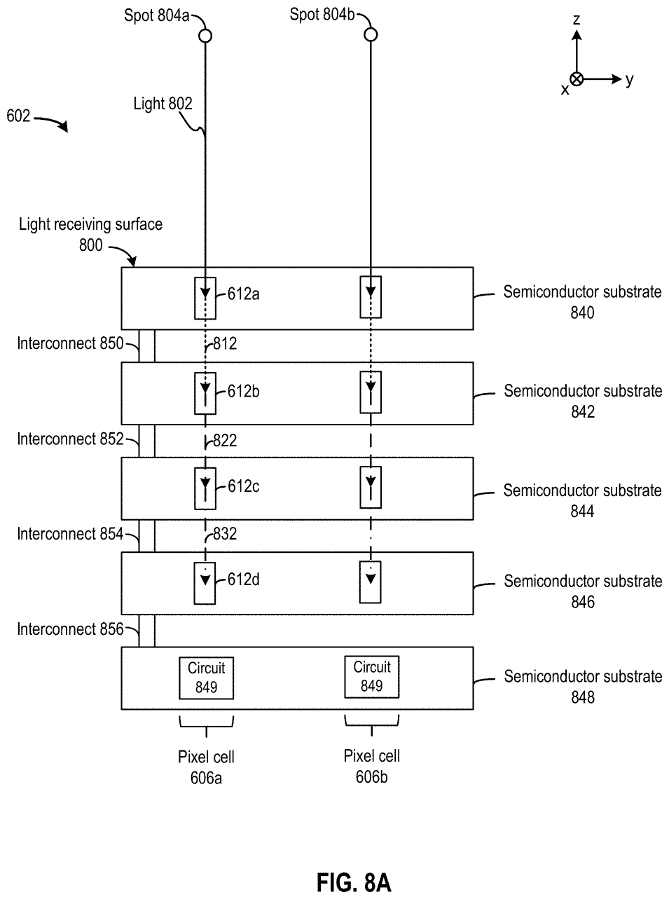

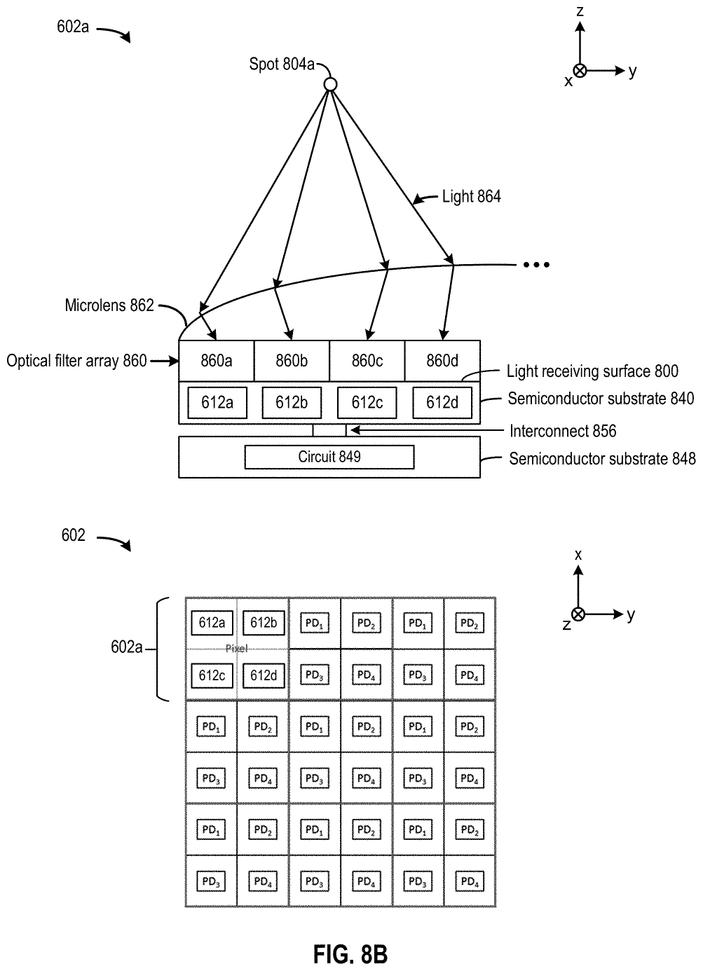

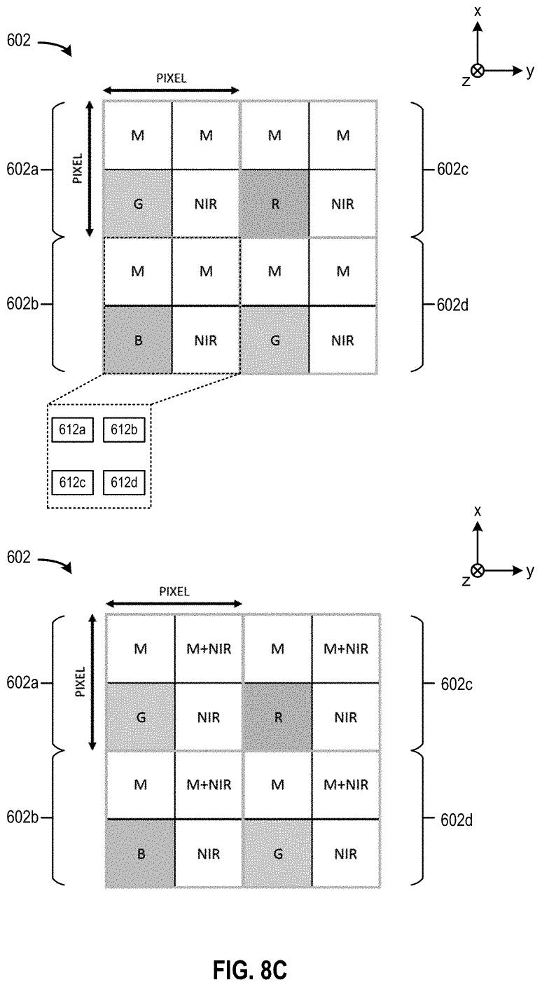

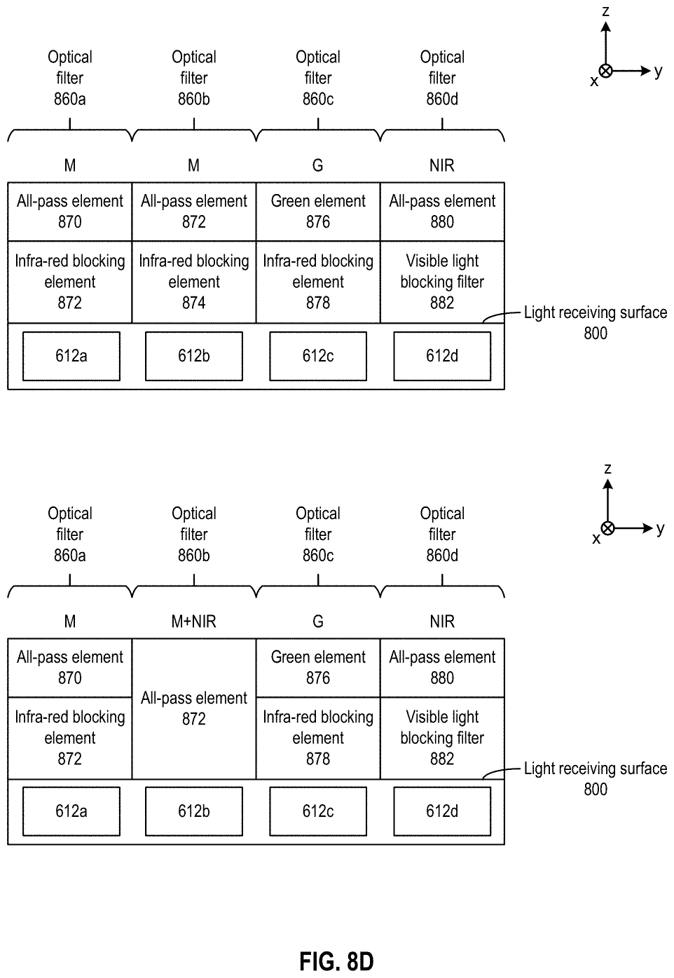

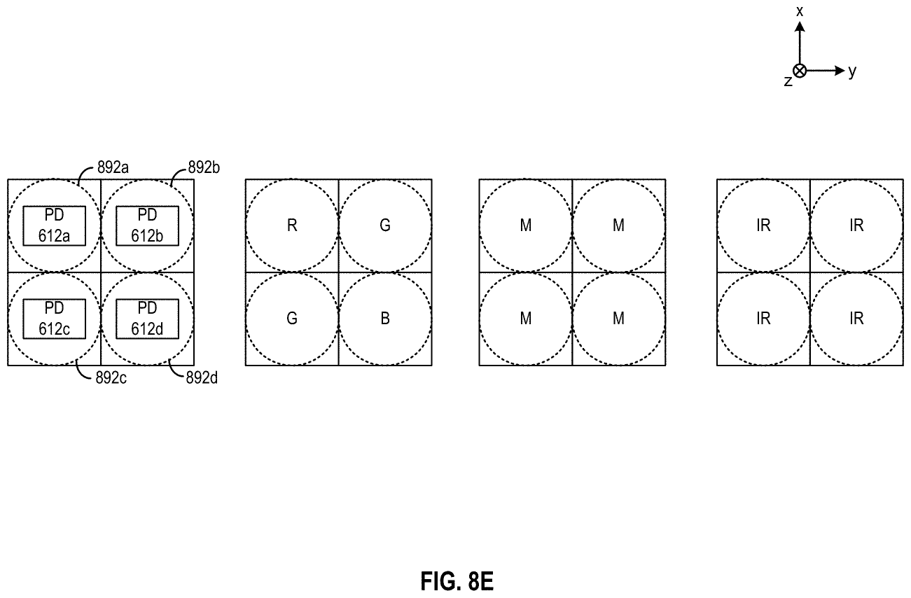

FIG. 8A FIG. 8E illustrate examples of arrangements of photodiodes 612 in an image sensor, such as within a pixel cell or between different pixel cells. As shown in FIG. 8A, the photodiodes 612a 612d in a pixel cell 602a can form a stack along an axis that is perpendicular to a light receiving surface 800 through which pixel cell 602a receives incident light 802 from a spot 804a. For example, the photodiodes 612a-612d can form a stack along a vertical axis (e.g., the z-axis) when the light receiving surface 800 is parallel with the x and y axes. Each photodiode can have a different distance from light receiving surface 800, and the distance can set the component of incident light 802 being absorbed and converted to charge by each photodiode. For example, photodiode 612a is closest to light receiving surface 800 and can absorb and convert the blue component to charge, which is of the shortest wavelength range among the other components. Light 812 includes the remaining components of light 802 (e.g., green, red, and infrared) and can propagate to photodiode 612b, which can absorb and convert the green component. Light 822 includes the remaining components of light 812 (e.g., red and infrared) and can propagate to photodiode 612c, which can absorb and convert the red component. The remaining infrared component 832 can propagate to photodiode 612d to be converted to charge.

Each the photodiodes 612a, 612b, 612c, and 612d can be in a separate semiconductor substrate, which can be stacked to form image sensor 600. For example, photodiode 612a can be in a semiconductor substrate 840, photodiode 612b can be in a semiconductor substrate 842, and photodiode 612c can be in a semiconductor substrate 844, whereas photodiode 612d can be in a semiconductor substrate 846. Each of substrates 840-846 can include a charge sensing unit, such as charge sensing units 614. Substrates 840-846 can form a sensor layer. Each semiconductor substrate can include other photodiodes of other pixel cells, such as pixel cells 602b to receive light from spot 804b. Image sensor 600 can include another semiconductor substrate 848 which can include pixel cell processing circuits 849 which can include, for example, ADCs 616, imaging module 628, sensing controller 640, etc. In some examples, charge sensing units 614 can be in semiconductor substrate 848. Semiconductor substrate 848 can form an application specific integrated circuit (ASIC) layer. Each semiconductor substrate can be connected to a metal interconnect, such as metal interconnects 850, 852, 854, and 856 to transfer the charge generated at each photodiode to processing circuit 849.

FIG. 8B-FIG. 8D illustrate other example arrangements of photodiodes 612 within a pixel cell. As shown in FIG. 8B-FIG. 8D, the plurality of photodiodes 612 can be arranged laterally, parallel with light receiving surface 800. The top graph of FIG. 8B illustrates a side view of an example of pixel cell 602a, whereas the bottom graph of FIG. 8B illustrates a top view of pixel array 602 including pixel cell 602a. The top graph and the bottom graph may illustrate two different example arrangements of photodiodes. For example, in the top graph four pixel cells 612a, 612b, 612c, and 612d can be arranged in a 4×1 pattern, while the bottom graph the four pixel cells are arranged in a 2×2 pattern.

As shown in FIG. 8B, with light receiving surface 800 being parallel with the x and y axes, photodiodes 612a, 612b, 612c, and 612d can be arranged adjacent to each other also along the x and y axes in semiconductor substrate 840. Pixel cell 602a further includes an optical filter array 860 overlaid on the photodiodes. Optical filter array 860 can be part of optical filter 624. Optical filter array 860 can include a filter element overlaid on each of photodiodes 612a, 612b, 612c, and 612d to set a wavelength range of an incident light component received by the respective photodiode. For example, filter element 860a is overlaid on photodiode 612a and can allow only visible blue light to enter photodiode 612a. Moreover, filter element 860b is overlaid on photodiode 612b and can allow only visible green light to enter photodiode 612b. Further, filter element 860c is overlaid on photodiode 612c and can allow only visible red light to enter photodiode 612c. Filter element 860d is overlaid on photodiode 612d and can allow only infrared light to enter photodiode 612d.

Pixel cell 602a further includes one or more microlens 862 which can project light 864 from a spot of a scene (e.g., spot 804a) via optical filter array 860 to different lateral locations of light receiving surface 800, which allows each photodiode to become a sub-pixel of pixel cell 602a and to receive components of light from the same spot corresponding to a pixel. In some examples, a single microlens 862 can be overlaid on multiple pixels as shown in FIG. 8B. In some examples, a single microlens 862 can be overlaid on a pixel, and each pixel can have a single microlens.

Pixel cell 602a can also include semiconductor substrate 848 which can include processing circuit 849 (e.g., charge sensing units 614, ADCs 616) to generate digital values from the charge generated by the photodiodes. Semiconductor substrates 840 and 848 can form a stack and can be connected with interconnect 856. In FIG. 8B, semiconductor substrate 840 can form a sensor layer, whereas semiconductor substrate 848 can form an ASIC layer.

The arrangements of FIG. 8B, in which the photodiodes are arranged laterally and an optical filter array is used to control the light components received by the photodiodes, can offer numerous advantages. For example, the number of stacks and the number of semiconductor substrates can be reduced, which not only reduce the vertical height but also the interconnects among the semiconductor substrates. Moreover, relying on filter elements rather than the propagation distance of light to set the wavelength ranges of the components absorbed by each photodiode can offer flexibilities in selecting the wavelength ranges. As shown in top graph of FIG. 8C, pixel cell array 602 can include different optical filter arrays 860 for different pixel cells. For example, each pixel cell of pixel cell array 602 can have an optical filter array that provides monochrome channel of a wavelength range of 380-740 nm (labelled with “M”) for photodiodes 612a and 612b, and an infrared channel of a wavelength range of 700-1000 nm (labelled with “NIR”) for photodiode 612d. But the optical filter arrays may also provide a different visible color channel for the different pixel cells. For example, the optical filter arrays 860 for pixel cells array 602a, 602b, 602c, and 602d may provide, respectively, a visible green channel (labelled with “G”), a visible red channel (labelled with “R”), a visible blue channel (labelled with “B”), and a visible green channel for photodiode 612c of the pixel cells arrays. As another example, as shown in the bottom graph of FIG. 8C, each optical filter array 860 can provide a monochrome and infrared channel (labelled “M+NIR”) which spans a wavelength range of 380-1000 nm for photodiode 612b of each pixel cells array.

FIG. 8D illustrates examples of optical filter array 860 to provide the example channels shown in FIG. 8C. As shown in FIG. 8D, optical filter array 860 can include a stack of optical filters to select a wavelength range of light received by each photodiode within a pixel cell array. For example, referring to the top graph of FIG. 8D, optical filter 860a can include an all-pass element 870 (e.g., a transparent glass that passes both visible light and infrared light) and an infrared blocking element 872 forming a stack to provide a monochrome channel for photodiode 612a. Optical filter 860b can also include an all-pass element 874 and an infrared blocking element 876 to also provide a monochrome channel for photodiode 612b. Further, optical filter 860c can include a green-pass element 876 which passes green visible light (but reject other visible light component), and an infrared blocking element 878, to provide a green channel for photodiode 612c. Lastly, optical filter 860d can include an all-pass element 880 and a visible light blocking filter 882 (which can block out visible light but allows infrared light to go through) to provide an infrared channel for photodiode 612d. In another example, as shown in the bottom graph of FIG. 8D, optical filter 860b can include only all-pass element 872 to provide a monochrome and infrared channel for photodiode 612b.

FIG. 8E illustrates another example of optical configurations of photodiodes 612. As shown in FIG. 8E, instead of overlaying a microlens 862 over a plurality of photodiodes, as shown in FIG. 8B, a plurality of microlenses 892 can be overlaid over the plurality of photodiodes 612a 612d, which are arranged in a 2×2 format. For example, microlens 892a can be overlaid over photodiode 612a, microlens 892b can be overlaid over photodiode 612b, and microlens 892c can be overlaid over photodiode 612c, whereas microlens 892d can be overlaid over photodiode 612d. With such arrangements, each photodiode can correspond to a pixel, which can shrink the required footprint of pixel cell array to achieve a target resolution.

Different patterns of filter arrays can be inserted between plurality of microlenses 862 and plurality of photodiodes 612. For example, as shown in FIG. 8E, a 2×2 color filter pattern comprising red (R), green (G), and blue (B) filters can be inserted between the microlenses and the photodiodes. Moreover, an all-pass filter pattern can also be inserted between the microlenses and the photodiodes so that each photodiode detects a monochrome channel. Also, an infrared filter pattern can be inserted between the microlenses and the photodiodes so that each photodiode detects infrared light.

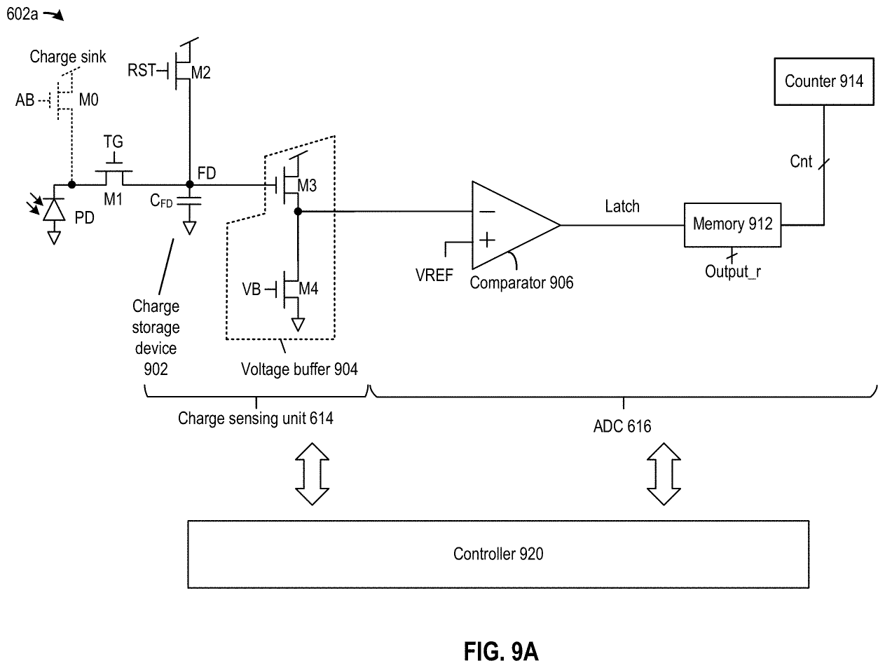

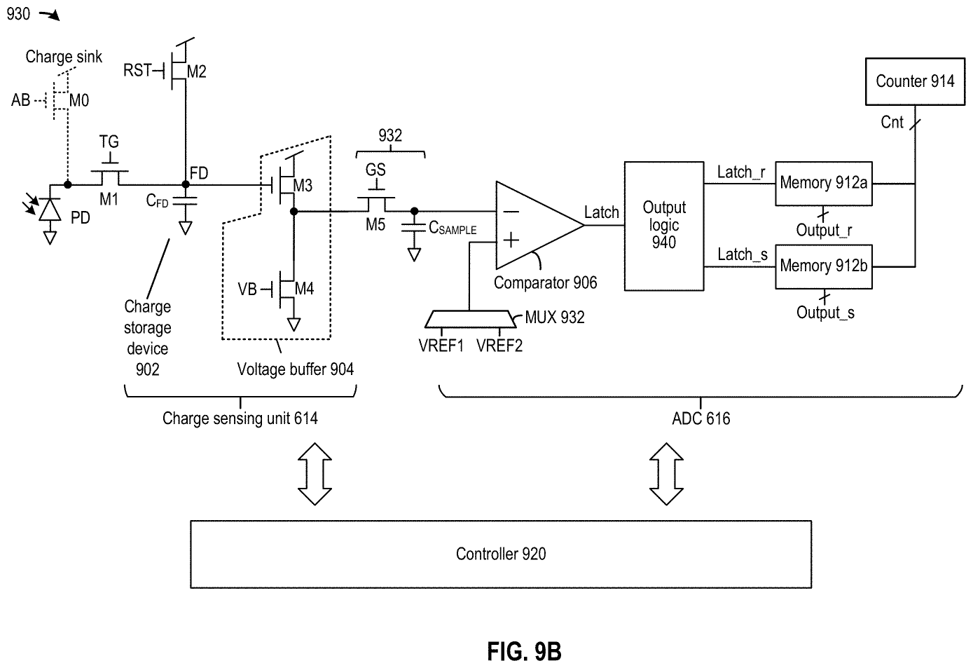

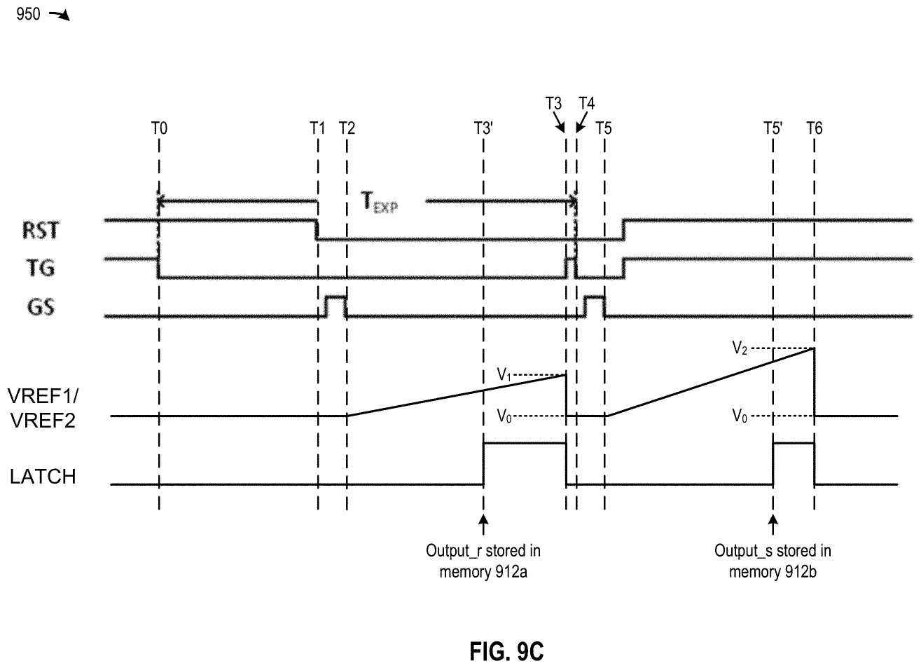

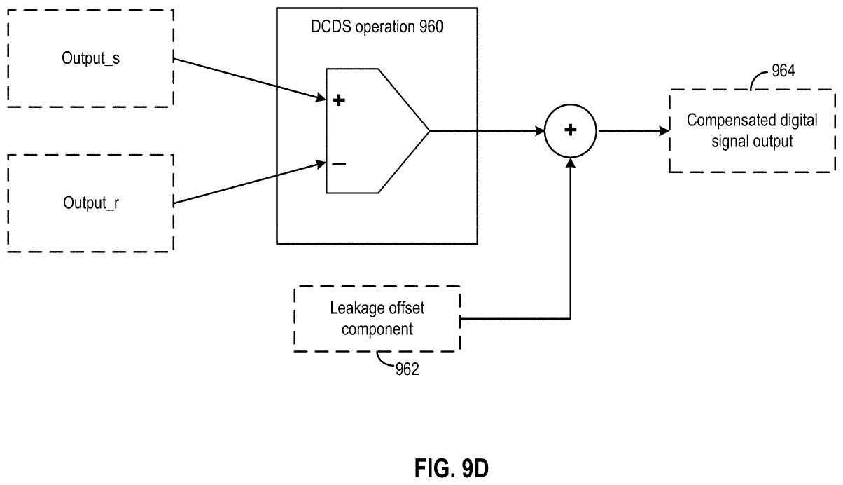

Reference is now made to FIG. 9A, which illustrates additional components of pixel cell 602a, including an example of charge sensing unit 614 and ADC 616. As shown in FIG. 9, pixel cell 602a can include a photodiode PD (e.g., photodiode 612a), an optional transistor M0 configured as a charge draining switch controlled by a control signal AB, and a transistor M1 configured as a charge transfer switch controlled by a control signal TG. Pixel cell 602 further includes a charge sensing unit 614, which includes a floating diffusion (FD) configured as charge storage device 902, a transistor M2 configured as a reset switch and controlled by a control signal RST to reset charge storage device 902, and a voltage buffer 904. Voltage buffer 904 includes a transistor M3 configured as a source follower and a transistor M4 to provide bias current to the source follower. Charge sensing unit 614 can receive the charge from photodiode PD and store the charge at charge storage device 902 to convert the charge to a voltage, which can then be buffered by voltage buffer 904.

Pixel cell 602a further includes an ADC 616 comprising a comparator 906, a memory 912, and a counter 914. Any one of comparator 906, memory 912, and counter 914 can be external to pixel cell 602a. ADC 616 can be used to quantize an output voltage of voltage buffer 904 to generate a digital output representing the quantity of charge stored at charge storage device 902. The digital output can also represent the quantity of charge generated by the photodiode PD, as well as the intensity of light received by the photodiode. To perform the quantization operation, comparator 906 can compare the output voltage with a VREF voltage ramp, which increases or decreases (continuously or in steps) with time within a voltage range. Counter 914 can also start counting at the beginning of the VREF voltage ramp. If the output voltage of voltage buffer 904 is within the voltage range, the output voltage can intersect with the VREF voltage ramp. When this happens, the output of comparator 906 can trip and generate a latch signal, which causes memory 912 to store a count value from counter 914. The stored count value can represent a time when the output voltage intersects with the VREF voltage ramp and can provide a digital representation of the output voltage.

Pixel cell 602a further includes a controller 920 to control the transistors, charge sensing unit 614, as well as ADC 616, by providing the control signals AB, TG, RST, etc. As to be described below, controller 920 can set an exposure period in which photodiode PD can generate and accumulate charge in response to incident light by controlling the TG and RST (and optional AB) signals. The controller can also control the transfer of charge from the photodiode PD to charge storage device 902 to convert the charge to a voltage, and control ADC 616 to perform the quantization operation above.

As described above, there are various performance metrics for an image sensor. One performance metric of an image sensor is a range of measurable light intensity, which determines the range of light intensity in which the digital output generated by a pixel cell is correlated to the intensity of light received by that pixel cell. The range of measurable light intensity can be characterized by the dynamic range of the image sensor, which can be defined by a ratio between an upper limit of the measurable light intensity and a lower limit of the measurable light intensity. A wide dynamic range is desirable as the image sensor may operate in environments with a very wide range of light intensities.

The degree of correlation between the digital output generated by a pixel cell and the intensity of light received by that pixel cell can vary. The degree of correlation can be affected by various factors. For example, referring to FIG. 9A, when operating in a strong ambient light environment, the floating diffusion FD can become saturated by the charge generated by the photodiode PD and cannot take in additional charge. As a result, the quantity of the charge stored at the floating diffusion may be lower than the quantity of charge actually generated by the photodiode. The intensity of light that causes the floating diffusion to saturate can define an upper limit of the measurable light intensity of the image sensor.

In addition, when operating in a low ambient light environment, the charge stored at the floating diffusion FD can include electronic noise charge (e.g., thermal noise, flicker noise, etc.) not related to the intensity of incident light, as well as dark charge contributed by dark current. The measurement of low intensity light can also be affected by measurement errors. For example, leakage of charge may occur at the floating diffusion FD prior to the quantization operation by ADC 616, such that the charge being measured no longer represents the total charge generated by the photodiode PD during the exposure period, and a measurement error is introduced. In addition, the offset of comparator 906, as well as threshold voltage mismatches between voltage buffers 904, can also add to an error component in the digital output. The error components can appear as fixed pattern noises (FPN) in the digital outputs of the pixel cell array, where different pixel cells may have different comparator offsets, voltage buffer thresholds, and/or charge leakage rates. If the light intensity is sufficiently low, the quantity of charge actually generated by the photodiode and stored in the floating diffusion can also become so low that the charge is indistinguishable from the error component caused by the noises and the measurement errors. The error component can define a lower limit of the measurable light intensity of the image sensor.

FIG. 9B and FIG. 9C illustrate examples of a pixel cell 930 that can extend the lower limit of the measurable light intensity, thereby providing an extended dynamic range, compared with pixel cell 602a. As shown in FIG. 9B, pixel cell 930 can include a sample-and-hold (S/H) circuit 932 coupled between charge sensing unit 614 and ADC 616. S/H circuit 932 can including a transistor M5 configured as a sampling switch controlled by a control signal GS, and a sampling capacitor CSAMPLE. S/H circuit 932 can sample the output voltage of voltage buffer 904 and store the sampled output voltage as charge in the sampling capacitor CSAMPLE. ADC 616 can then perform the quantization of the sampled output voltage. Sampling capacitor CSAMPLE can include a metal capacitor and can have a much larger capacitance than the capacitance of floating diffusion CFD, and the sampled output voltage at sampling capacitor CSAMPLE can experience less leakage compared with the voltage at the floating diffusion FD. Moreover, the metal sampling capacitor is also less susceptible to dark charge. Such arrangements can reduce the measurement error of the photodiode charge at the floating diffusion FD caused by charge leakage and dark charge introduced prior to the quantization operation by ADC 616.

In addition, ADC 616 can include a memory 912a and a memory 912b, and an output logic 940, to support quantization operations of a signal voltage at floating diffusion FD after the charge is transferred from photodiode PD to the floating diffusion FD, and of a reset voltage at floating diffusion FD when the floating diffusion is being reset. Comparator 906 is also coupled with a multiplexor circuit 934, which can be controlled by controller 920 to select one of a first VREF ramp (VREF1) or a second VREF ramp (VREF2) to support the quantization operations of the signal voltage and the rest voltage. The reset voltage, buffered by voltage buffer 904, can be quantized by comparator 906 to generate a digital reset value output_r. Output logic 940 can route the output of comparator 906 to memory 912a to store the digital reset value output_r at memory 912a. After the floating diffusion FD exits the reset state and receives charge from the photodiode PD, a signal voltage can be established at floating diffusion FD. ADC 616 can quantize the signal voltage to generate a digital signal value output_s. Output logic 940 can route the output of comparator 904 to memory 912b to store the digital reset value output_s at memory 912b.

FIG. 9C illustrates a chart 950 of a sequence of control signals provided by controller 920 for pixel cell 930. In chart 950, the exposure period TEXP for photodiode PD starts at time T0. Prior to the start of the exposure period, RST and TG can be asserted to reset both the photodiode PD and the floating diffusion FD.

Between times T0 and T1, TG can be de-asserted to disconnect the photodiode PD from the floating diffusion FD, which remains in the reset state. Photodiode PD can generate and accumulate photo charge. Meanwhile, floating diffusion FD can output a reset voltage, which can be buffered by voltage buffer 904. The reset voltage can represent electronic noise charge (e.g., thermal noise, flicker noise, etc.) introduced by the reset switch M2. The reset voltage can also include a measurement error introduced by the source follower of voltage buffer 904 due to threshold voltage mismatch with other voltage buffer 904 used by other pixel cells. Between times T1 and T2, the floating diffusion can exit the reset state. The GS signal can be asserted to enable S/H circuit 932 to sample and hold the reset voltage.

Between times T2 and T3, ADC 616 can perform a first quantization operation to quantize the sampled reset voltage by comparing the sampled reset voltage with the first VREF ramp (VREF1), while counter 914 starts counting at time T2. The first VREF ramp can have a voltage range of V0 to V1. As the reset voltage can correspond to a dark pixel value with zero photo charge, the voltage range V0-V1 is typically much smaller than a voltage range of the second VREF ramp (VREF2) used to quantize the signal voltage generated from a finite quantity of photo charge. At time T3′, the first VREF ramp intersects with the reset voltage, which causes the output of comparator 906 (labelled Latch in FIG. 9B) to trip. Output logic 940 can route the output of comparator 906 as a latch_r signal to memory 912a, which causes memory 912a to store a count value from counter 914 as a digital reset value output_r. The digital reset value output_r can include an error component contributed by the aforementioned electronic noise charge, the source follower threshold mismatch, as well as the offset of comparator 906.

Between times T3 and T4, after the quantization operation of the reset voltage completes, the TG signal is asserted to transfer the photo charge from the photodiode PD to the floating diffusion FD, to establish a signal voltage. The signal voltage can include a signal component contributed by the photo charge, as well as the electronic noise charge introduced by the reset switch and the threshold mismatch error introduced by voltage buffer 904. After the transfer of the photo charge completes, the TG signal is de-asserted at time T4, which marks the end of the exposure period TEXP. Between times T4 and T5, the GS signal can be asserted to enable S/H circuit 932 to sample and hold the signal voltage.

Between times T5 and T6, ADC 616 can perform a second quantization operation to quantize the sampled signal voltage by comparing the sampled signal voltage with a second VREF ramp, while counter 914 starts counting at time T5. The second VREF ramp can have a voltage range of V0 to V2 larger than the voltage range of the first VREF ramp to measure a finite quantity of photo charge generated by the photodiode PD, as explained above. At time T5′, the second VREF ramp intersects with the signal voltage, which causes the output of comparator 906 to trip. Output logic 940 can route the output of comparator 906 as a latch_s signal to memory 912b, which causes memory 912b to store a count value from counter 914 as a digital signal value output_s. The digital signal value output_s can include the signal component contributed by the photo charge, as well as the same error component in digital reset value output_r contributed by the electronic noise charge, the source follower threshold mismatch, as well as the offset of comparator 906.

A downstream image processor (not shown in the figures) can perform a readout of the digital reset value output_r and the digital signal value output_s from, respectively, memory 912a and memory 912b, and perform a post-processing operation to improve the correlation between the digital signal output and the intensity of light received by photodiode PD. For example, the image processor can perform a digital correlated double sampling (CDS) operation. As described above, the error component contributed by the electronic noise charge, the source follower threshold mismatch, and the offset of comparator 906 are present in both the digital reset value and in the digital signal value. A digital CDS operation 960 can be performed by subtracting the digital reset value output_r from the digital output signal value output_s to remove the error component.

In additional to digital CDS operation, other post-processing operations, such as leakage compensation, can also be performed. Specifically, if the first quantization operation and the second quantization operation are separated by a long duration, some of the reset noise charge may be reduced due to charge leakage when the second quantization operation starts, such that the digital reset value output_r no longer accurately represents the error component present in the signal voltage. To compensate for the effect of leakage, a leakage offset component 962 can be added to (or subtracted from) the digital output signal value output_s after the digital CDS operation as shown in FIG. 9D, or to the digital reset value prior to the digital CDS operation, to generate a compensated digital signal output 964 to represent the intensity of light received by the photodiode PD within the exposure period TEXP. The leakage offset component can be determined from a calibration operation.

Although the pixel cell of FIG. 9B can provide improved performance, having a dedicated comparator for each photodiode and/or for each pixel cell can substantially increase the power consumption and footprint of the pixel cell. This is because the comparator is typically built using analog processes and typically have much bigger footprints than the photodiode. The comparator also uses a lot of power. If a dedicated comparator is to be provided for each photodiode, the number of pixel cells that can be included in a pixel cell array of an image sensor may be reduced due to the limited available space and power of a wearable device, which in turn can reduce the resolution of the image sensor.

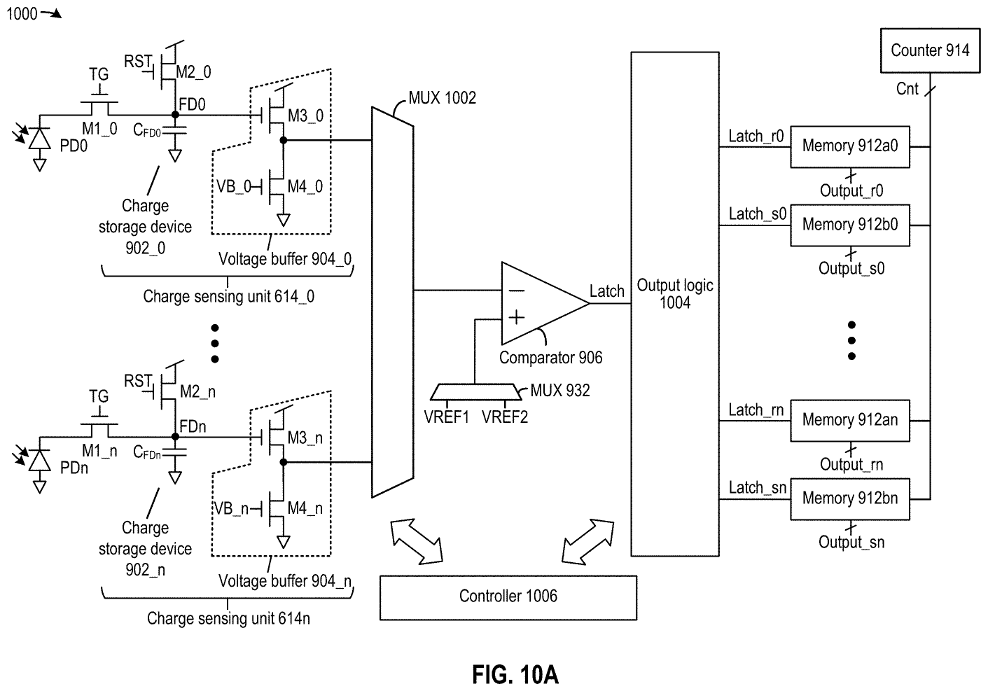

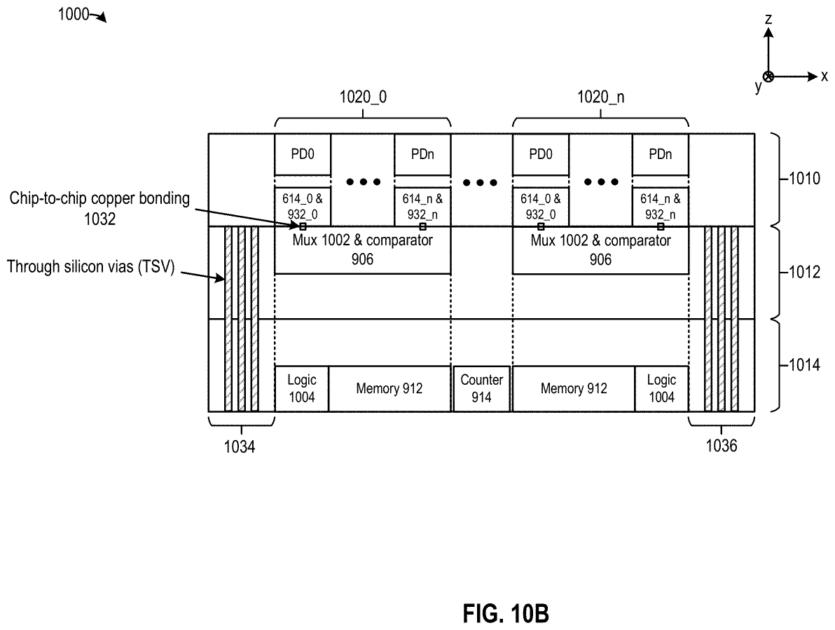

FIG. 10A and FIG. 10B illustrate examples of an image sensor 1000 that can provide reduced footprint and power. As shown in FIG. 10A, image sensor 1000 includes multiple photodiodes PD0-PDn. In some examples, the photodiodes PD0-PDn can be the photodiodes of a multi-photodiode pixel cell, such as pixel cell 602a of FIG. 6. In some examples, the photodiodes PD0-PDn can be part of a block of pixel cells. For example, PD0-PDn can be part of a block of two, four, or eight pixel cells.

Each photodiode can be associated with a charge sensing unit including a transfer switch, a floating diffusion, a reset switch, and a voltage buffer. For example, photodiode PD0 is associated with a charging sensing unit 614_0 that includes a transfer switch M1_0, a reset switch M2_0, a floating diffusion FD0 (represented by a capacitor CFD0) configured as charge storage device 902_0, and a voltage buffer 904_0. Moreover, photodiode PDn is associated with a charging sensing unit 614_n including a transfer switch M1_n, a reset switch M2_n, a floating diffusion FDn (represented by a capacitor CFDn) configured as charge storage device 902_n, and a voltage buffer 904_n. In some examples, image sensor 1000 further includes a sample-and-hold (S/H) circuit coupled with the voltage buffer to sample and hold the output voltage, in a similar arrangement as shown in FIG. 9B.

Image sensor 1000 further includes comparator 906, and a set of memory 912a0-912an and memory 912b0-912bn. Comparator 906 can be shared among photodiodes PD0-PDn, and their associated charge sensing units, to perform quantization operations. The quantization operations can be performed to generate a digital reset value and a digital signal value for each photodiode, and the digital values can be stored at the two sets of memory. For example, memory 912a0 and memory 912b0 can store, respectively, a digital reset value and a digital signal value for photodiode PD0, whereas memory 912an and memory 912bn can store, respectively, a digital reset value and a digital signal value for photodiode PDn.

Image sensor 1000 further includes a multiplexor circuit 1002, and a controller 1006. Multiplexor circuit 1002 is coupled between comparator 906 and each of charge sensing units 614_0-614_n (or the output of S/H circuits 932, not shown in FIG. 10A). Multiplexor circuit 1002 can be controlled by controller 1006 to sequentially couple the output of each charge sensing unit to comparator 906 to perform quantization operations for the charge sensing unit. As to be described below, multiplexor circuit 1002 can include a network of switches, a set of switchable source followers, etc.

Controller 1006 can generate the control signals TG and RST to enable each of photodiodes PD0-PDn to generate and accumulate charge in the same global exposure period to perform a global shutter operation. During the global exposure period, controller 1006 can assert the RST signal to reset the floating diffusions FD0-FDn so that each charge sensing unit can output a reset voltage that can include electronic noise charge and measurement error introduced by the charge sensing unit, while de-asserting the TG signal to disconnect the photodiode from the floating diffusion.

During the global exposure period, controller 1006 can also control multiplexor circuit 1002 to sequentially couple the output of each charge sensing unit to comparator 906 to quantize the reset voltage of each charge sensing unit to generate a digital reset value. Referring back to FIG. 9C, controller 1006 can control multiplexor circuit 934 to forward the first VREF ramp (VREF1) to comparator 906. Comparator 906 can then compare the reset voltage of each charge sensing unit with VREF1 to generate a decision. Controller 1006 can control output logic 1004 to route the decision to the memory for that charge sensing unit to store the digital reset value. For example, when comparator 906 compares the reset voltage of charge sensing unit 614_0 with VREF1, controller 1006 can control output logic 1004 to route the decision of comparator 906 (latch signal in FIG. 10A) to memory 912a0 as latch_r0 signal, to store a count value from counter 914 at memory 912a0 as a digital reset value for charge sensing unit 614_0. Moreover, when comparator 906 compares the reset voltage of charge sensing unit 614_n with VREF1, controller 1006 can control output logic 1004 to route the decision of comparator 906 to memory 912an as latch_rn signal, and store a count value from counter 914 at memory 912an as a digital reset value for charge sensing unit 614_n.

After the global exposure period ends, controller 1006 can de-assert the RST signal to release the reset of each of floating diffusions FD0-FDn, and assert the TG signal to transfer the charge generated and accumulated by each photodiode during the global exposure period to the floating diffusion of the charge sensing unit associated with the photodiode. For example, charge accumulated at photodiode PD0 can be transferred to floating diffusion FD0 to generate a signal voltage, which can be buffered by voltage buffer 904_0, and the buffered voltage can be sampled by a S/H circuit 932 coupled with voltage buffer 904_0 (not shown in FIG. 10A). Moreover, charge accumulated at photodiode PDn can be transferred to floating diffusion FDn to generate another signal voltage, which can be buffered by voltage buffer 904_n, and the buffered voltage can be sampled by another S/H circuit 932 coupled with voltage buffer 904_n (not shown in FIG. 10A).

After the charge transfer between each photodiode and the associated charge sensing unit completes, controller 1006 can control multiplexor circuit 1002 to sequentially couple the output of each charge sensing unit to comparator 906 to quantize the signal voltage of each charge sensing unit to generate a digital signal value. Referring back to FIG. 9C, controller 1006 can control multiplexor circuit 934 to forward the second VREF ramp (VREF2) to comparator 906. Comparator 906 can then compare the signal voltage of each charge sensing unit with VREF2 to generate a decision. Controller 1006 can control output logic 1004 to route the decision to the memory for that charge sensing unit to store the digital signal value. For example, when comparator 906 compares the reset voltage of charge sensing unit 614_0 with VREF2, controller 1006 can control output logic 1004 to route the decision of comparator 906 (latch signal in FIG. 10A) to memory 912a0 as latch_r0 signal, to store a count value from counter 914 at memory 912a0 as a digital signal value for charge sensing unit 614_0. The digital signal value at memory 912a0 can represent the intensity of light detected by photodiode PD0. Moreover, when comparator 906 compares the reset voltage of charge sensing unit 614_n with VREF1, controller 1006 can control output logic 1004 to route the decision of comparator 906 to memory 912an as latch_rn signal, to store a count value from counter 914 at memory 912an as a digital signal value for charge sensing unit 614_n. The digital signal value at memory 912an can represent the intensity of light detected by photodiode PDn.

FIG. 10B illustrates an example physical arrangement of image sensor 1000. Referring to FIG. 10B, components of image sensor 1000 can be implemented in multiple semiconductor layers arranged in a stack (e.g., along the z-axis). For example, the photodiodes (PD0, PDn, etc.) and their associated charge sensing units (charge sensing units 614_0, 614_n, etc.) and S/H circuits (e.g., S/H 932_0, S/H 932_n, etc.) can be implemented in semiconductor layer 1010, whereas comparators 906 can be implemented in semiconductor layer 1012. Depending on its implementation, multiplexor circuit 1002 can be implemented in semiconductor layer 1010 with charge sensing circuits 614 and S/H circuits, or can be implemented in semiconductor layer 1012 with comparator 906 as shown in FIG. 10B. Output logic 1004, a set of memory 912 (e.g., memory 912a0-912an and 912b0-912bn), controller 1006 (not shown in FIG. 10B) and counter 914 can be implemented in semiconductor layer 1014. In a case where image sensor 1000 includes S/H circuits coupled with the outputs of voltage buffer 904/charge sensing unit 614, the sampling capacitors of the S/H circuits can be implemented as metal capacitors sandwiched between semiconductor layers 1010 and 1012. The stack arrangements where large footprint components such as analog comparators are positioned below the photodiodes can reduce the total footprint (along the x-y axes) of image sensor 1000. Moreover, the routing distances of critical signals, such as connections between multiplexor circuit 1002 and comparator 906, the connections between output of comparator 906 and memory 912, etc., can be reduced to facilitate transmission of critical signals.

Groups of photodiodes and their associated charge sensing units and S/H circuits can share a set of multiplexor circuit 1002 and comparator 906 and a set of memory 912. For example, a group 1020_0 of photodiodes PD0-PDn can share a multiplexor circuit 1002, a comparator 906, and memory 912, whereas another group 1020_n of photodiodes PD0-PDn can share another multiplexor circuit 1002, comparator 906, and memory 912.

Image sensor 1000 further includes vertical interconnects to connect between circuit components implemented in different semiconductor layers. As described above, the stack arrangements allow reduction of routing distances of critical signals, and vertical interconnects can be used to transmit those critical signals. For example, image sensor 1000 can include chip-to-chip copper bonding 1032 between semiconductor layers 1010 and 1012. In a case where multiplexor circuits 1002 are implemented in semiconductor layer 1012, chip-to-chip copper bonding 1032 can provide electrical connections between the outputs of charge sensing units 614 (or S/H circuits) and the inputs of multiplexor circuits 1012. In a case where multiplexor circuits 1002 are implemented in semiconductor layer 1010, chip-to-chip copper bonding 1032 can provide electrical connections between the outputs of multiplexor circuits 1012 and the inputs of comparators 906. In addition, image sensor 1000 can include through silicon vias (or micro TSVs) 1034 and 1036 that connect between semiconductor layers 1012 and 1014. The TSVs can provide, for example, electrical connections between comparator 906 and memory 912, as well as electrical connections between controller 1006 and charge sensing units 614 and S/H circuits 932 to transmit control signals.

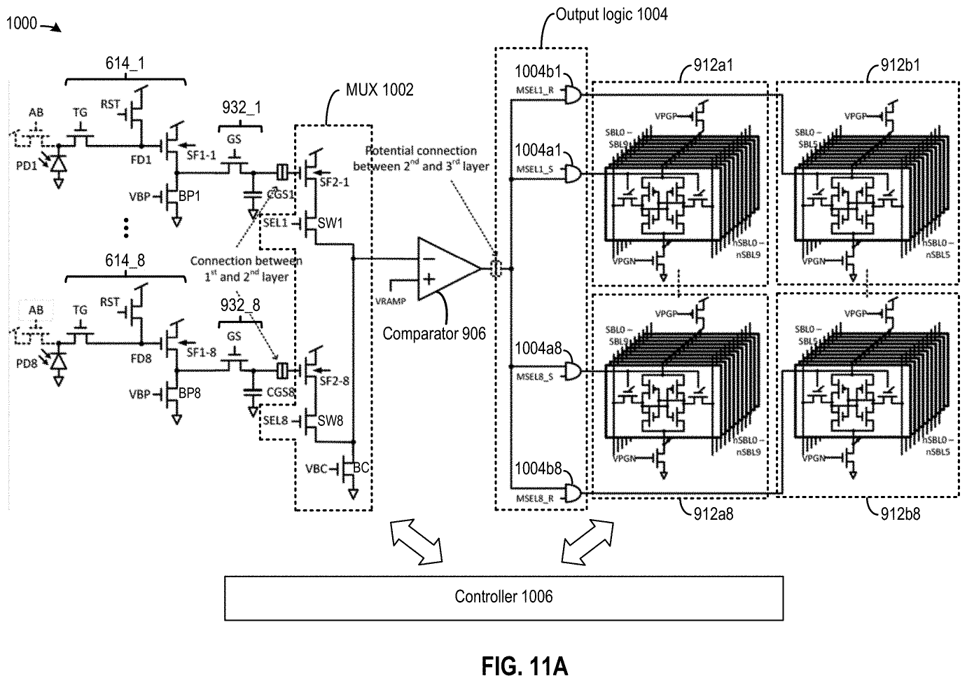

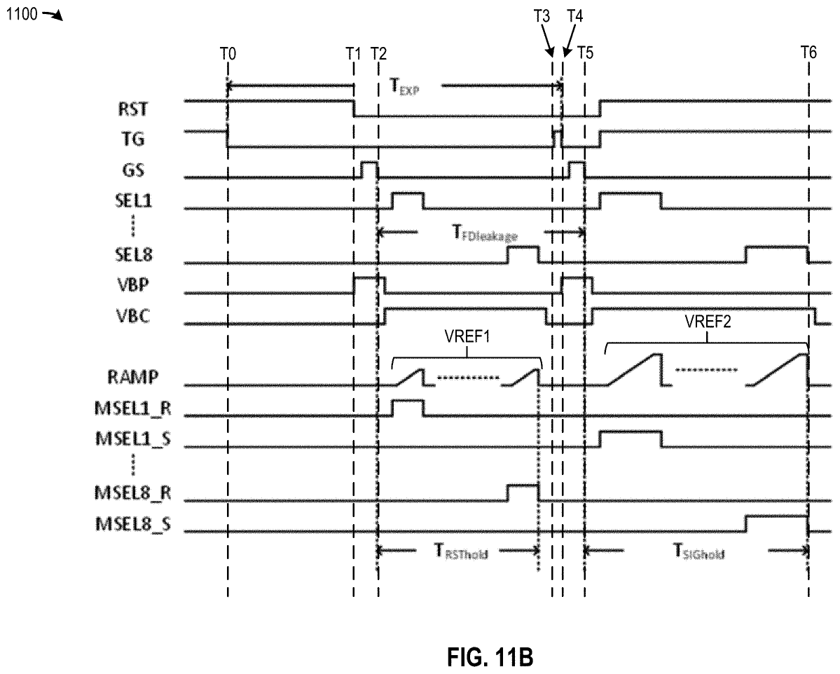

FIG. 11A and FIG. 11B illustrate additional examples of image sensor 1000 and their operations. FIG. 11A illustrates an example of image sensor 1000 where eight photodiodes PD1-PD8 and their associated charge sensing units 614_1-614_8 share a comparator 906. Each charge sensing unit includes a floating diffusion (e.g., FD1, FD8, etc.) and a voltage buffer including a source follower (e.g., SF1-1, SF1-8, etc.) and a current source (e.g., BP-1, BP-8, etc.). Each charge sensing unit is coupled with an S/H circuit 932, each including a sampling switch controlled by the GS control signal and a sampling capacitor (CGS1, CGS8, etc.). For example, charge sensing unit 614_1 of photodiode PD1 is coupled with S/H circuit 932_1, whereas charge sensing unit 614_n of photodiode PDn is coupled with S/H circuit 932_n. In the example of FIG. 11A, the photodiodes, charge sensing units 614, and S/H circuits 932 can be in a first semiconductor layer, such as semiconductor layer 1010 of FIG. 10B.

The outputs of S/H circuits 932 are coupled with comparator 906 via multiplexor circuit 1002. In FIG. 11A, multiplexor circuit 1002 can include a network of source followers, including SF2-1-SF2-8, with each source follower coupled with a S/H circuit 932 of a charge sensing unit 614. Each source follower of multiplexor circuit 1002 is coupled with the input of comparator 906 via a switch. For example, source follower SF2-1 is coupled with the input of comparator 906 and a current source BC via a switch SW1 controlled by an SEL1 control signal, whereas source follower SF2-8 is coupled with the input of comparator 906 and the current source BC via a switch SW8 controlled by an SEL8 control signal. Controller 1006 can sequentially assert SEL1-SEL8 signals to sequentially couple each of source followers SF2-1-SF2-8 to comparator 906. In FIG. 11A, multiplexor circuit 1002 and comparator 906 can be formed in a second semiconductor layer, such as semiconductor layer 1012 of FIG. 10B.

In FIG. 11A, the source followers of multiplexor circuit 1002 can provide various performance advantages. For example, the source followers can improve the driving strength and bandwidth in driving the input terminal of comparator 906, as well as the interconnects between the sampling capacitors and the input terminal of comparator 906, all of which can have substantial parasitic capacitances. Moreover, the source followers can isolate the sampling capacitors from the input terminal of comparator 906 when the sampling switches are not yet enabled to couple the sampling capacitors with the input of comparator 906. Such arrangements can reduce the effect of leakage of charge via the disabled sampling switches on the input voltage of comparator 906, to ensure that the input voltage closely follows a sampled signal voltage when the input is selectively coupled with the sampling capacitor.

In addition, memory 912 includes, for example, memory 912a1, 912b1, 912a8, 912b8, etc. Each memory 912 can include a bank of SRAM devices to store a digital reset value or a digital signal value. Each bank of SRAM devices is coupled with a word line (WL) which is driven by output logic 1004. Output logic 1004 can include a set of logic gates, such AND gates, each to route the output of comparator 906 to the word line of one of memory 912. For example, AND gate 1004a1 routes the output of comparator 906 to the word line of memory 912a1, AND gate 1004b1 routes the output of comparator 906 to the word line of memory 912b1, AND gate 1004a8 routes the output of comparator 906 to the word line of memory 912a8, whereas AND gate 1004b8 routes the output of comparator 906 to the word line of memory 912b8. Each AND gate can receive a control signal (e.g., MSEL1_S, MSEL_R, MSEL8_S, MSEL8_R, etc.) from controller 1006 to route the output of comparator 906 to the appropriate memory during the quantization operations of the reset voltages and the signal voltages for different photodiodes.

FIG. 11B illustrates a chart 1100 of a sequence of control signals provided by controller 1006 for the example of image sensor 1000 of FIG. 11A. In chart 1100, a global exposure period TEXP for photodiodes PD1-PD8 starts at time T0. Prior to the start of the exposure period, RST and TG can be asserted to reset all of the photodiodes PD1-PD8 and their floating diffusion FD1-FD8.

Between times T0 and T1, the TG signal can be de-asserted to disconnect each of photodiodes PD1-PD8 from floating diffusions FD1-FD8, which remain in the reset state. Each photodiode can generate and accumulate photo charge in response to light detected by the photodiode. Meanwhile, each of floating diffusions FD1-FD8 can output a reset voltage. The current sources BP1-BP8 and BC are disabled by de-asserting the VBP and VBC bias voltages, as the voltage buffers that buffer the reset voltages, as well as multiplexor circuit 1002, are not yet used within this time period. Such arrangements can reduce power consumption.

Between times T1 and T2, the VBP voltage can be increased to enable current sources BP1-BP8 as well as source followers SF-1-SF-8, to buffer the reset voltages at floating diffusions FD1-FD8. Moreover, the GS signal can be asserted to enable each of S/H circuits 932_1 to 932_8 to sample and hold the buffered reset voltage at the respective floating diffusions FD1-FD8. The sampling ends at time T2 when the GS signal is de-asserted, and VBP can be de-asserted to disable source followers SF1-1-SF1-8 after the sampling completes to reduce power.

Between times T2 and T3, controller 1006 can control comparator 906 to perform quantization operations sequentially to quantize the sampled reset voltage output by each of S/H circuits 932_1 to 932_8. Controller 1006 can first assert the SEL1 signal to couple S/H circuit 932_1 with comparator 906 and enable comparator 906 to compare the sampled reset voltage with a VREF1 ramp, while counter 914 starts counting at the beginning of the VREF1 ramp. Controller 1006 also enables MSEL1_R and disables the rest of the control signals to the AND gates of output logic 1006, such that when the output of comparator 906 flips due to the VREF1 ramp intersecting with the sampled reset voltage, the count value from counter 914 can be stored in memory 912a1 as a digital reset value for FD1. Controller 1006 can then assert SEL2-SEL8 signals and MSEL2_R-MSEL8_R signals sequentially, and control comparator 906 to perform quantization operations sequentially for the sampled reset voltages at FD2-FD8, to store digital reset values for FD2-FD8 in memory 912a2-912a8.

In FIG. 11B, the total duration of the quantization operations of the reset voltages can be represented by TRSThold. As each S/H circuit 932 takes turn to access comparator 906, the charge stored in the sampling capacitors of the S/H circuits may experience different degrees of leakage, and the maximum leakage can be experienced by the S/H circuit that waits for the duration of TRSThold to access comparator 906 and to complete the quantization operation. Referring back to FIG. 9D, a leakage offset component 962 can be added to each digital reset value to compensate for the unequal degrees of leakage experienced by the sampling capacitors, and the leakage offset component can be determined based on TRSThold.

Between times T3 and T4, after the quantization operations of the reset voltages at floating diffusion FD1-FD8 completes, the TG signals of charge sensing units 614_1-614_8 can be asserted to transfer the photo charge from the photodiodes PD1-PD8 to the respective floating diffusions FD1-FD8, to establish signal voltages at the floating diffusions. As described above, each signal voltage can include a signal component contributed by the photo charge, as well as the electronic noise charge introduced by the reset switch and the threshold mismatch error introduced by the voltage buffer. After the transfer of the photo charge completes, the TG signals are de-asserted at time T4, which marks the end of the global exposure period TEXP. Between times T4 and T5, the GS signals can be asserted to enable S/H circuits 932_1-932_8 to sample and hold/store the signal voltages at the respective floating diffusions FD1-FD8. The sampling of the signal voltages ends at time T5 when the GS signal is de-asserted, and VBP can be de-asserted to disable source followers SF1-1-SF1-8 after the sampling completes to reduce power.

Between times T5 and T6, controller 1006 can control comparator 906 to perform quantization operations sequentially to quantize the sampled signal voltage output by each of S/H circuits 932_1 to 932_8. Controller 1006 can first assert the SEL1 signal to couple S/H circuit 932_1 with comparator 906 and enable comparator 906 to compare the sampled signal voltage with a VREF2 ramp, while counter 914 starts counting at the beginning of the VREF2 ramp. Controller 1006 also enables MSEL1_S and disables the rest of the control signals to the AND gates of output logic 1006, such that when the output of comparator 906 flips due to the VREF1 ramp intersecting with the sampled reset voltage, the count value from counter 914 can be stored in memory 912b1 as a digital signal value for FD1. Controller 1006 can then assert SEL2-SEL8 signals and MSEL2_S-MSEL8_S signals sequentially, and control comparator 906 to perform quantization operations sequentially for the sampled signal voltages at FD2-FD8, to store digital signal values for FD2-FD8 in memory 912b2-912b8.

In FIG. 11B, the total duration of the quantization operations of the signal voltages can be represented by TSIGhold. As each S/H circuit 932 takes turn to access comparator 906, the charge stored in the sampling capacitors of the S/H circuits may experience different degrees of leakage, and the maximum leakage can be experienced by the S/H circuit that waits for the duration of TSIGhold to access comparator 906 and to complete the quantization operation. A leakage offset component 962 can be added to each digital signal value to compensate for the unequal degrees of leakage experienced by the sampling capacitors, and the leakage offset component can be determined based on TSIGhold.

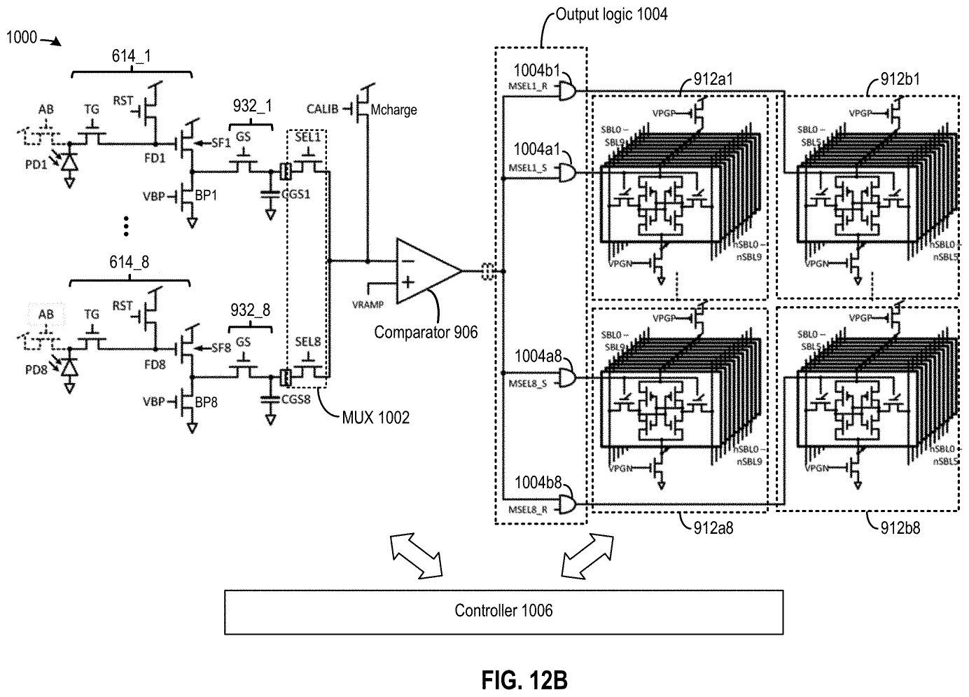

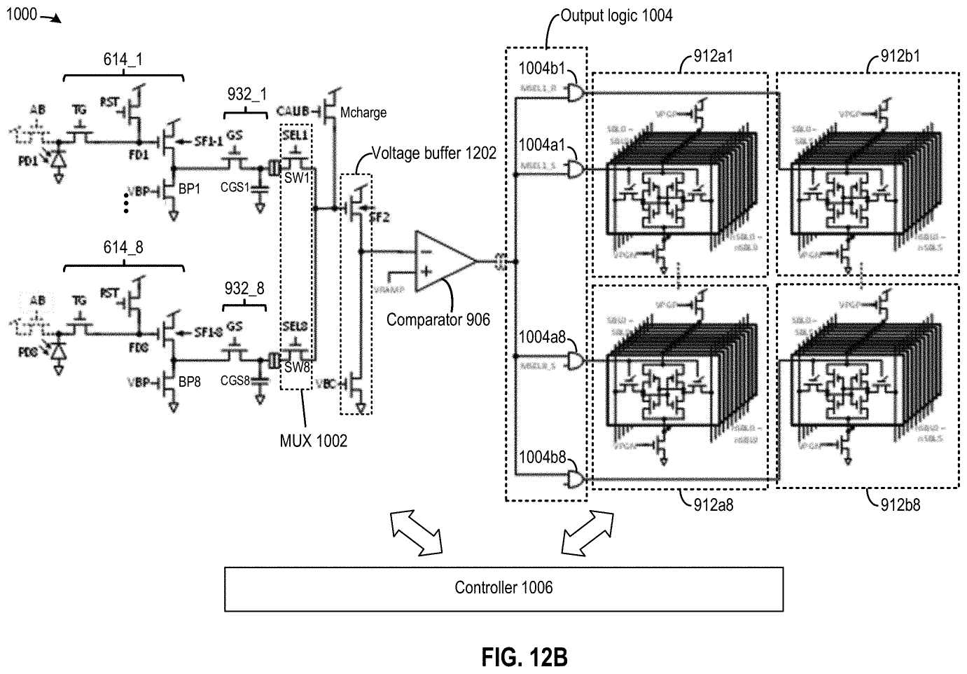

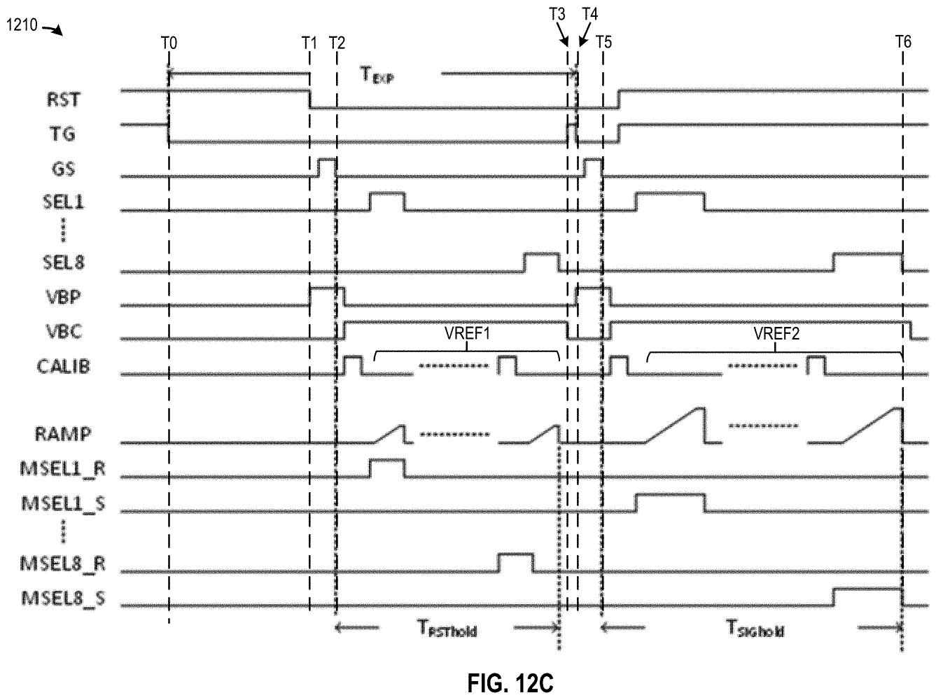

FIG. 12A, FIG. 12B, and FIG. 12C illustrate additional examples of image sensor 1000 and their operations. Compared with the example shown in FIG. 11A, in FIG. 12A multiplexor circuit 1002 includes a set of switches SW1-SW8, each controlled by a respective selection signal SEL1-SEL8, to selectively connect one of S/H circuits 932_1 to 932_8 to comparator 906 at a time.

As described above, the source followers in multiplexor circuit 1002 of FIG. 11A can improve driving strength and bandwidth in driving the input of comparator 906, while isolating the sampling capacitors from the input of comparator 906 to reduce the impact of leakage on the input voltage to comparator 906. But the source followers in multiplexor circuit 1002 can increase the footprint and power consumption, and can introduce additional electronic noise. Removing the source followers in multiplexor circuit 1002 can reduce footprint and power consumption.

To reduce the effect of charge leakage on the input voltage of comparator 906 via the disabled sampling switches, the image sensor can include a pre-charge transistor Mcharge, controlled by a CALIB signal, to pre-charge the input of comparator 906 to a pre-defined voltage level prior to any of the selection switches coupling the input with a sampling capacitor. With such arrangements, when the input of comparator 906 becomes coupled with one of the sampling capacitors, the initial input voltage of comparator 906 is at the pre-defined voltage level rather than a voltage level defined by the leakage of charge to other sampling capacitors. In some examples, the Mcharge transistor and the selection switches SW1-SW8 can be implemented in semiconductor layer 1012 together with comparator 906.

FIG. 12B illustrates another example of image sensor 1000. Compared with FIG. 12A, image sensor 1000 in FIG. 12B can include a voltage buffer 1202 coupled between the output of pre-charge transistor Mcharge and the input of comparator 906. The additional voltage buffer can improve the driving strength and bandwidth in driving the input of comparator 906. Moreover, compared with the examples of FIG. 11A, the number of source followers can be reduced, which can reduce the footprint of image sensor 1000 in semiconductor layer 1012 and improve the matching (e.g., placement, routing, etc.) of local pixels in semiconductor layer 1012.

FIG. 12B illustrates a chart 1210 of a sequence of control signals provided by controller 1006 for the example of image sensor 1000 of FIG. 12A and FIG. 12B. As shown in chart 1210, controller 1006 can assert the CALIB signal prior to the start of each quantization operation (represented by a VREF1 or a VREF2 ramp) to reset the input voltage of comparator 906. In addition, for the example of image sensor 1000 of FIG. 12B, the current source of voltage buffer 1202, controlled by a VBC bias voltage, can be enabled during the quantization operations and can be disabled before and after the quantization operations, to further reduce power. The sequence of other control signals TG, GS, SEL1-SEL8, VBP, MSEL1_R-MSEL8_R, and MSEL1_S-MSEL8-S are identical to chart 1100 and their description are not repeated here.

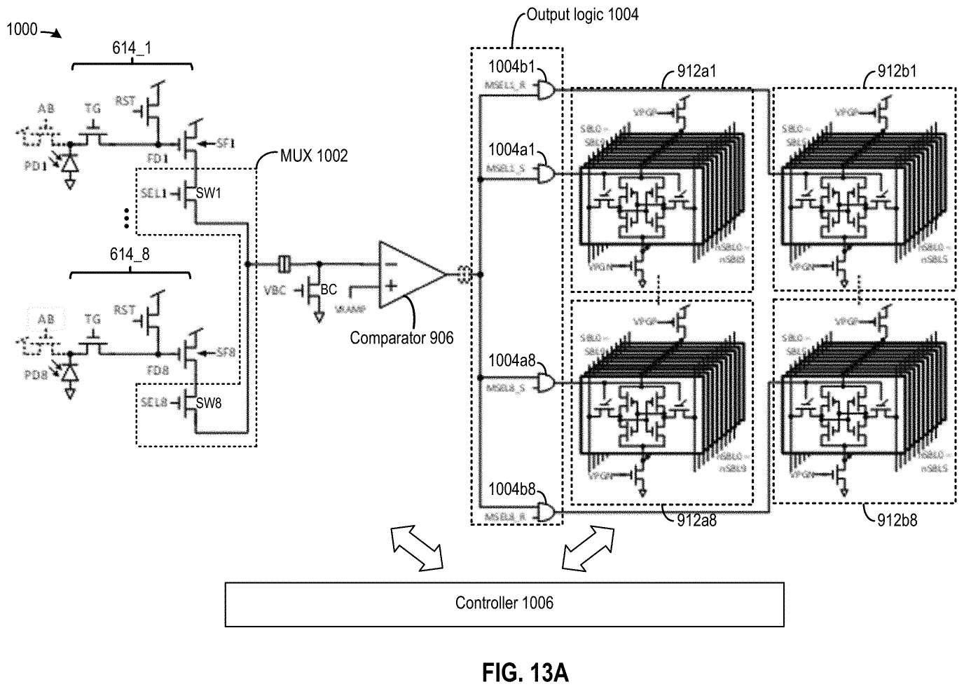

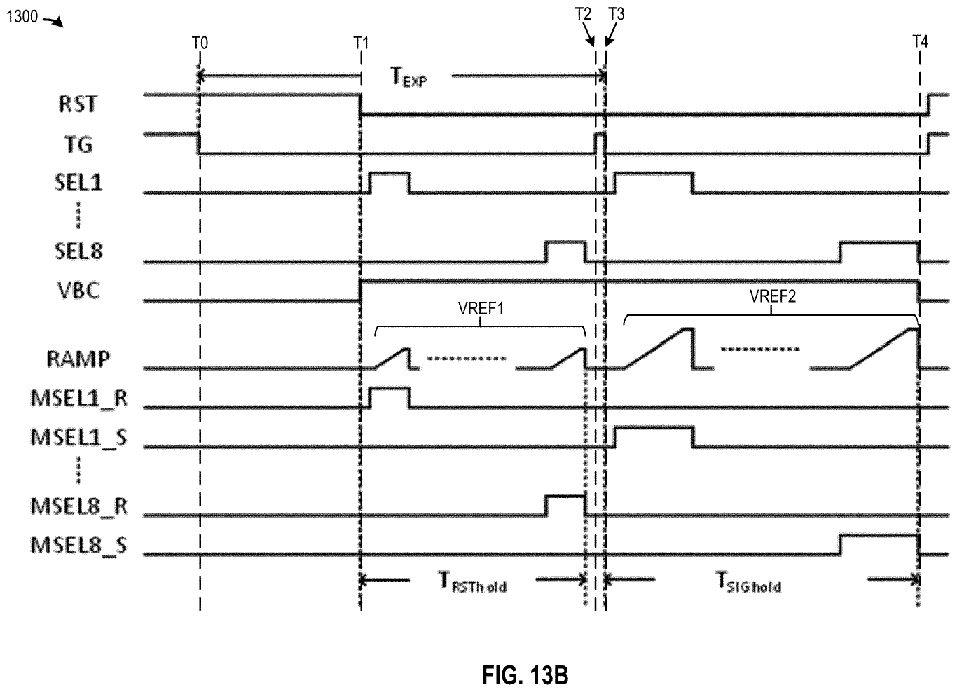

FIG. 13A and FIG. 13B illustrate additional examples of image sensor 1000 and their operations. Compared with the example shown in FIG. 11A, FIG. 12A, and FIG. 12B, S/H circuits 932 are omitted, and multiplexor circuit 1002 include a set of switches SW1-SW8, each controlled by a respective selection signal SEL1-SEL8, that selectively couple the outputs of the source followers of charge sensing units 614 with the input of comparator 906. Image sensor 1000 further includes a current source BC coupled with the input of comparator 906, to provide a bias current to one of the source followers selected to couple with the input of comparator 906, thereby allowing that source follower to drive comparator 906 with a reset voltage or a signal voltage at one of the floating diffusions FD1-FD8. In FIG. 13A, switches SW1-SW8 can be implemented in semiconductor layer 1010 together with charge sensing units 614 and photodiodes PD1-PD8, whereas comparator 906 and current source BC can be implemented in semiconductor layer 1012.

The arrangements in FIG. 13A, with the omission of S/H circuits 932, can further reduce the number of transistors and the footprint of image sensor 1000. This can reduce the parasitic capacitances of the interconnects and allow the quantization operations to be performed at a higher speed to improve the frame rate. Moreover, by speeding up the quantization operations, the total durations of the quantization operations TRSThold and TSIGhold can also be reduced, which can reduce the effect of leakage at the floating diffusions on the quantization operations in the absence of S/H circuits 932.

FIG. 13B illustrates a chart 1300 of a sequence of control signals provided by controller 1006 for the example of image sensor 1000 of FIG. 13A. In chart 1300, a global exposure period TEXP for photodiodes PD1-PD8 starts at time T0. Prior to the start of the exposure period, RST and TG can be asserted to reset all of the photodiodes PD1-PD8 and their floating diffusion FD1-FD8.

Between times T0 and T1, the TG signal can be de-asserted to disconnect each of photodiodes PD1-PD8 from floating diffusions FD1-FD8, which remain in the reset state. Each photodiode can generate and accumulate photo charge in response to light detected by the photodiode. Meanwhile, each of floating diffusions FD1-FD8 can output a reset voltage. The switches SW1-SW8 are disabled by de-asserting selection signals SEL1-SEL8, whereas current source BC is disabled by de-asserting the VBC bias voltage, as quantization operation has not yet started and comparator 906 needs not receive a voltage from one of the floating diffusions at this point. Such arrangements can reduce power consumption.

Between times T1 and T2, controller 1006 can control comparator 906 to perform quantization operations sequentially to quantize the reset voltage output by each charge sensing unit 614. The VBC voltage can be increased to enable current BC to enable the source follower of each charge sensing unit 614 to drive comparator 906. Controller 1006 can first assert the SEL1 signal to couple the output of source follower SF1 (of charge sensing unit 614_1) with comparator 906 and enable comparator 906 to compare the reset voltage with a VREF1 ramp, while counter 914 starts counting at the beginning of the VREF1 ramp. Controller 1006 also enables MSEL1_R and disables the rest of the control signals to the AND gates of output logic 1004, such that when the output of comparator 906 flips due to the VREF1 ramp intersecting with the reset voltage, the count value from counter 914 can be stored in memory 912a1 as a digital reset value for FD1. Controller 1006 can then assert SEL2-SEL8 signals and MSEL2_R-MSEL8_R signals sequentially, and control comparator 906 to perform quantization operations sequentially for the reset voltages at FD2-FD8, to store digital reset values for FD2-FD8 in memory 912a2-912a8.

Between times T2 and T3, after the quantization operations of the reset voltages at floating diffusion FD1-FD8 completes, the TG signals of charge sensing units 614_1-614_8 can be asserted to transfer the photo charge from the photodiodes PD1-PD8 to the respective floating diffusions FD1-FD8, to establish signal voltages at the floating diffusions. As described above, each signal voltage can include a signal component contributed by the photo charge, as well as the electronic noise charge introduced by the reset switch and the threshold mismatch error introduced by the voltage buffer. After the transfer of the photo charge completes, the TG signals are de-asserted at time T3, which marks the end of the global exposure period TEXP.

Between times T3 and T4, controller 1006 can control comparator 906 to perform quantization operations sequentially to quantize the signal voltage output by each charge sensing unit. The VBC voltage can remain elevated to enable current BC to enable the source follower of each charge sensing unit 614 to drive comparator 906. Controller 1006 can first assert the SEL1 signal to couple the output of source follower SF1 (of charge sensing unit 614_1) with comparator 906 and enable comparator 906 to compare the signal voltage with a VREF2 ramp, while counter 914 starts counting at the beginning of the VREF2 ramp. Controller 1006 also enables MSEL1_S and disables the rest of the control signals to the AND gates of output logic 1006, such that when the output of comparator 906 flips due to the VREF1 ramp intersecting with the signal voltage, the count value from counter 914 can be stored in memory 912b1 as a digital signal value for FD1. Controller 1006 can then assert SEL2-SEL8 signals and MSEL2_S-MSEL8_S signals sequentially, and control comparator 906 to perform quantization operations sequentially for the signal voltages at FD2-FD8, to store digital signal values for FD2-FD8 in memory 912b2-912b8.

In some examples, to further increase the dynamic range of image sensor 1000, controller 1006 can enable the photodiodes to generate charge in multiple exposure sub-periods of different durations within a global exposure period. The different durations can be configured based on different target intensity ranges. For example, controller 1006 can enable a photodiode (e.g., photodiode PD1) to sense light of a high light intensity range in a short exposure sub-period to avoid saturating the photodiode. Moreover, the controller can enable the same photodiode to sense light of a low light intensity range in a long exposure sub-period to ensure that the charge generated and accumulated by the photodiode exceeds the electronic noise charge. Quantization operations can be performed for each photodiode to generate, for example, a short exposure digital output representing the charge generated and accumulated by the photodiode during the short exposure sub-period, and a long exposure digital output representing the charge generated and accumulated by the photodiode during the long exposure sub-period. The controller (or a downstream image processor) can generate a digital output representing the intensity of light received by the photodiode within the global exposure period based on the short exposure digital output, the long exposure digital output, or a combination of both.

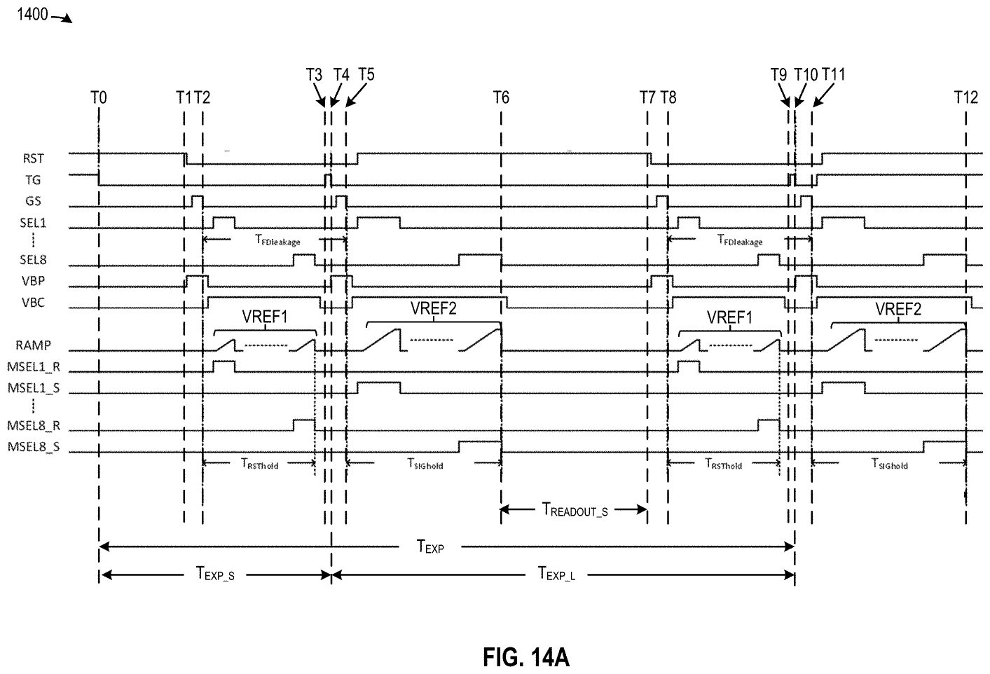

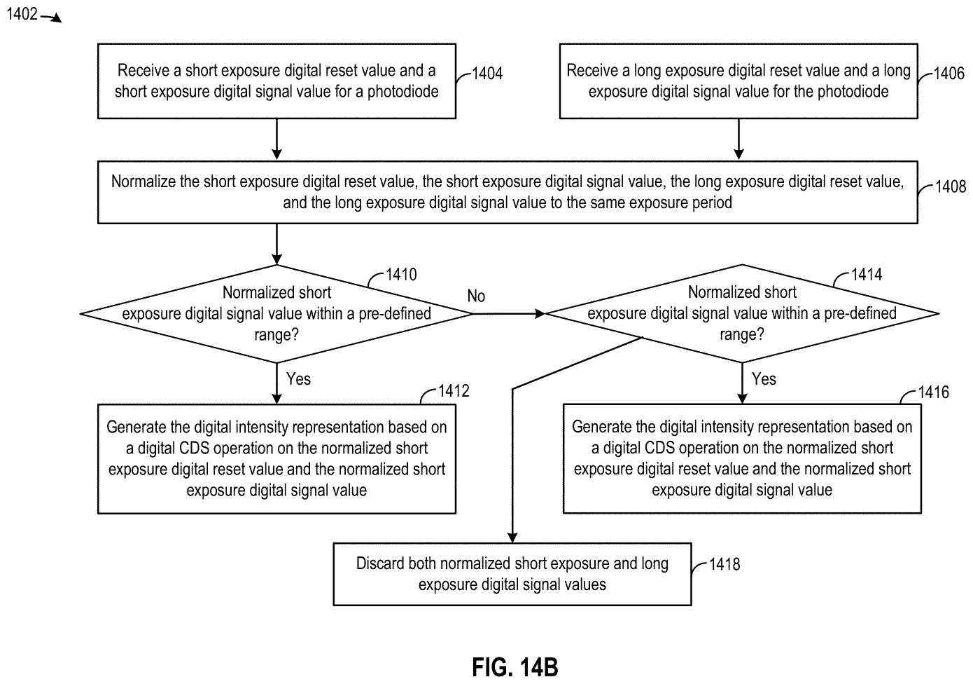

FIG. 14A illustrates a chart 1400 of a sequence of control signals provided by controller 1006 for the example of image sensor 1000 of FIG. 11A to support multiple exposure sub-periods within a global exposure period TEXP to generate an image frame. Referring to FIG. 14, the global exposure period TEXP includes a short exposure sub-period TEXP_S between times T0 and T4, followed by a long exposure sub-period TEXP_L between times T4 and T10. Long exposure reset voltages and signal voltages can be generated in the long exposure sub-period TEXP_L for each of photodiodes PD1-PD8, and can be quantized into long exposure reset values and long exposure signal values. Moreover, short exposure reset voltages and signal voltages can be generated in the short exposure sub-period TEXP_S for each of photodiodes PD1-PD8, and can be quantized into short exposure reset values and short exposure signal values. Although FIG. 14A illustrates that the global exposure period has two exposure sub-periods, it is understood that the global exposure period can have more than two exposure sub-periods, and quantization operations can be performed on reset voltages and signal voltages obtained from each exposure sub-period.

In some examples, the exposure time ratio between the long and short exposure sub-periods (TEXP_L/TEXP_S) can be determined based on a signal-to-noise ratio (SNR) or dynamic range (DR) requirement. In some examples, the ratio can be between 5 to 10 for most imaging applications, and can be increased to 15 for applications that are less sensitive to noise performance.

Global exposure period TEXP for photodiodes PD1-PD8 starts at time T0. Prior to the start of the exposure period, RST and TG can be asserted to reset all of the photodiodes PD1-PD8 and their floating diffusions FD1-FD8.

Between times T0 and T1 (and within the short exposure sub-period TEXP_S), the TG signal can be de-asserted to disconnect each of photodiodes PD1-PD8 from floating diffusions FD1-FD8, which remain in the reset state. Each photodiode can generate and accumulate photo charge in response to light detected by the photodiode. Meanwhile, each of floating diffusions FD1-FD8 can output a short exposure reset voltage. The current sources BP1-BP8 and BC are disabled by de-asserting the VBP and VBC bias voltages, as the voltage buffers that buffer the reset voltages, as well as multiplexor circuit 1002, are not yet used within this time period. Such arrangements can reduce power consumption.

Between times T1 and T2, the VBP voltage can be increased to enable current sources BP1-BP8 as well as source followers SF-1-SF-8, to buffer the reset voltages at floating diffusions FD1-FD8. Moreover, the GS signal can be asserted to enable each of S/H circuits 932_1 to 932_8 to sample and hold the buffered reset voltage at the respective floating diffusions FD1-FD8. The sampling ends time T2 when the GS signal is de-asserted, and VBP can be de-asserted to disable source followers SF1-1-SF1-8 after the sampling completes to reduce power.

Between times T2 and T3, controller 1006 can control comparator 906 to perform quantization operations sequentially to quantize the sampled reset voltage output by each of S/H circuits 932_1 to 932_8. Controller 1006 can first assert the SEL1 signal to couple S/H circuit 932_1 with comparator 906 and enable comparator 906 to compare the sampled reset voltage with a VREF1 ramp, while counter 914 starts counting at the beginning of the VREF1 ramp. Controller 1006 also enables MSEL1_R and disables the rest of the control signals to the AND gates of output logic 1006, such that when the output of comparator 906 flips due to the VREF1 ramp intersecting with the sampled reset voltage, the count value from counter 914 can be stored in memory 912a1 as a short exposure digital reset value for FD1. Controller 1006 can then assert SEL2-SEL8 signals and MSEL2_R-MSEL8_R signals sequentially, and control comparator 906 to perform quantization operations sequentially for the sampled reset voltages at FD2-FD8, to store short exposure digital reset values for FD2-FD8 in memory 912a2-912a8.

Between times T3 and T4, after the quantization operations of the reset voltages at floating diffusion FD1-FD8 complete, the TG signals of charge sensing units 614_1-614_8 can be asserted to transfer the photo charge generated and accumulated by the photodiodes PD1-PD8 within the short exposure sub-period to the respective floating diffusions FD1-FD8, to establish short exposure signal voltages at the floating diffusions. A short exposure signal voltage can include a signal component contributed by the photo charge generated during the short exposure sub-period TEXP_S, as well as the electronic noise charge introduced by the reset switch and the threshold mismatch error introduced by the voltage buffer. After the transfer of the photo charge completes, the TG signals are de-asserted at time T4, which marks the end of the short exposure sub-period TEXP_S. Moreover, controller 1006 can also assert the RST signals to reset all of floating diffusions FD1-FD8 at or after time T4, which can mark the beginning of the long exposure sub-period TEXP_L.

Between times T4 and T5, the GS signals can be asserted to enable S/H circuits 932_1-932_8 to sample and hold/store the short exposure signal voltages at the respective floating diffusions FD1-FD8. The sampling of the signal voltages ends at time T5 when the GS signal is de-asserted, and VBP can be de-asserted to disable source followers SF1-1-SF1-8 after the sampling completes to reduce power.

Between times T5 and T6, controller 1006 can control comparator 906 to perform quantization operations sequentially to quantize the sampled short exposure signal voltages output by each of S/H circuits 932_1 to 932_8. Controller 1006 can first assert the SEL1 signal to couple S/H circuit 932_1 with comparator 906 and enable comparator 906 to compare the sampled signal voltage with a VREF2 ramp, while counter 914 starts counting at the beginning of the VREF2 ramp. Controller 1006 also enables MSEL1_S and disables the rest of the control signals to the AND gates of output logic 1006, such that when the output of comparator 906 flips due to the VREF1 ramp intersecting with the sampled reset voltage, the count value from counter 914 can be stored in memory 912b1 as a short exposure digital signal value for FD1. Controller 1006 can then assert SEL2-SEL8 signals and MSEL2_S-MSEL8_S signals sequentially, and control comparator 906 to perform quantization operations sequentially for the sampled signal voltages at FD2-FD8, to store short exposure digital signal values for FD2-FD8 in memory 912b2-912b8.

In cases where image sensor 1000 includes memory 912a and memory 912b to store only one set of the digital reset values and one set of digital signal values, the short exposure digital reset values and the short exposure digital signal values stored in memory 912a and 912b need to be read-out before they can be overwritten by the digital reset and signal values generated from the subsequent long exposure sub-period. Controller 1006 can hold the RST signal and the floating diffusions in a reset state after time T6 to delay the beginning of the subsequent quantization operations that generate long exposure digital reset and signal values for the long exposure sub-period. In the example of FIG. 14, the read-out operations of the short exposure digital reset values from memory 912a can be performed between times T5 and T6, whereas the read-out of the short exposure digital signal values from memory 912b can be performed between times T6 and T7 within a duration of TREADOUT_S. The long exposure sub-period TEXP_L can be extended to accommodate TREADOUT_S.

Between times T7 and T8, the VBP voltage can be increased to enable current sources BP1-BP8 as well as source followers SF-1-SF-8, to buffer the reset voltages at floating diffusions FD1-FD8. Moreover, the GS signal can be asserted to enable each of S/H circuits 932_1 to 932_8 to sample and hold the buffered reset voltage at the respective floating diffusions FD1-FD8. The sampling ends time T8 when the GS signal is de-asserted, and VBP can be de-asserted again to disable source followers SF1-1-SF1-8 after the sampling completes to reduce power.

Between times T8 and T9, controller 1006 can control comparator 906 to perform quantization operations sequentially to quantize the sampled long exposure reset voltage output by each of S/H circuits 932_1 to 932_8 by comparing the sampled long exposure reset voltages with VREF1 to generate long exposure digital reset values, and store the long exposure digital reset values at memory 912a1-912a8.

Between times T9 and T10, after the quantization operations of the reset voltages at floating diffusion FD1-FD8 complete, the TG signals of charge sensing units 614_1-614_8 can be asserted to transfer the photo charge generated and accumulated by the photodiodes PD1-PD8 within the long exposure sub-period to the respective floating diffusions FD1-FD8, to establish long exposure signal voltages at the floating diffusions. After the transfer of the photo charge completes, the TG signals are de-asserted at time T10, which marks the end of the long exposure sub-period TEXP_L.

Between times T10 and T11, the GS signals can be asserted to enable S/H circuits 932_1-932_8 to sample and hold/store the long exposure signal voltages at the respective floating diffusions FD1-FD8. The sampling of the long exposure signal voltages ends at time T5 when the GS signal is de-asserted, and VBP can be de-asserted to disable source followers SF1-1-SF1-8 after the sampling completes to reduce power.

Between times T11 and T12, controller 1006 can control comparator 906 to perform quantization operations sequentially to quantize the sampled long exposure signal voltages output by each of S/H circuits 932_1 to 932_8 by comparing the sampled long exposure signal voltages with VREF2 to generate long exposure digital signal values, and store the long exposure digital signal values at memory 912b 1-912b8.

After time T12, the long exposure digital reset values and long exposure digital signal values can be read-out from memory 912a1-912a8 and 912b1-912b8. The digital reset values and digital signal values from one of the long exposure sub-period and the short exposure sub-period can be selected for each photodiode to generate a digital representation of the intensity of light received by that photodiode within the global exposure period.

FIG. 14B illustrates an example flow diagram of a method 1402 of selecting a pair of reset value and digital signal value from one of the long exposure sub-period or the short exposure sub-period to generate a digital intensity representation for the photodiode. Method 1402 can be performed by controller 1006 or another system that receives the digital reset values and the digital signal values from image sensor 1000, such as an image processor, a host, etc.

In step 1404, a system can receive a short exposure digital reset value and a short exposure digital signal value for a photodiode. The short exposure digital reset value and the short exposure digital signal value can be read-out from memory 912 between times T5 and T7 in FIG. 14A.

In step 1406, the system can receive a long exposure digital reset value and a long exposure digital signal value for the photodiode. The long exposure digital reset value can be read-out from memory 912 after time T9 in FIG. 14A, whereas the long exposure digital signal value can be read-out from memory 912 after time T12 in FIG. 14A.

In step 1408, the short exposure digital reset value, the short exposure digital signal value, the long exposure digital reset value, and the long exposure digital signal value can be normalized to the same exposure period. For example, the short exposure digital values can be scaled up based on a ratio between the global exposure period (TEXP) and the short exposure period (TEXP_S), whereas the long exposure digital values can be scaled up based on a ratio between the global exposure period (TEXP) and the long exposure period (TEXP_L), so that the normalized digital values have the same scale.

In step 1410, the system can determine whether the normalized short exposure digital signal value is within a pre-defined range. The short exposure sub-period can be targeted at measuring light of high intensity to avoid saturating the photodiode. The normalized short exposure digital signal value being within the pre-defined range can indicate that the photodiode is not saturated by the charge, and the charge also exceeds a noise floor set by the electronic noise and measurement error, and that the intensity of light received by the photodiode within the short exposure sub-period is within a measurable intensity range.

If the system determines that the normalized short exposure digital signal value is within the pre-defined range in step 1410, the system can proceed to generate a digital intensity representation of the light received by the photodiode based on a digital CDS operation on the normalized short exposure digital reset value and the normalized short exposure digital signal value, in step 1412.

On the other hand, if the normalized short exposure digital signal value is not within the pre-defined range, the system can determine whether the normalized long exposure digital signal value is within the pre-defined range, in step 1414. If the normalized long exposure digital signal value is within the pre-defined range, the system can proceed to generate a digital intensity representation of the light received by the photodiode based on a digital CDS operation on the normalized long exposure digital reset value and the normalized long exposure digital signal value, in step 1416. The long exposure sub-period can be targeted at measuring light of low/medium intensity such that charge accumulated within an extended exposure period can be above the noise floor. If the normalized short exposure digital signal value is below (and outside of) the pre-defined range, the system can use the long exposure digital signal value to generate the digital representation of light intensity instead. But if both the normalized long exposure and short exposure digital values are outside the pre-defined range, both digital values may be discarded, in step 1418.

In some examples, if both the normalized long exposure and short exposure digital signal values are within the pre-defined range, the digital representation of light intensity can be generated based on averaging the digital CDS outputs of the short exposure and long exposure digital reset and signal values.

As described above, in order to limit the size of memory 912, read-out operations from memory 912 may be performed within the long exposure sub-period to allow the short exposure digital signal and reset values in memory 912 to be overwritten by the long exposure digital signal and reset values. But if the global exposure period includes additional exposure sub-periods, additional read-out operations may have to be performed within the global exposure period. This can increase the duration of the global exposure period, which can lead to reduced frame rate as well as increased power consumption.

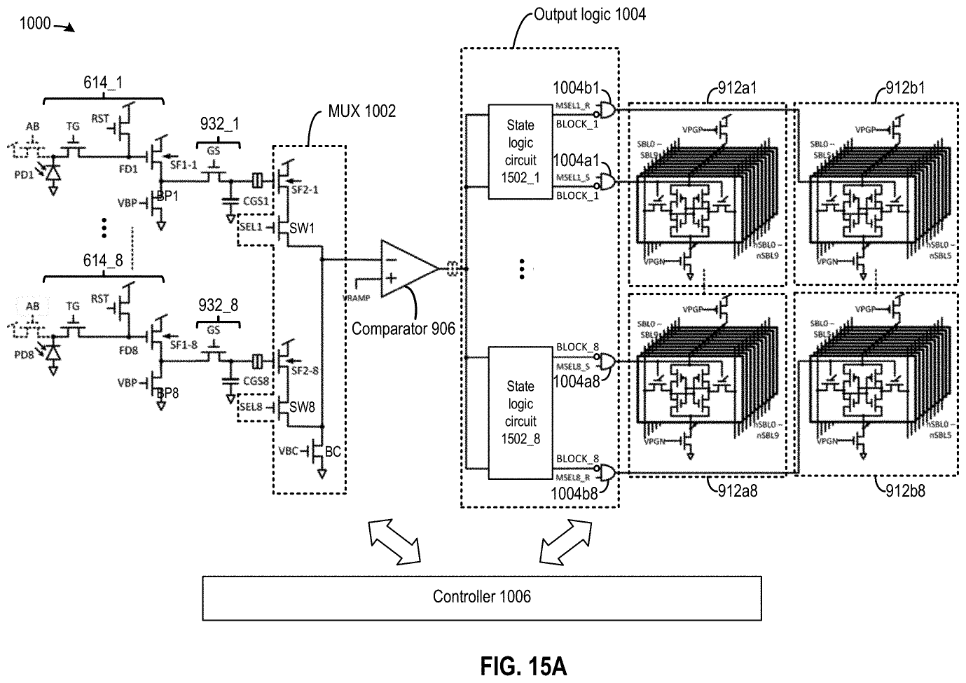

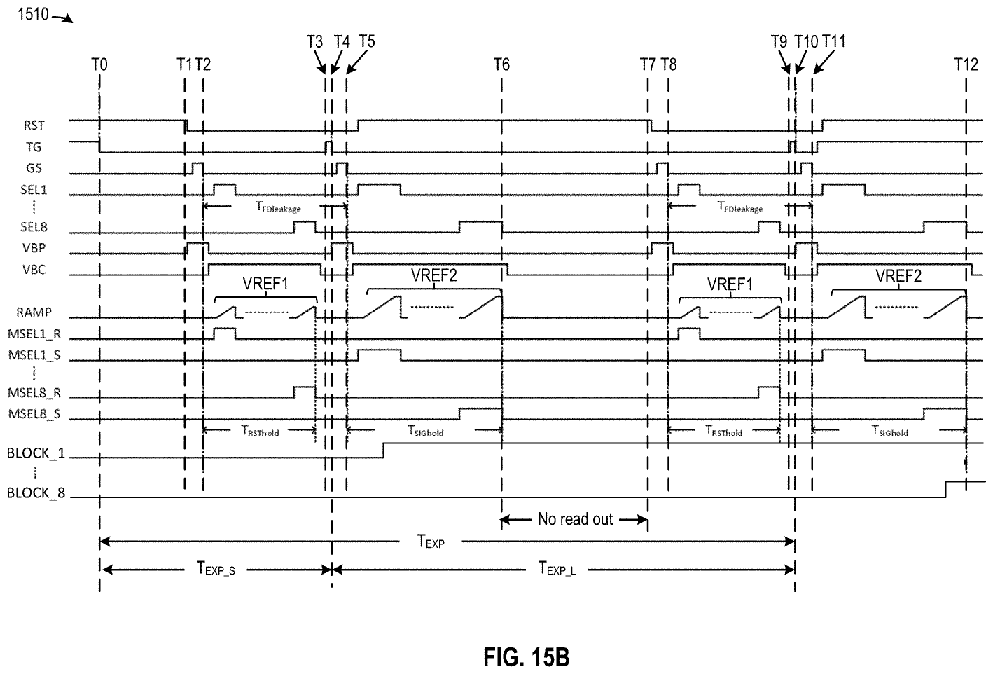

FIG. 15A and FIG. 15B illustrate additional examples of image sensor 1000 that can reduce the read-out operations. Compared with the example of image sensor 1000 of FIG. 11A, output logic 1004 of FIG. 15A includes state logic circuits 1502_1-1502_8. Each state logic circuit is associated with a pair of AND gates that control the storage of a pair of digital reset value and digital signal value at memory 912. For example, state logic circuit 1502_1 is associated with AND gates 1008a1 and 1008b1 to control the storage of digital reset value and digital signal value at memory 912a1 and memory 912b1. Moreover, state logic circuit 1502_8 is associated with AND gates 1008a8 and 1008b8 to control the storage of digital reset value and digital signal value at memory 912a8 and memory 912a8.

Each state logic circuit can include registers and trip detection logic circuit. The trip detection logic circuit can detect the tripping of the output of comparator 906 in comparing the signal voltage with the second VREF ramp (VREF2) from each exposure sub-period, which indicates the signal voltage is within a measurable light intensity range. Each register of the state logic circuit can be associated with an exposure sub-period. The detection of tripping from the comparator output for a particular exposure period can cause an asserted flag bit to be stored in the register for that exposure sub-period. After a pair of digital reset value and digital signal value from a particular exposure sub-period is stored at a set of memory 912a and 912b for a particular photodiode and charge sensing unit, the storage of the asserted flag bit in one or more of the registers in state logic can cause the state logic to output a BLOCK signal which, when asserted, can disable the AND gate and prevent the AND gate from propagating a latch signal to the set of memory 912a and 912b. This can freeze the set of memory 912a and 912b so that the digital reset values and digital signal values obtained from subsequent exposure sub-periods (if any) will not be stored into the set of memory 912a and 912b. As shown in FIG. 15A, state logic circuit 1502_1 can output a BLOCK_1 signal to freeze memory 912a1 and 912b1, whereas state logic circuit 1502_8 can output a BLOCK_8 signal to freeze memory 912a8 and 912b8.

With the arrangements of FIG. 15A, no read-out operation needs to be performed within the global exposure period, and memory 912a and 912b can store a single set of valid digital reset values and digital signal values for an image frame. This allows reduction of the duration of global exposure period, which allows each image frame to be generated within a shorter period of time and increase of frame rate. Moreover, the power consumption of image sensor 1000 can also be reduced, as the read-out operations involve movement of a large amount of data and consume a lot of power. Further, the freezing of both memory 912a and 912b can also ensure that a pair of digital reset value and digital signal value generated from the same exposure sub-period is frozen, and the digital signal value contains the same noise and error component present in the digital reset value, such that a digital CDS operation based on the pair can remove the noise and error component from the digital signal value. This can maintain the lower limit of the dynamic range, while the upper limit of the dynamic range can be extended by the multiple exposure sub-period arrangements, thereby the dynamic range can be extended.

FIG. 15B illustrates a chart 1510 of a sequence of control signals provided by controller 1006 for the example of image sensor 1000 of FIG. 11A to support multiple exposure sub-periods within a global exposure period TEXP to generate an image frame. Compared with chart 1400 of FIG. 14B, it can be seen that control signals BLOCK_1 and BLOCK_8 are added. The descriptions of the rest of the control signals are identical to those in FIG. 14B and are not repeated here.

Specifically, at time T6 where the quantization operations of the reset voltages and the signal voltages obtained from the short exposure sub-period TEXP_S complete, and the short exposure digital reset values and the short exposure digital signal values are generated and stored, one or more of BLOCK_1 to BLOCK_8 signals can be asserted if the output of comparator 906 flips and the short exposure digital signal value is stored. For example, in FIG. 15B, the output of comparator 906 trips while comparing the sampled signal voltage for FD1 obtained from the short exposure sub-period TEXP_S, and the BLOCK_1 signal can be asserted between times T5 and T6. The assertion of the BLOCK_1 signal can prevent comparator 906 from overwriting the short exposure digital reset and signal values stored in memory 912a1 and 912b1 in the subsequent long exposure sub-period TEXP_L. Meanwhile, the output of comparator 906 does not trip while comparing the sampled signal voltage for FD8, and the BLOCK_8 signal can remain de-asserted after times T5-T6.

Due to the freezing of memory 912 that stores valid short exposure digital signal values, there is no need to perform a read-out operation as those valid digital signal values will not be overwritten by digital signal values obtained from the subsequent long exposure sub-period. Therefore no read-out operation needs to be performed between times T6 and T7. Instead, the duration between times T6 and T7 can be determined entirely based on a required duration of the long exposure sub-period to, for example, achieve a target DR/SNR as described above.

Between times T8 and T12, comparator 906 can perform quantization operations of the reset voltages and signal voltages obtained from the long exposure sub-period TEXP_L to generate long exposure digital reset values and long exposure digital signal values. But with the BLOCK_1 signal asserted, memory 912a1 and 912b1 are frozen and cannot be overwritten with the long exposure digital reset value and long exposure digital signal value obtained for floating diffusion FD1. On the other hand, as BLOCK_8 signal remains de-asserted, comparator 906 can store the long exposure digital reset value and long exposure digital signal value obtained for floating diffusion FD8 into memory 912a8 and 912b8.

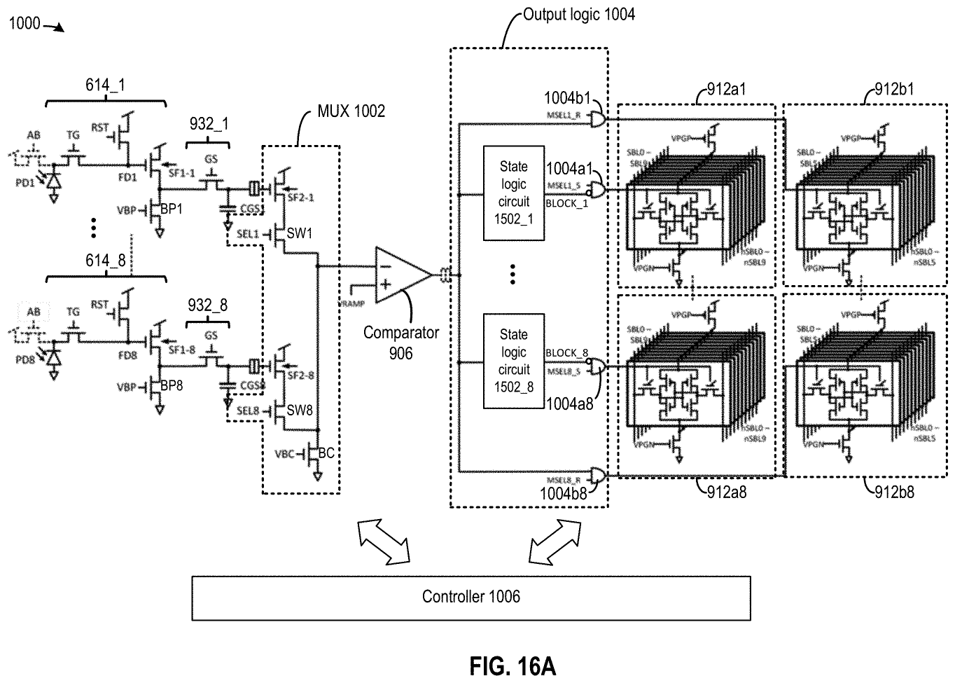

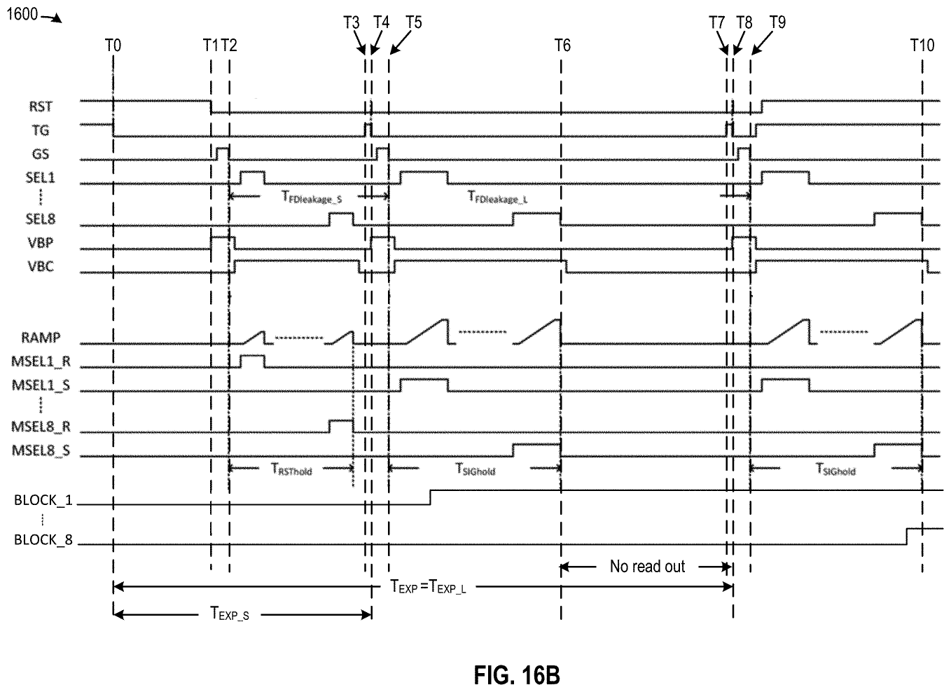

FIG. 16A and FIG. 16B illustrate additional examples of image sensor 1000 and their operations. In the example of FIG. 16A, controller 1006 can control comparator 906 to perform quantization operations of reset voltages obtained from the first exposure sub-period (e.g., short exposure sub-period TEXP_S) and store the digital reset values at memory 912a1-912a8. For the rest of the global exposure period, the controller 1006 can maintain the RST signal in the de-asserted state and not to reset the floating diffusions, such that the floating diffusions continue to accumulate charge through the rest of the global exposure period, and no additional quantization operations of reset voltages are performed. Meanwhile, image sensor 1000 includes state logic circuits 1502_1 to 1502_8 to control the storage of digital signal values at memory 912b1-912b8. The operations of other components in FIG. 16A are identical to those of FIG. 11A and their descriptions are not repeated here.

The arrangements of FIG. 16A, where a single set of quantization operations is performed for the reset voltages for each image frame, can provide various advantages. For example, the number of quantization operations can be reduced, which can reduce power as well as the total time incurred by the quantization operations. The frame period can be reduced as a result. In addition, by having the multiple exposure periods starting at the same time, it becomes more likely that the same scenes are captured in the multiple exposure periods, which can reduce the motion artifacts in the image in a case where the scene contains fast moving objects.

FIG. 16B illustrates a chart 1600 of a sequence of control signals provided by controller 1006 for the example of image sensor 1000 of FIG. 16A. Referring to FIG. 16B, the global exposure period TEXP is between times T0 and T8, which also corresponds to a long exposure sub-period TEXP_L. In addition, the global exposure period TEXP also includes a short exposure sub-period TEXP_S between times T0 and T4. In some examples, the global exposure period TEXP can include more than two exposure sub-periods of different durations, each starting at time T0.

In FIG. 16B, both long exposure TEXP_L and short exposure period TEXP_S start at time T0 as the floating diffusions are not reset again at the end of short exposure period TEXP_S, which allows the floating diffusions to continue accumulating the charge after the end of short exposure period TEXP_S. Prior to the start of the global exposure period, RST and TG can be asserted to reset all of the photodiodes PD1-PD8 and their floating diffusion FD1-FD8.

Between times T0 and T1 (and within the short exposure sub-period TEXP_S), the TG signal can be de-asserted to disconnect each of photodiodes PD1-PD8 from floating diffusions FD1-FD8, which remain in the reset state. Each photodiode can generate and accumulate photo charge in response to light detected by the photodiode. Meanwhile, each of floating diffusions FD1-FD8 can output a short exposure reset voltage. The current sources BP1-BP8 and BC are disabled by de-asserting the VBP and VBC bias voltages, as the voltage buffers that buffer the reset voltages, as well as multiplexor circuit 1002, are not yet used within this time period. Such arrangements can reduce power consumption.

Between times T1 and T2, the VBP voltage can be increased to enable current sources BP1-BP8 as well as source followers SF-1-SF-8, to buffer the reset voltages at floating diffusions FD1-FD8. Moreover, the GS signal can be asserted to enable each of S/H circuits 932_1 to 932_8 to sample and hold the buffered reset voltage at the respective floating diffusions FD1-FD8. The sampling ends time T2 when the GS signal is de-asserted, and VBP can be de-asserted to disable source followers SF1-1-SF1-8 after the sampling completes to reduce power.

Between times T2 and T3, controller 1006 can control comparator 906 to perform quantization operations sequentially to quantize the sampled reset voltage output by each of S/H circuits 932_1 to 932_8. Controller 1006 can first assert the SEL1 signal to couple S/H circuit 932_1 with comparator 906 and enable comparator 906 to compare the sampled reset voltage with a VREF1 ramp, while counter 914 starts counting at the beginning of the VREF1 ramp. Controller 1006 also enables MSEL1_R and disables the rest of the control signals to the AND gates of output logic 1006, such that, when the output of comparator 906 flips due to the VREF1 ramp intersecting with the sampled reset voltage, the count value from counter 914 can be stored in memory 912a1 as a short exposure digital reset value for FD1. Controller 1006 can then assert SEL2-SEL8 signals and MSEL2_R-MSEL8_R signals sequentially, and control comparator 906 to perform quantization operations sequentially for the sampled reset voltages at FD2-FD8, to store short exposure digital reset values for FD2-FD8 in memory 912a2-912a8.

Between times T3 and T4, after the quantization operations of the reset voltages at floating diffusion FD1-FD8 complete, the TG signals of charge sensing units 614_1-614_8 can be asserted to transfer the photo charge generated and accumulated by the photodiodes PD1-PD8 within the short exposure sub-period to the respective floating diffusions FD1-FD8, to establish short exposure signal voltages at the floating diffusions. A short exposure signal voltage can include a signal component contributed by the photo charge generated during the short exposure sub-period TEXP_S, as well as the electronic noise charge introduced by the reset switch and the threshold mismatch error introduced by the voltage buffer. After the transfer of the photo charge completes, the TG signals are de-asserted at time T4, which marks the end of the short exposure sub-period TEXP_S. But unlike the arrangements of FIG. 14A, in the arrangements of FIG. 16B, controller 1006 does not assert the RST signals to reset floating diffusions FD1-FD8 at or after time T4, which allows floating diffusions FD1-FD8 to continue accumulating charge, which in turn allows the long exposure sub-period TEXP_L to continue beyond time T4.

Between times T4 and T5, the GS signals can be asserted to enable S/H circuits 932_1-932_8 to sample and hold/store the short exposure signal voltages at the respective floating diffusions FD1-FD8. The sampling of the signal voltages ends at time T5 when the GS signal is de-asserted, and VBP can be de-asserted to disable source followers SF1-1-SF1-8 after the sampling completes to reduce power.

Between times T5 and T6, controller 1006 can control comparator 906 to perform quantization operations sequentially to quantize the sampled short exposure signal voltages output by each of S/H circuits 932_1 to 932_8. Controller 1006 can first assert the SEL1 signal to couple S/H circuit 932_1 with comparator 906 and enable comparator 906 to compare the sampled signal voltage with a VREF2 ramp, while counter 914 starts counting at the beginning of the VREF2 ramp. Controller 1006 also enables MSEL1_S and disables the rest of the control signals to the AND gates of output logic 1006, such that when the output of comparator 906 flips due to the VREF1 ramp intersecting with the sampled reset voltage, the count value from counter 914 can be stored in memory 912b1 as a short exposure digital signal value for FD1. Controller 1006 can then assert SEL2-SEL8 signals and MSEL2_S-MSEL8_S signals sequentially, and control comparator 906 to perform quantization operations sequentially for the sampled signal voltages at FD2-FD8, to store short exposure digital signal values for FD2-FD8 in memory 912b2-912b8.

In addition, between times T5 and T6, state logic circuits 1502_1-1502_8 can determine which of memory 912b1-912b8 stores a short exposure digital signal value (based on whether the output of comparator 906 trips), and assert the BLOCK signal(s) to freeze the memory. In FIG. 16B, state logic circuit 1502_1 can assert the BLOCK_1 signal to freeze memory 912b1, while state logic circuit 1502_8 can maintain the BLOCK_8 signal in a de-asserted state to allow memory 912b8 to be overwritten by a long exposure digital signal value from the subsequent quantization operations.

Between times T6 and T7, no readout operation is performed due to the freezing of memory 912 that stores valid short exposure digital signal values, as described above. Instead, the duration between times T6 and T7 can be determined entirely based on a required duration of the long exposure sub-period to, for example, achieve a target DR/SNR as described above.

Between times T7 and T8, the TG signals of charge sensing units 614_1-614_8 can be asserted to transfer the photo charge generated and accumulated by the photodiodes PD1-PD8 within the long exposure sub-period to the respective floating diffusions FD1-FD8, to establish long exposure signal voltages at the floating diffusions. After the transfer of the photo charge completes, the TG signals are de-asserted at time T8, which marks the end of the long exposure sub-period TEXP_L as well as the global exposure period TEXP.

Between times T8 and T9, the VBP voltage can be increased to enable current sources BP1-BP8 as well as source followers SF-1-SF-8, to buffer the long exposure signal voltages at floating diffusions FD1-FD8. Moreover, the GS signal can be asserted to enable each of S/H circuits 932_1 to 932_8 to sample and hold the buffered long exposure signal voltage at the respective floating diffusions FD1-FD8. The sampling ends time T9 when the GS signal is de-asserted, and VBP can be de-asserted again to disable source followers SF1-1-SF1-8 after the sampling completes to reduce power.

Between times T9 and T10, controller 1006 can control comparator 906 to perform quantization operations sequentially to quantize the sampled long exposure reset voltage output by each of S/H circuits 932_1 to 932_8 by comparing the sampled long exposure signal voltages with VREF2 to generate long exposure digital signal values, and store the long exposure digital signal values at memory 912b1-912b8 that have not been frozen by the BLOCK signals. In FIG. 16B, memory 912b1 is frozen by the BLOCK_1 signal and will not store the long exposure digital signal value for floating diffusion FD1, while memory 912b8 is not frozen by the BLOCK_8 signal and can store the long exposure digital signal value for floating diffusion FD8.

After time T10, the digital signal values (from short or long exposure periods) can be read-out from memory 912b1-912b8. In addition, the short exposure digital reset values can also be read-out from memory 912a1-912a8 after time T5. Digital CDS operations can be performed using the digital signal values and the short exposure digital reset values. In a case where a short exposure digital reset value is used to combine with a long exposure digital signal value in a digital CDS operation, an offset component, similar to the one shown in FIG. 9D and can be obtained from a calibration operation, can be added to the short exposure digital reset value, or to the digital CDS output, to account for additional leakage and dark charge received by the floating diffusions after the quantization operations of the reset voltages end and before the quantization operations of the long exposure signal voltages begin (e.g., between times T5 and T9). The additional leakage and dark charge are present due to the omission of the reset operations prior to the quantization operations of the long exposure signal voltage and increase the total error components, but the additional error components are not present in the reset voltages quantized by comparator 906. By adding the offset component, the removal of error components from the digital signal values can be improved, which in turn can further extend the dynamic range of the image sensor.

Although not shown in the figures, it is understood that examples of image sensor 1000 shown in FIG. 12A-FIG. 13B can be controlled to generate digital reset values and digital signal values from multiple exposure sub-periods to generate an image frame, and can include state logic circuits 1502 to control the storage of digital reset values and digital signal values in memory 912, based on the techniques described in FIG. 14A-FIG. 16B.

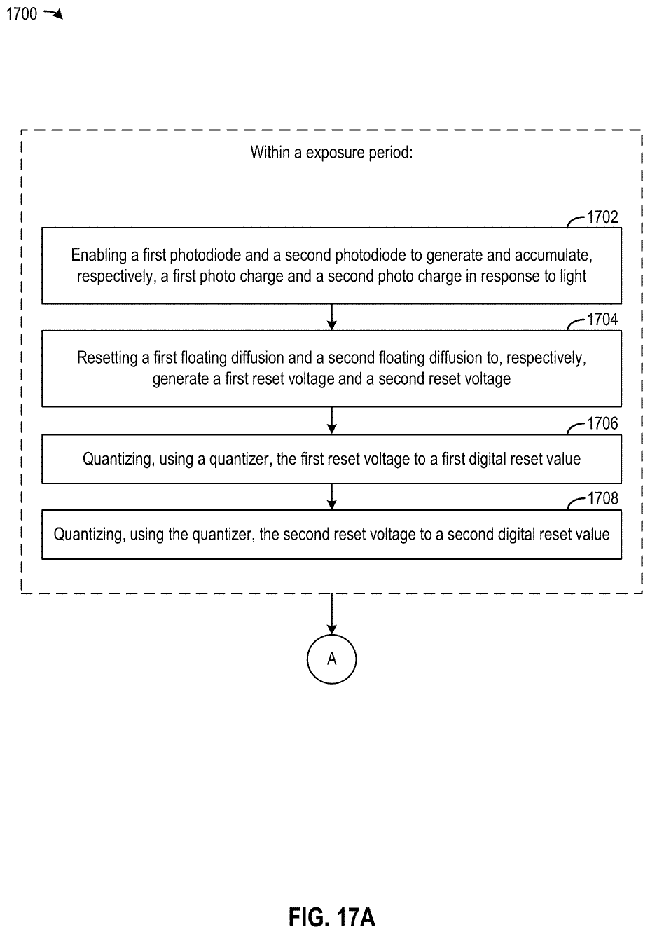

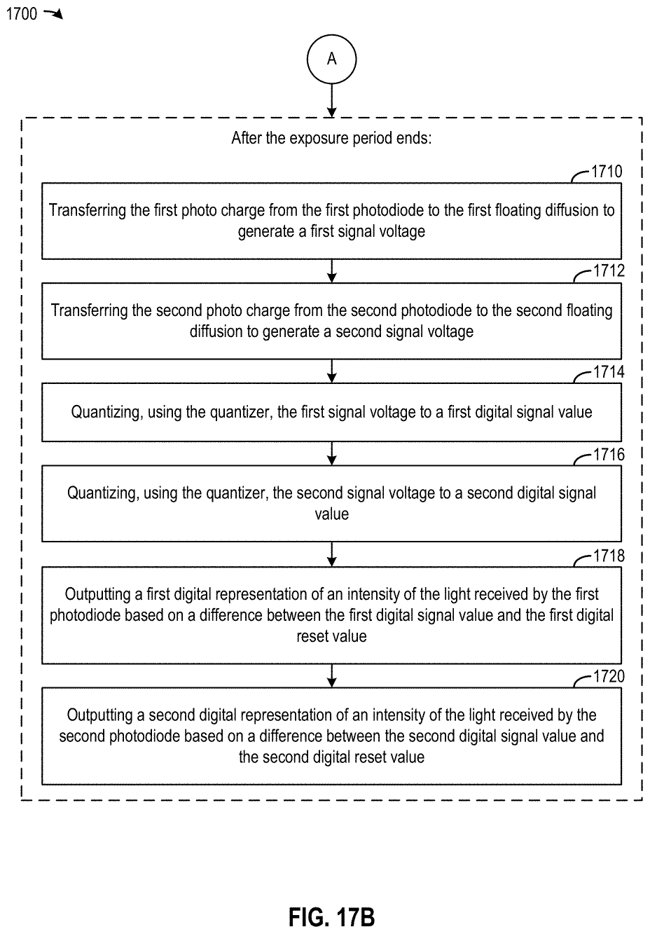

FIG. 17A and FIG. 17B illustrate a flowchart of a method 1700 of performing an imaging operation. Method 1700 can be performed by a controller (e.g., controller 1006) of image sensor 1000 of FIG. 10A-FIG. 16B that further includes a first photodiode (e.g., PD1), a second photodiode (e.g., PD8), a first floating diffusion (e.g., FD1), a second floating diffusion (e.g., FD8), and a quantizer (e.g., comparator 906). Image sensor 1000 may further include a first source follower coupled with the first floating diffusion, a second source follower coupled with the second floating diffusion, a first S/H circuit and a second S/H circuit coupled with, respectively, the first and second source followers, as well as a multiplexor circuit (e.g., multiplexor circuit 1002) to selectively couple one of the first or second S/H circuits (or one of the first or second source followers) to the comparator. Image sensor 1000 further includes a first memory (e.g., memory 912a1 and memory 912b1) to store the digital reset and signal values for the first photodiode, and a second memory (e.g., memory 912a8 and memory 912b8) to store the digital reset and signal values for the second photodiode.

Referring to FIG. 17A, steps 1702-1708 of method 1700 can be performed within an exposure period (e.g., TEXP of FIG. 10B-FIG. 16B, TEXP_S of FIG. 14A-FIG. 16B, etc.). In step 1702, the controller can enable the first photodiode and the second photodiode to generate and accumulate, respectively, a first photo charge and a second photo charge in response to light. Referring to FIG. 10A, the controller can de-assert the TG signal to isolate the first and second photodiodes from, respectively, the first floating diffusion and the second floating diffusion, to enable the photodiodes to generate and accumulate photo charge.

In step 1704, the controller can reset the first floating diffusion and the second floating diffusion to, respectively, generate a first reset voltage and a second reset voltage. The controller can assert the RST signal to reset the floating diffusions. With the TG signals de-asserted, the photodiodes can be isolated from the floating diffusions and are not reset. In some examples, the controller can also enable the first S/H circuit and the second S/H circuit to sample and hold, respectively, the first reset voltage and the second reset voltage.

In step 1706, the controller can quantize, using the quantizer, the first reset voltage to a first digital reset value.

Specifically, in step 1706, the controller can control the multiplexor circuit to couple the first S/H circuit (or the first source follower) to the input of the comparator, while isolating the second S/H circuit (or the second source follower) from the input of the comparator. The controller can also forward a first VREF ramp (VREF1) to the comparator to compare against the first reset voltage to generate a first output, and start a counter coupled with the first memory. The controller can forward the first output to the first memory to control when the first memory stores a first count value from the counter. The first count value can be the first digital reset value.

In step 1708, the controller can quantize, using the quantizer, the second reset voltage to a second digital reset value.

Specifically, in step 1708, the controller can control the multiplexor circuit to couple the second S/H circuit (or the second source follower) to the input of the comparator, while isolating the first S/H circuit (or the first source follower) from the input of the comparator. The controller can also forward the first VREF ramp (VREF1) to the comparator to compare against the second reset voltage to generate a second output, and restart the counter coupled with the second memory. The controller can forward the second output to the first memory to control when the second memory stores a second count value from the counter. The second count value can be the second digital reset value.

Referring to FIG. 17B, step 1708 can be followed by steps 1710-1718, which can be performed after the exposure period ends. In step 1710, the controller can transfer the first photo charge from the first photodiode to the first floating diffusion to generate a first signal voltage. Moreover, in step 1712, the controller can transfer the second photo charge from the second photodiode to the second floating diffusion to generate a second signal voltage. The transfer of the first photo charge and the second photo charge can be performed simultaneously by asserting the TG signals.

In step 1714, the controller can quantize, using the quantizer, the first reset voltage to a first digital reset value.

Specifically, in step 1714, the controller can control the multiplexor circuit to couple the first S/H circuit (or the first source follower) to the input of the comparator, while isolating the second S/H circuit (or the second source follower) from the input of the comparator. The controller can also forward a second VREF ramp (VREF2) to the comparator to compare against the first signal voltage to generate a third output, and start the counter coupled with the first memory. The controller can forward the third output to the first memory to control when the first memory stores a third count value from the counter. The third count value can be the first digital signal value.

In step 1716, the controller can quantize, using the quantizer, the second signal voltage to a second digital signal value.

Specifically, in step 1716, the controller can control the multiplexor circuit to couple the second S/H circuit (or the second source follower) to the input of the comparator, while isolating the first S/H circuit (or the first source follower) from the input of the comparator. The controller can also forward the second VREF ramp (VREF2) to the comparator to compare against the second signal voltage to generate a fourth output, and restart the counter coupled with the second memory. The controller can forward the fourth output to the second memory to control when the second memory stores a fourth count value from the counter. The fourth count value can be the second digital signal value.

In step 1718, the image sensor can output a first digital representation of an intensity of the light received by the first photodiode based on a difference between the first digital signal value and the first digital reset value. Moreover, in step 1720, the image sensor can output a second digital representation of an intensity of the light received by the second photodiode based on a difference between the second digital signal value and the second digital reset value.

Specifically, the first digital signal value can include an error component contributed by the electronic noise and measurement error. The error component is also present in the first digital reset value. Accordingly, a digital CDS operation can be performed to subtract the first digital reset value from the first digital signal value to remove or reduce the error component. Moreover, a digital CDS operation can also be performed to subtract the second digital reset value from the second digital signal value. In some examples, a leakage offset component can be added to (or subtracted) from the second digital reset value to account the additional leakage experienced by the noise charge due to the second signal voltage being quantized later than the first signal voltage.

In some examples, as described in FIG. 14A-FIG. 16B, the controller can enable the first photodiode and the second photodiode to generate charge in multiple exposure sub-periods of different durations within a global exposure period, and the charge can be quantized to generate an image frame. The different durations can be configured based on different target intensity ranges. For example, the controller can enable a photodiode to sense light of a high light intensity range in a short duration exposure period to avoid saturating the photodiode. Moreover, the controller can enable the photodiode to sense light of a low light intensity range in a long duration exposure period to ensure that the charge generated and accumulated by the photodiode exceeds the noise charge.

In some examples, a pair of digital reset value and digital signal value can be generated from each exposure sub-period for each photodiode, and the pairs of digital reset values and digital signal values can be read-out and combined to generate an image frame based on, for example, method 1402 of FIG. 14B. In some examples, the image sensor can include state logic circuits that can freeze memory 912 after storing a pair of digital reset value and digital signal value in the memory, to avoid read-out operations during the global exposure period, as shown in FIG. 15A and FIG. 15B. In such examples, the different exposure sub-periods can have different start times. In some examples, the image sensor can also perform one reset operation and obtain a set of digital reset values from the first exposure sub-period, and use the set of digital reset values to perform digital CDS operations with digital signal values obtained from the first exposure sub-period and other exposure sub-periods, to reduce the number of quantization operations and frame period, as shown in FIG. 16A and FIG. 16B. In such examples, the exposure sub-periods can have the same start time.

Steps, operations, or processes described may be performed or implemented with one or more hardware or software modules, alone or in combination with other devices. In some examples, a software module is implemented with a computer program product comprising a computer-readable medium containing computer program code, which can be executed by a computer processor for performing any or all of the steps, operations, or processes described.

Examples of the disclosure may also relate to an apparatus for performing the operations described. The apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Examples of the disclosure may also relate to a product that is produced by a computing process described herein. Such a product may comprise information resulting from a computing process, where the information is stored on a non-transitory, tangible computer readable storage medium and may include any example of a computer program product or other data combination described herein.

The language used in the specification has been principally selected for readability and instructional purposes, and it may not have been selected to delineate or circumscribe the inventive subject matter. It is therefore intended that the scope of the disclosure be limited not by this detailed description, but rather by any claims that issue on an application based hereon. Accordingly, the disclosure of the examples is intended to be illustrative, but not limiting, of the scope of the disclosure, which is set forth in the following claims.

That which is claimed is:

1. An apparatus comprising:
a first photodiode;
a second photodiode;
a first floating diffusion;
a second floating diffusion;
a quantizer; and
a controller configured to:
within an exposure period:
enable the first photodiode and the second photodiode to generate and accumulate, respectively, a first photo charge and a second photo charge in response to light;
reset the first floating diffusion and the second floating diffusion to, respectively, generate a first reset voltage and a second reset voltage;
quantize, using the quantizer, the first reset voltage to a first digital reset value; and
quantize, using the quantizer, the second reset voltage to a second digital reset value; and
after the exposure period ends:
transfer the first photo charge from the first photodiode to the first floating diffusion to generate a first signal voltage;
transfer the second photo charge from the second photodiode to the second floating diffusion to generate a second signal voltage;
quantize, using the quantizer, the first signal voltage to a first digital signal value;
quantize, using the quantizer, the second signal voltage to a second digital signal value;
output a first digital representation of an intensity of the light received by the first photodiode based on a difference between the first digital signal value and the first digital reset value; and
output a second digital representation of an intensity of the light received by the second photodiode based on a difference between the second digital signal value and the second digital reset value.

2. The apparatus of claim 1, further comprising a first sampling-and-hold (S/H) circuit coupled between the first floating diffusion and the quantizer and a second S/H circuit coupled between the second floating diffusion and the quantizer;
wherein the controller is configured to:
within the exposure period:
control the first S/H circuit to sample and hold the first reset voltage;
control the second S/H circuit to sample and hold the second reset voltage;
quantize, using the quantizer, the first reset voltage stored in the first S/H circuit to generate the first digital reset value; and
quantize, using the quantizer, the second reset voltage stored in the first S/H circuit to generate the second digital reset value; and
after the exposure period ends:
control the first S/H circuit to sample and hold the first signal voltage;
control the second S/H circuit to sample and hold the second signal voltage;
quantize, using the quantizer, the first signal voltage stored in the first S/H circuit to generate the first digital signal value; and
quantize, using the quantizer, the second signal voltage stored in the second S/H circuit to generate the second digital signal value.

3. The apparatus of claim 1, further comprising a first memory and a second memory;
wherein the first memory is configured to store the first digital reset value and the first digital signal value; and
wherein the second memory is configured to store the second digital reset value and the second digital signal value.

4. The apparatus of claim 3, wherein the quantizer comprises a comparator;
wherein the apparatus further comprises:
a counter coupled with each of the first memory and the second memory;
an output logic circuit coupled between an output of the comparator and each of the first memory and the second memory; and
wherein the controller is configured to:
within the exposure period:
control the comparator to compare the first reset voltage with a first voltage ramp to generate a first output; and
control the output logic circuit to forward the first output of the comparator to the first memory to store a first count value from the counter as the first digital reset value;
control the comparator to compare the second reset voltage with the first voltage ramp to generate a second output; and
control the output logic circuit to forward the second output of the comparator to the second memory to store a second count value from the counter as the second digital reset value; and
after the exposure period:
control the comparator to compare the first signal voltage with a second voltage ramp to generate a third output; and
control the output logic circuit to forward the third output of the comparator to the first memory to store a third count value from the counter as the first digital signal value;
control the comparator to compare the second signal voltage with the second voltage ramp to generate a fourth output; and
control the output logic circuit to forward the fourth output of the comparator to the second memory to store a fourth count value from the counter as the second digital signal value.

5. The apparatus of claim 2, wherein the quantizer further includes a comparator;
wherein the apparatus further includes a multiplexor circuit coupled between the first S/H circuit and the comparator, and between the second S/H circuit and the comparator;
wherein the controller is configured to:
within the exposure period:
control the multiplexor circuit to couple the first S/H circuit with the comparator, and to isolate the second S/H circuit from the comparator, to generate the first digital reset value; and
control the multiplexor circuit to couple the second S/H circuit with the comparator, and to isolate the first S/H circuit from the comparator, to generate the second digital reset value; and
after the exposure period ends:
control the multiplexor circuit to couple the first S/H circuit with the comparator, and to isolate the second S/H circuit from the comparator, to generate the first digital signal value; and
control the multiplexor circuit to couple the second S/H circuit with the comparator, and isolate the first S/H circuit from the comparator, to generate the second digital signal value.

6. The apparatus of claim 5, further comprising a first source follower coupled between the first floating diffusion and the first S/H circuit, and a second source follower coupled between the second S/H circuit and the multiplexor circuit.

7. The apparatus of claim 6, wherein the controller is configured to disable the first source follower and the second source follower when the quantizer quantizes the first reset voltage, the first signal voltage, the second reset voltage, and the second signal voltage.

8. The apparatus of claim 6, wherein the multiplexor circuit comprises:
a third source follower coupled with the first source follower;
a first switch coupled between an input of the comparator and the third source follower, the first switch controllable by the controller to couple the third source follower with the input of the comparator, or to isolate the third source follower from the input of the comparator;
a fourth source follower coupled with the second source follower;
a second switch and coupled between an input of the comparator and the third source follower, the second switch controllable by the controller to couple the fourth source follower with the input of the comparator, or to isolate the fourth source follower from the input of the comparator; and
a current source coupled with the input of the comparator to supply a bias current to one of the third source follower or the fourth source follower.

9. The apparatus of claim 6, wherein the multiplexor circuit comprises;
a first switch coupled between the first S/H circuit and an input of the comparator, the first switch controllable by the controller to couple the first S/H circuit with the input of the comparator, or to isolate the first S/H circuit from the input of the comparator; and
a second switch coupled between the second S/H circuit and the input of the comparator, the second switch controllable by the controller to couple the second S/H circuit with the input of the comparator, or to isolate the second S/H circuit from the input of the comparator.

10. The apparatus of claim 9, further comprising a pre-charge circuit coupled with the input of the comparator,
wherein the controller is configured to enable the pre-charge circuit to pre-charge the input of the comparator prior to the multiplexor circuit coupling the first S/H circuit with the input of the comparator, and prior to the multiplexor circuit coupling the second S/H circuit with the input of the comparator.

11. The apparatus of claim 9, further comprising:
a third source follower coupled between an output of the multiplexor circuit and the input of the comparator; and
a pre-charge circuit coupled with the output of the multiplexor circuit,
wherein the controller is configured to enable the pre-charge circuit to pre-charge the output of the multiplexor circuit prior to the multiplexor circuit coupling the first S/H circuit with the input of the comparator, and prior to the multiplexor circuit coupling the second S/H circuit with the input of the comparator.

12. The apparatus of claim 3, wherein the first photodiode, the second photodiode, the first floating diffusion, and the second floating diffusion are formed in a first semiconductor layer;
wherein the quantizer is formed in a second semiconductor layer;
wherein the first memory and the second memory are formed in a third semiconductor layer; and
wherein the first semiconductor layer, the second semiconductor layer, and the third semiconductor layer form a stack.

13. The apparatus of claim 3, wherein the exposure period is a first exposure period;
wherein the controller is configured to:
within a second exposure period:
enable the first photodiode and the second photodiode to generate and accumulate, respectively, a third photo charge and a fourth photo charge in response to light;
and
after the second exposure period ends:
transfer the third photo charge from the first photodiode to the first floating diffusion to generate a third signal voltage;
transfer the fourth photo charge from the second photodiode to the second floating diffusion to generate a fourth signal voltage;
quantize, using the quantizer, the third signal voltage to a third digital signal value;
quantize, using the quantizer, the fourth signal voltage to a fourth digital signal value;
output the first digital representation for an image frame based on one of the first digital signal value or the third digital signal value; and
output the second digital representation for the image frame based on one of the second digital signal value or the fourth digital signal value.

14. The apparatus of claim 13, wherein the second exposure period is part of a global exposure period that further comprises the first exposure period.

15. The apparatus of claim 14, wherein the controller is configured to:
within the second exposure period:
reset the first floating diffusion and the second floating diffusion to, respectively, generate a third reset voltage and a fourth reset voltage;
quantize, using the quantizer, the third reset voltage to a third digital reset value; and
quantize, using the quantizer, the fourth reset voltage to a fourth digital reset value;
wherein the first digital representation is generated based on one of: a first difference between the first digital signal value and the first digital reset value, or a second difference between the third digital signal value and the third digital reset value;
wherein the second digital representation is generated based on one of: a third difference between the second digital signal value and the second digital reset value, or a fourth difference between the fourth digital signal value and the fourth digital reset value; and
wherein the second exposure period starts after the first exposure period.

16. The apparatus of claim 15, wherein the controller is configured to, within the global exposure period:
perform read-out operations of the first digital reset value and the first digital signal value from the first memory;
perform read-out operations of the second digital reset value and the second digital signal value from the second memory;
overwrite the first digital reset value and the first digital signal value with, respectively, the third digital reset value and the third digital signal value in the first memory; and
overwrite the second digital reset value and the second digital signal value with, respectively, the fourth digital reset value and the fourth digital signal value in the second memory.

17. The apparatus of claim 15, further comprising static logic circuits configured to:
based on whether the first digital signal value is within a pre-defined range, freeze the first memory or allow storage of the third digital reset value and the third digital signal value into the first memory; and
based on whether the second digital signal value is within the pre-defined range, freeze the second memory or allow storage of the fourth digital reset value and the fourth digital signal value into the second memory.

18. The apparatus of claim 15, wherein the first digital representation is generated based on one of: a first difference between the first digital signal value and the first digital reset value, or a second difference between the third digital signal value and the first digital reset value;
wherein the second digital representation is generated based on one of: a third difference between the second digital signal value and the second digital reset value, or a fourth difference between the fourth digital signal value and the second digital reset value; and
wherein the second exposure period starts at the same time as the first exposure period.

19. A method comprising:
within an exposure period:
enabling a first photodiode and a second photodiode to generate and accumulate, respectively, a first photo charge and a second photo charge in response to light;
resetting a first floating diffusion and a second floating diffusion to, respectively, generate a first reset voltage and a second reset voltage;
quantizing, using a quantizer, the first reset voltage to a first digital reset value; and
quantizing, using the quantizer, the second reset voltage to a second digital reset value; and
after the exposure period ends:
transferring the first photo charge from the first photodiode to the first floating diffusion to generate a first signal voltage;
transferring the second photo charge from the second photodiode to the second floating diffusion to generate a second signal voltage;
quantizing, using the quantizer, the first signal voltage to a first digital signal value;
quantizing, using the quantizer, the second signal voltage to a second digital signal value;
outputting a first digital representation of an intensity of the light received by the first photodiode based on a difference between the first digital signal value and the first digital reset value; and
outputting a second digital representation of an intensity of the light received by the second photodiode based on a difference between the second digital signal value and the second digital reset value.

20. The method of claim 19, wherein the exposure period is a first exposure period; wherein the method further comprises:
within a second exposure period, enabling the first photodiode and the second photodiode to generate and accumulate, respectively, a third photo charge and a fourth photo charge in response to light; and
after the second exposure period ends:
transferring the third photo charge from the first photodiode to the first floating diffusion to generate a third signal voltage;
transferring the fourth photo charge from the second photodiode to the second floating diffusion to generate a fourth signal voltage;
quantizing, using the quantizer, the third signal voltage to a third digital signal value;
quantizing, using the quantizer, the fourth signal voltage to a fourth digital signal value;
outputting the first digital representation for an image frame based on one of the first digital signal value or the third digital signal value; and
outputting the second digital representation for the image frame based on one of the second digital signal value or the fourth digital signal value.
